(19) United States
(12) Patent Application Publication
(10) Pub. No.: US 2026/0236048 A1
(43) Pub. Date: Aug. 13, 2026

(54) HYBRID SUPPLY GENERATOR AND SUPPLY MODULATOR AND RELATED CIRCUITS AND TECHNIQUES

(71) Applicant: Murata Manufacturing Co., Ltd., Kyoto (JP)

(72) Inventors: David J. Perreault, Cambridge, MA (US); Aaron Cook, Windham, NH (US)

(73) Assignee: Murata Manufacturing Co., Ltd., Kyoto (JP)

(21) Appl. No.: 19/530,971

(22) Filed: Feb. 5, 2026

Related U.S. Application Data
(60) Provisional application No. 63/757,153, filed on Feb. 11, 2025.

(51) Int. Cl. G05F 1/46

(52) U.S. Cl. CPC G05F 1/462

(57) ABSTRACT

Described are concepts, systems, circuits, devices, methods, and techniques directed toward power management and control. In particular, described are concepts, systems, circuits, devices, methods, and techniques for implementing hybrid supply generators and supply modulators that comprise a controllable linear regulator and a reconfigurable network of switches and capacitors to generate and supply a voltage level out of multiple available voltage levels.

### CROSS-REFERENCE TO RELATED APPLICATIONS

This application claims the benefit of priority under 35 U.S.C. § 119 of U.S. Provisional Patent Application No. 63/757,153, filed on Feb. 11, 2025, which is hereby incorporated by reference herein in its entirety.

### BACKGROUND

The efficiency of radio-frequency (RF) power amplifiers (PAS) can be improved through “supply modulation” (or “drain modulation” or “collector modulation”), in which the power supply voltage provided to the PA is adjusted dynamically (“modulated”) over time depending upon the RF signal being synthesized. For the largest efficiency improvements, supply voltage can be adjusted discretely (among discrete levels) or continuously on a short time scale that tracks or dynamically accommodates rapid variations in RF signal amplitude (or envelope), such as may occur as data is encoded in the RF signal or as the RF signal amplitude is desired to be changed with high envelope bandwidth (e.g., as in envelope tracking, envelope tracking advanced, polar modulation, “class G” power amplification, multilevel backoff, multilevel linear amplifier with nonlinear components (LINC), Asymmetric Multilevel Outphasing (AMO), etc.). The power supply voltage (or voltage levels) provided to the PA may also be adapted to accommodate longer-term changes in desired RF envelope (e.g., “adaptive bias”) such as associated with adapting transmitter output strength to minimize errors in data transfer, for RF “traffic” variations, etc.

“Continuous” supply modulation (e.g., “envelope tracking” or “adaptive bias”) may be advantageously realized by dynamically selecting an intermediate voltage from among a set of discrete power supply voltages and then further regulating (stepping down) this intermediate voltage to create a continuously-variable supply voltage to be provided to the PA, or by pulse-width modulating between two or more levels and filtering the output to create a continuously-varying waveform.

Some RF amplifier systems utilize “discrete” supply modulation (or discrete “drain modulation”) in which the supply voltage is switched among a set of discrete voltage levels, possibly including additional filtering or modulation to shape the voltage transitions among levels. Systems of this type include “class G” amplifiers, multilevel LINC (MLINC) power amplifiers, AMO power amplifiers, multilevel backoff amplifiers (including “asymmetric multilevel backoff” amplifiers) and digitized polar transmitters among other types. Hybrid systems which utilize a combination of continuous and discrete supply modulation may also be realized.

### SUMMARY

Described herein are concepts, systems, circuits, devices, methods, and techniques for use in and/or with PA architectures. The described concepts, systems, circuits, devices, methods, and techniques may provide for very rapid variations in modulated power supply voltage (e.g., among multiple discrete levels). The described concepts, systems, circuits, devices, methods, and techniques may also provide the ability to slowly adapt the voltages of the discrete levels over a desired range. The described concepts, systems, circuits, devices, methods, and techniques may provide high performance power supplies in PA architectures at lower cost and/or at reduced size as compared to prior solutions. Such concepts, systems, circuits, devices, methods, and techniques may find use in a number of applications including, but not limited to PA architectures.

Using concepts, systems, circuits, devices, methods, and techniques described herein, it may be possible to efficiently and compactly generate a set of m power supply voltages. In some embodiments, two of the m power supply voltages (e.g., V1 and Vm) may be independently controlled. The other m-2 power supply voltages may be distributed in some prescribed relation to the two independently controlled power supply voltages, such as spaced in an even fashion between them and/or around them (e.g., with adjacent voltage levels each separated by an approximate voltage ΔV). Thus, for example, the following m power supply voltages may be provided wherein V1 and Vm are the independently controlled supply voltages:

$$Vk = V 1 + ( k - 1 ) * ( Vm - V 1 ) / ( m - 1 ) for k = 1 … m .$$

Such an arrangement may be equivalent to allowing for independently specifying or controlling:
(a) minimum (Vₘᵢₙ) and maximum (Vₘₐₓ) voltage levels (with the spacing between voltage levels ΔV determined in terms of Vₘᵢₙ and Vₘₐₓ and the total number of levels m);
(b) minimum supply voltage level (Vₘᵢₙ) and an inter-level voltage spacing ΔV (with the maximum voltage level Vₘₐₓ determined by ΔV and the total number of levels m); and/or
(c) maximum supply voltage level (Vₘₐₓ) and an inter-level voltage spacing ΔV (with the minimum voltage level Vₘᵢₙ determined by ΔV and the total number of levels m).

The concepts, systems, circuits, devices, methods, and techniques described herein may provide substantially all (or most) of the practical benefits available from supply modulation (e.g., in terms of PA efficiency) while at the same time avoiding limitations associated with providing truly independent voltage level control. Thus, the concepts, systems, circuits, devices, methods, and techniques described herein may provide significant advantages in combinations of size, cost, efficiency and performance as compared to existing approaches.

Further benefits may be provided by generating and providing supply voltage levels to the PA without the necessity of having a separate supply generator element to generate the levels cascaded with a supply modulator to select among the levels (i.e., by providing a hybrid supply generator and supply modulator). Merging the functions of supply voltage level generation and supply modulation may reduce the number and size of passive components (e.g., capacitors) required as well as the number, required area, and loss of semiconductor elements (e.g., switches).

Additional benefits may also be provided by providing a hybrid supply generator and supply modulator that includes a controllable linear regulator, such as a controllable low dropout (LDO) voltage regulator, coupled between an energy source and a controllable network of switches and capacitors. Such a power supply architecture may provide for flexibility in controlling voltage levels to output from the power supply, while reducing cost and/or space requirements (e.g., given the smaller size of components in a linear regulator as opposed to a magnetic and/or capacitive power converter) as compared to other power supply architectures.

In accordance with some embodiments, a system is provided. The system has a pair of input terminals configured to be connected to terminals of an energy source and has a pair of output terminals configured to be connected to a radio frequency (RF) amplifier. The system comprises a hybrid supply generator and supply modulator. The hybrid supply generator and supply modulator comprises a linear regulator configured to draw power at the input terminals, and a network of switches and at least one capacitor coupled to an output of the linear regulator. The system further comprises a controller configured to control the hybrid supply generator and supply modulator to output a selected voltage level.

In some embodiments, the hybrid supply generator and supply modulator is reconfigurable.

In further embodiments, the controller is further configured to reconfigure the hybrid supply generator and supply modulator to output the selected voltage level.

In still further embodiments, the energy source is a variable voltage source.

In some embodiments, the variable voltage source is a battery.

In further embodiments, the controller is further configured to control the linear regulator to output a first voltage level. The controller is still further configured to control the network of switches to output a second voltage level as the selected voltage level.

In still further embodiments, the second voltage level is related to the first voltage level.

In some embodiments, an output reference of the linear regulator is selected from among multiple discrete regulation points.

In further embodiments, the at least one capacitor comprises a plurality of capacitors, the linear regulator is configured to output a first voltage level, and the network of switches and capacitors is reconfigurable to output one of a plurality of different voltage levels related to the first voltage level as the selected voltage level.

In still further embodiments, the plurality of different voltage levels are proportional to the first voltage level.

In some embodiments, the plurality of different voltage levels comprises the first level, two thirds of the first voltage level, and one third of the first voltage level.

In further embodiments, the plurality of different voltage levels further comprises a voltage of zero volts.

In still further embodiments, the plurality of different voltage levels comprises the first voltage level and one half of the first voltage level.

In some embodiments, the plurality of different voltage levels further comprises a voltage of zero volts.

In further embodiments, the at least one capacitor comprises a plurality of capacitors, the linear regulator is configured to output a first voltage level, and the network of switches and capacitors is reconfigurable to operate in one of at least two different operating modes, a first operating mode configured to output a first set of voltage levels proportional to the first voltage level and a second operating mode configured to output a second set of voltage levels proportional to the first voltage level, the second set being different from the first set.

In still further embodiments, the at least one capacitor comprises a plurality of capacitors, the linear regulator is configured to output a first voltage level, and the controller is configured to control the network of switches to reconfigure the hybrid supply generator and supply modulator to operate in one of at least two different operating modes, a first operating mode configured to output at least three different voltage levels proportional to the first voltage level and a second operating mode configured to output at least two different voltage levels proportional to the first voltage level.

In some embodiments, the controller is further configured to detect a voltage level of the energy source, and control the linear regulator to output a first voltage level based on the detected voltage level.

In further embodiments, the at least one capacitor comprises a plurality of capacitors. The controller is further configured to detect a voltage level of the energy source, and reconfigure the network of switches and capacitors to output the selected voltage level based on the detected voltage level.

In still further embodiments, the at least one capacitor comprises a plurality of capacitors. The controller is further configured to detect a voltage level of the energy source, control the linear regulator to output a first voltage level based on the detected voltage level, and reconfigure the network of switches and capacitors to output a second voltage level related to the first voltage level based on the detected voltage level.

In some embodiments, the controller is further configured to detect a voltage level of the energy source, and reconfigure the hybrid supply generator and supply modulator to operate in one of at least two different operating modes based on the detected voltage level.

In further embodiments, the controller is further configured to receive a signal related to at least one of a voltage level of the energy source or a desired RF output power of the RF amplifier, and control the linear regulator to output a first voltage level and/or reconfigure the network of switches and capacitors to output a second voltage level based on the received signal.

In still further embodiments, the RF amplifier transmits at least one of WiFi signals or cellular signals.

In some embodiments, the linear regulator is a low drop-out (LDO) linear regulator.

In further embodiments, the linear regulator comprises a metal oxide semiconductor (MOS) transistor device.

In still further embodiments, the hybrid supply generator and supply modulator comprises lumped element capacitors and integrated circuit (IC) transistors.

In some embodiments, the at least one capacitor comprises a plurality of capacitors, and at least one of the linear regulator or the network of switches and capacitors can be programmatically reconfigured.

In further embodiments, the at least one capacitor comprises a plurality of capacitors, and at least one of the linear regulator or the network of switches and capacitors can be reconfigured based on a signal received from a digital pre-distortion (DPD) circuit.

In still further embodiments, the system further comprises a filtering circuit coupled between the hybrid supply generator and supply modulator and the RF amplifier, the filtering circuit comprising at least one of a resistor, capacitor, or inductor.

In some embodiments, the system further comprises at least one switch coupled between the hybrid supply generator and supply modulator and the RF amplifier, wherein operation of the at least one switch powers down the RF amplifier.

In further embodiments, the hybrid supply generator and supply modulator is capable of synthesizing the selected voltage level and supplying the selected voltage level, wherein at least one of the switches is utilized in both the synthesizing and supplying of the selected voltage level.

In still further embodiments, the controller is further configured to operate the switches according to a state of a state machine implemented in the controller.

In some embodiments, the state of the state machine is selected to synthesize the selected voltage level and to maintain one or more voltages in the hybrid supply generator and supply modulator within a range.

In further embodiments, the controller implements the state machine on a clocked basis.

In still further embodiments, the controller implements the state machine on an unclocked basis.

In some embodiments, the at least one capacitor comprises a plurality of capacitors, the linear regulator is configured to output a first voltage level, and the controller is further configured to operate the switches to regulate a voltage on one of the capacitors near one third of the first voltage level, and to regulate a voltage on another of the capacitors near two thirds of the first voltage level.

In further embodiments, the at least one capacitor comprises a plurality of capacitors, the linear regulator is configured to output a first voltage level, and the controller is further configured to operate the switches to regulate a voltage on one of the capacitors near one half of the first voltage level, and to regulate a voltage on another of the capacitors near one half of the first voltage level.

In still further embodiments, the controller is further configured to control the hybrid supply generator and supply modulator to set a minimum voltage level for the selected voltage level, set a maximum voltage level for the selected voltage level, and set a number of voltage levels for the selected voltage level between the minimum voltage level and the maximum voltage level.

In some embodiments, the controller is further configured to control the hybrid supply generator and supply modulator to set a minimum voltage level, and set a voltage level spacing between additional voltage levels for the selected voltage level above the minimum voltage level, wherein a maximum voltage level for the selected voltage level is based on a number of the additional voltage levels.

In further embodiments, the controller is further configured to control the hybrid supply generator and supply modulator to set a maximum voltage level for the selected voltage level, and set a voltage level spacing between additional voltage levels for the selected voltage level below the maximum voltage level, wherein a minimum voltage level for the selected voltage level is based on a number of the additional voltage levels.

In still further embodiments, the at least one capacitor comprises a plurality of capacitors. The system further comprises a regulation stage comprising the linear regulator that outputs multiple voltage levels, and a differential multi-level converter stage comprising the network of switches and capacitors that synthesizes one of two or more voltage levels related to at least one of the multiple voltage levels for output as the selected voltage level.

In some embodiments, the controller is further configured to control the switches to output the selected voltage level.

In further embodiments, at least one of the switches comprises an integrated transistor switch.

Before explaining example embodiments consistent with the present disclosure in detail, it is to be understood that the disclosure is not limited in its application to the details of constructions and to the arrangements set forth in the following description or illustrated in the drawings. The disclosure is capable of being practiced and carried out in various ways. Also, it is to be understood that the phraseology and terminology employed herein, as well as in the abstract, are for the purpose of description and should not be regarded as limiting.

It is to be understood that both the foregoing general description and the following detailed description are explanatory only and are not restrictive of the claimed subject matter.

### BRIEF DESCRIPTION OF THE DRAWINGS

The accompanying drawings, which are incorporated in and constitute part of this specification, and together with the description, illustrate and serve to explain the principles of various example embodiments.

FIG. 1A is a diagram of an example radio frequency (RF) power amplifier (PA) system utilizing multiple supply levels and supply modulators to select from the multiple supply levels to supply multiple PAs.

FIG. 1B is a diagram of an example RF amplifier system including a multiple-output supply generator comprising a single-input multiple-output (SIMO) boost converter, a supply modulator, and a filter.

FIG. 2A is a diagram of an example switching network for implementing a series supply modulator.

FIG. 2B is a diagram of an example switching network for implementing a parallel supply modulator.

FIG. 3 is a diagram of an example supply modulator with a cascaded turn-off switch.

FIG. 4 is a diagram of an example implementation of a series supply modulator, such as the series supply modulator of FIG. 2A.

FIG. 5A is a diagram of an example RF amplifier system utilizing a hybrid supply generator and supply modulator to provide multiple supply levels.

FIG. 5B is a diagram of an example RF amplifier system utilizing a hybrid supply generator and supply modulator and a filter network.

FIG. 5C is a diagram of an example RF amplifier system utilizing a hybrid supply generator and supply modulator and a PA turn-off switch.

FIG. 6A is a diagram of an example architecture of a hybrid supply generator and supply modulator that may be used in an RF amplifier system.

FIG. 6B is a diagram of another example hybrid supply generator and supply modulator architecture, where a differential multi-level converter couples to an input voltage of an energy source and to a regulated voltage.

FIG. 6C is a diagram of still another example hybrid supply generator and supply modulator architecture, where a multi-level converter couples to a regulated voltage and to a ground reference potential (e.g., 0V).

FIG. 7A is a diagram illustrating one implementation of a magnetic multi-output regulation stage suitable for use in a hybrid supply generator and supply modulator.

FIG. 7B is a diagram illustrating another implementation of a magnetic multi-output regulation stage suitable for use in a hybrid supply generator and supply modulator.

FIG. 7C is a diagram illustrating still another implementation of a magnetic multi-output regulation stage suitable for use in a hybrid supply generator and supply modulator.

FIG. 7D is a diagram illustrating a further implementation of a magnetic multi-output regulation stage suitable for use in a hybrid supply generator and supply modulator.

FIG. 7E is a diagram illustrating a still further implementation of a magnetic multi-output regulation stage suitable for use in a hybrid supply generator and supply modulator.

FIG. 7F is a diagram illustrating one implementation of a non-magnetic regulation stage suitable for use in a hybrid supply generator and supply modulator.

FIG. 7G is a diagram illustrating another implementation of a non-magnetic regulation stage suitable for use in a hybrid supply generator and supply modulator.

FIG. 7H is a diagram illustrating still another implementation of a non-magnetic multi-output regulation stage suitable for use in a hybrid supply generator and supply modulator.

FIG. 7I is a diagram illustrating a further implementation of a non-magnetic multi-output regulation stage suitable for use in a hybrid supply generator and supply modulator.

FIG. 7J is a diagram illustrating a still further implementation of a non-magnetic multi-output regulation stage suitable for use in a hybrid supply generator and supply modulator.

FIG. 8 is a diagram of an example multilevel converter that may be used in a hybrid supply generator and supply modulator.

FIG. 9A is a diagram of an example state machine that may be used for controlling switch states in a multilevel converter, such as the multilevel converter of FIG. 8.

FIG. 9B is a diagram of another example state machine that may be used for controlling switch states in a multilevel converter, such as the multilevel converter of FIG. 8.

FIG. 10A is a plot showing example voltage patterns, such as voltage patterns that may be associated with the state machine of FIG. 9A or FIG. 9B.

FIG. 10B is a plot showing additional example voltage patterns, such as voltage patterns that may be associated with the state machine of FIG. 9A or FIG. 9B.

FIG. 10C is a plot showing example state transitions, such as state transitions that may be associated with the state machine of FIG. 9A, or FIG. 9B.

FIG. 11 is a diagram of another example multilevel converter that may be used in a hybrid supply generator and supply modulator.

FIG. 12A is a diagram showing example states that may be selected to properly maintain capacitor voltages (V_{cf1}, V_{cf2}) for different level selections in a multilevel converter (e.g., multilevel converter of FIG. 11), based on different levels of the capacitor voltages (V_{cf1}, V_{cf2}) (or different regions in the (V_{cf1}, Vor2) plane), and showing approximate directions of change in the (V_{cf1}, V_{cf2}) plane for the different state selections.

FIG. 12B is another diagram showing example states that may be selected to provide a high degree of corrective action in maintaining capacitor voltages (V_{cf1}, V_{cf2}) for different level selections in a multilevel converter (e.g., multilevel converter of FIG. 11), based on different levels of the capacitor voltages (V_{cf1}, V_{cf2}) (or different regions in the (V_{cf1}, V_{cf2}) plane).

FIG. 13 is a diagram of an example state machine that may be used for controlling switch states in a multilevel converter, such as the multilevel converter of FIG. 11.

FIG. 14 is a diagram of an example state machine that may be used for switching operating modes between a first operation mode where a multilevel converter (e.g., multilevel converter of FIG. 11) operates as a four-level multilevel converter and a second operation mode where the multilevel converter operates as a three-level multilevel converter.

FIG. 15 is a diagram of an example hybrid supply generator and supply modulator including a regulation stage, such as a linear regulator, and a network of switches and a capacitor (e.g., multilevel converter).

FIG. 16 is a diagram of another example hybrid supply generator and supply modulator including a regulation stage, such as a linear regulator, and a network of switches and capacitors (e.g., multilevel converter).

FIG. 17A is a diagram of an example multilevel converter that may be used in a hybrid supply generator and supply modulator, including circuitry for regulating charge on a flying capacitor.

FIG. 17B is a diagram of another example multilevel converter that may be used in a hybrid supply generator and supply modulator, including circuitry for regulating charge on a flying capacitor.

FIG. 18 is a diagram of an example RF power amplifier system utilizing a hybrid supply generator and supply modulator with multiple outputs to supply multiple power amplifiers.

FIG. 19 is a diagram of an example switching network having one or more pulse-shaping networks (PSNs) and being coupled to one or more hybrid supply generator and supply modulators.

### DETAILED DESCRIPTION

Reference will now be made in detail to the embodiments of the disclosure, certain examples of which are illustrated in the accompanying drawings.

In the following description, numerous specific details are set forth regarding the concepts, systems, circuits, devices, methods, and techniques of the disclosed subject matter, and the environment in which such concepts, systems, circuits, devices, methods, and techniques operate, to provide a thorough understanding of the disclosed subject matter. After reading the descriptions provided herein, it will be apparent to one skilled in the art, however, that the disclosed subject matter may be practiced without such specific details. It will also be apparent to one skilled in the art that certain features, which are well known within the art, are not described in detail to avoid unnecessary complication of the description of the concepts, systems, circuits, devices, methods, and techniques described herein. In addition, it will be understood that the embodiments provided below are examples, and that it is contemplated that there are other concepts, systems, circuits, devices, methods, and techniques that are within the scope of the subject matter disclosed herein.

The disclosure herein includes discussion of certain concepts that would be understood by one of ordinary skill in the art, and so are not discussed in greater detail so as to avoid unnecessary complication of the description of the concepts, systems, circuits, devices, methods, and techniques described herein. For example, a person of ordinary skill in the art would recognize that connections between components (e.g., amplifiers, inductors, resistors, capacitors, switches, diodes, sources, subsystems) described herein may be realized with wires, circuit board traces on a printed circuit board (PCB) or any other way of electrically and/or mechanically connecting components together. A person of ordinary skill in the art will further understand that connection may mean an electrical connection, a mechanical connection or both an electrical and mechanical connection.

A person of ordinary skill in the art would further understand what is meant when discussing certain circuit components or subsystems herein, such as inductors, resistors, capacitors (e.g., lumped element capacitors, distributed capacitors), switches, amplifiers, filters, linear regulators, switched-capacitor converters, supply modulators, and energy sources. For example, a switch may be implemented as a metal oxide semiconductor field effect transistor (MOSFET) (e.g., N-channel MOSFET (NMOS), P-channel MOSFET (PMOS)), bipolar junction transistor (BJT), silicon-controlled rectifier (SCR), insulated gate bipolar transistor (IGBT), diode, integrated transistor switch (or integrated circuit (IC) transistor), or any other component known by one skilled in the art to provide a switching function in electronics. A person of ordinary skill in the art would recognize how to drive (i.e., provide bias and/or control signals to) these components to switch between an “on” state in which current flows through the component and an “off” state in which current does not flow through the component. A person of ordinary skill in the art would understand that these circuit components have terminals for connection to wires or circuit board traces. Thus, the description below and/or the claims may make reference to one or more terminals of a component to convey how that component is connected in relation to other components of the circuit. The term “energy storage element” as used herein should be considered to include any type of energy storage element (such as a capacitor or an inductor as just two examples).

A person of ordinary skill in the art would further recognize that electrical components may be imperfect and may fail at certain levels of current and/or voltage. As a result, components may be provided with ratings (e.g., a voltage rating or a current rating of the component) indicating a maximum level of electric current or voltage a component is designed to withstand, and beyond which the component might fail. A person of ordinary skill in the art would also understand that losses may occur in circuit components and connections. As a result, a person of skill in the art would recognize that, when discussing voltages and currents herein, those voltages and currents may be approximate, and in practice may be off by some degree from the described value (e.g., 1%-30% off from a described or target or ideal value).

The concepts, systems, circuits, devices, methods, and techniques described herein relate to power management and conversion. A person of ordinary skill in the art would understand certain concepts related to this topic. For example, a person of ordinary skill in the art would understand what is meant when describing certain types of power converters, such as a linear regulator or switched-mode power supply (SMPS). A person of ordinary skill in the art would further understand what is meant when describing certain types of SMPS power converters, such as buck converters, boost converters, buck-boost converters, or flyback converters. A person of ordinary skill in the art would further understand what is meant when describing a switched-capacitor converter. A person of ordinary skill in the art would understand that one or more switches of a power supply (e.g., SMPS) are typically operated by a controller at a certain operating frequency (e.g., kHz to MHz range). A person of ordinary skill in the art would understand that these converters typically operate in two distinct phases per cycle of their operating frequency, a first phase in which one or more switches may be on, and a second phase in which the one or more switches may be off. Output voltage or current may be controlled by changing the period for which the one or more switches are on or off per cycle. The percentage of on time per cycle may be referred to as a duty cycle.

A person of ordinary skill in the art would recognize that controllers in converters may receive feedforward and/or feedback signals regarding one or more characteristics of the converter, and may modify one or more aspects of the converter accordingly, to achieve a desired output.

An energy source, as used herein, may be any type of energy source that provides a direct current (DC) voltage. For example, an energy source may be any type of battery, one example of which is a lithium-ion battery. An energy source may also be a DC source converted from an alternating current (AC) source, such as a DC source created by rectifying an AC source. A person of ordinary skill in the art would recognize that a system (e.g., power converter, hybrid supply generator and supply modulator) may have input terminals configured for connection to terminals (e.g., opposing terminals) of the energy source to draw power from the energy source. A person of ordinary skill in the art would also recognize that a system (e.g., power converter, hybrid supply generator and supply modulator) may have output terminals configured to be coupled to a load (e.g., power amplifier). A person of ordinary skill in the art would recognize that certain energy sources may have a voltage that varies, while other energy sources may have a voltage that is fixed. For example, a voltage supplied by a battery may vary over time as the battery discharges. In the case of a battery, chemical reactions within the battery may deplete the energy stored in the battery, thereby causing a decrease in voltage over time until the stored energy of the battery is such that it may no longer effectively power a device until it is recharged. By contrast, a DC source converted from an AC wall outlet, for example, may have a voltage that is fixed and that does not discharge over time.

A “regulator,” as used herein, may comprise one or more electrical components that may operate to provide a desired output voltage regardless of changes to an input voltage. A “supply generator,” as used herein, may comprise one or more electrical components that may operate to generate one or more output voltages from an input voltage. A “supply modulator,” as used herein, may comprise one or more electrical components that may operate to select between different voltage levels. For example, a supply modulator used in power supply circuitry to supply voltage to a PA of a mobile device (e.g., mobile phone) as described herein may switch between different voltages at high frequency to efficiently adjust power supply voltage to a PA dynamically over time depending upon an RF signal being synthesized.

Power management and conversion techniques are described herein with respect to mobile applications, such as for use in mobile devices (e.g., mobile phones). However, the disclosure is not so limited. The techniques described herein may be applicable to any type of electronic device that uses power (e.g., mobile devices, laptops, tablets, personal computers, servers, televisions, base stations).

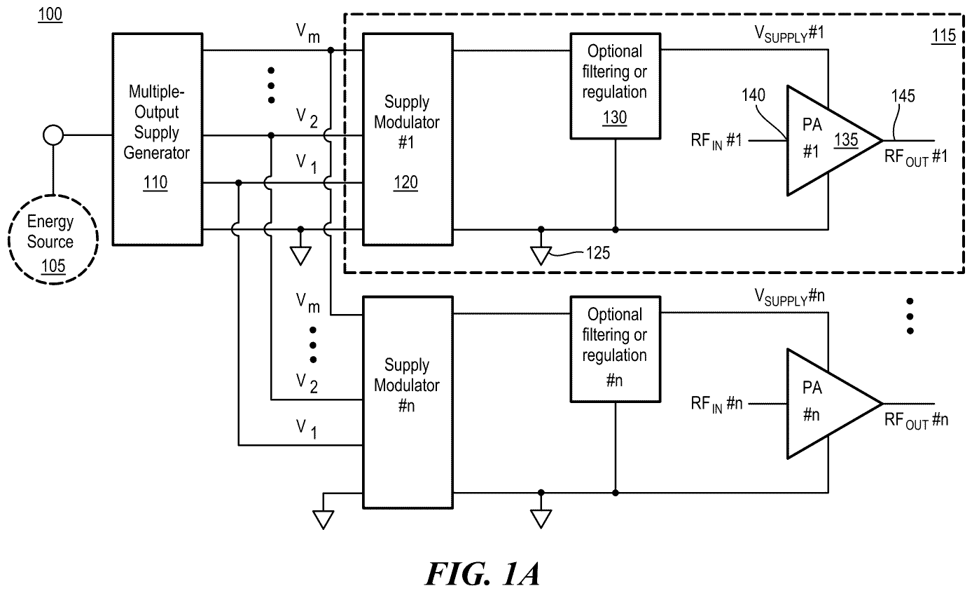

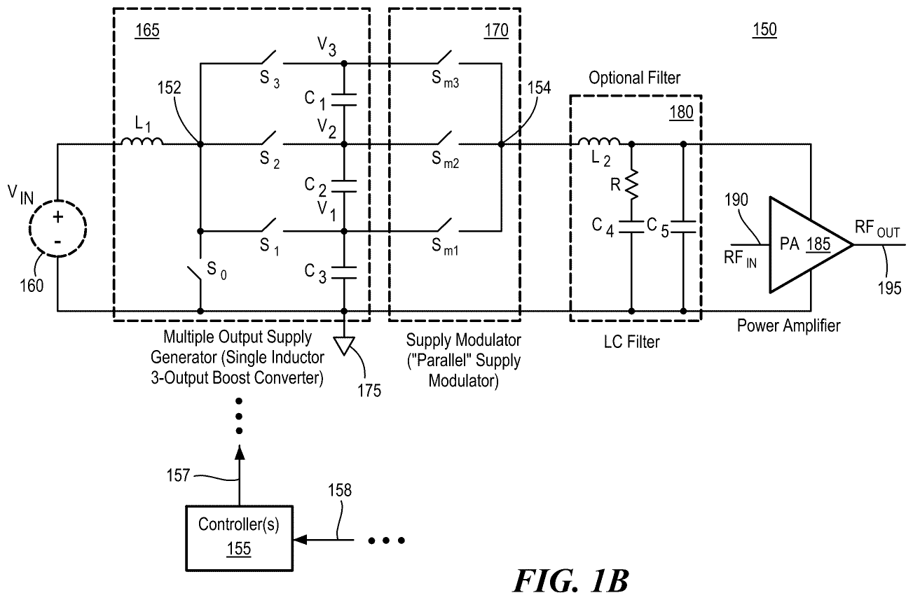

FIG. 1A shows an example of a radio frequency (RF) power amplifier (PA) system utilizing multiple supply levels, and supply modulators to select from the multiple supply levels. Elements and aspects related to signal processing and control for such a system are omitted from FIG. 1A for clarity. System 100 may utilize supply modulation for providing power to one or more RF power amplifiers 135 (e.g., as may be used in a mobile device). System 100 may include a supply generator 110 having an input configured to be coupled to an energy source 105, such as a battery (energy source 105 is here shown in phantom since it may not properly be part of system 100). Supply generator 110 may receive an input signal (e.g., an input voltage) from energy source 105 and in response thereto may output different voltage levels (e.g., 0V, V₁, V₂, . . . , Vₘ) on different voltage rails (e.g., connections, or signal paths each having a certain voltage—such as 0V, V₁, V₂, . . . , Vₘ as illustrated in FIG. 1A). That is, a supply generator subsystem (or more simply a “supply generator”) (e.g., supply generator 110) of system 100 may be a multiple output supply generator 110 that may synthesize multiple power supply voltages V₁-Vₘ from a single input energy source 105. In some examples, a supply generator (e.g., supply generator 110) may regulate one or more of power supply voltages V₁-Vₘ.

System 100 may further include a subsystem 115, which may include a supply modulator 120, optional filtering or regulation circuit 130, and/or power amplifier 135, all of which may be connected to the different voltage rails. For example, supply modulator 120 (e.g., supply modulator #1) may be connected to the voltage rails and may be configured to switch among the multiple voltages of the voltage rails. That is, a supply generator (e.g., supply generator 110) may provide one or more of the voltages V₁-Vₘ to inputs of one or more supply modulator subsystems (or more simply “supply modulators”) (e.g., supply modulator #1 120, supply modulator #n) of a supply modulator subsystem (e.g., subsystem comprising supply modulator #1, . . . , supply modulator #n).

The supply modulators (e.g., supply modulator #1, . . . , supply modulator #n) may switch (e.g., rapidly switch) among the different power supply voltages provided thereto by the supply generator (e.g., supply generator 110) to provide modulated supply voltages V_{SUPPLY} #1-V_{SUPPLY} #n at an output thereof. In some embodiments, switches may be modulated sufficiently rapidly to provide a power supply voltage to the PA such that the PA may provide the required RF output envelope while maintaining high efficiency, in accordance with techniques such as discrete drain modulation, envelope tracking advanced (ETA), discrete envelope tracking, and digital envelope tracking (digital ET). Such techniques are described, for example, in one or more of U.S. Pat. Nos. 8,829,993; 9,160,287; 9,172,336; 9,209,758; and 9,755,672, each of which is commonly assigned and is hereby incorporated by reference herein in its entirety. The supply voltages may be coupled to supply terminals of respective ones of one or more PAs (e.g., PA #1 135-PA #n). In some examples, PA #1 135-PA #n may be provided as RF power amplifiers. In some examples, a supply generator (e.g., supply generator 110) may supply the same or different voltages to different supply modulators (e.g., supply modulator 120—supply modulator #n). In some examples, a different number of voltages may be coupled between a supply generator (e.g., supply generator 110) and different supply modulators (e.g., supply modulator #1 120—supply modulator #n).

A filtering or regulation circuit 130 may optionally be connected to supply modulator 120 to filter or regulate the voltage signal selected by supply modulator 120. The result may be a voltage supply (e.g., V_{SUPPLY} #1) for powering a power amplifier (PA) 135 (e.g., PA #1). Power amplifier 135 may amplify an RF input signal 140 (e.g., RF_{IN} #1), and the amplified RF signal may be output as RF output signal 145 (e.g., RF_{OUT} #1). RF input signal 140 may be, for example, an RF signal to be amplified in a mobile device for wireless transmission as RF output signal 145 (e.g., as a cellular or WiFi signal). As shown in FIG. 1A, some or all of the supply voltages may be coupled to the supply terminals of the PAs through respective ones of optional filtering and/or voltage regulation stages (e.g., optional filtering or regulation circuit 130). The filtering and/or voltage regulation stages may comprise filtering networks, such as passive filters, active filters, and/or additional circuitry capable of regulating the voltage (e.g., including low-dropout regulator(s) (LDOs)) to the PA, V_{SUPPLY}, from a modulated voltage, V_{MOD}.

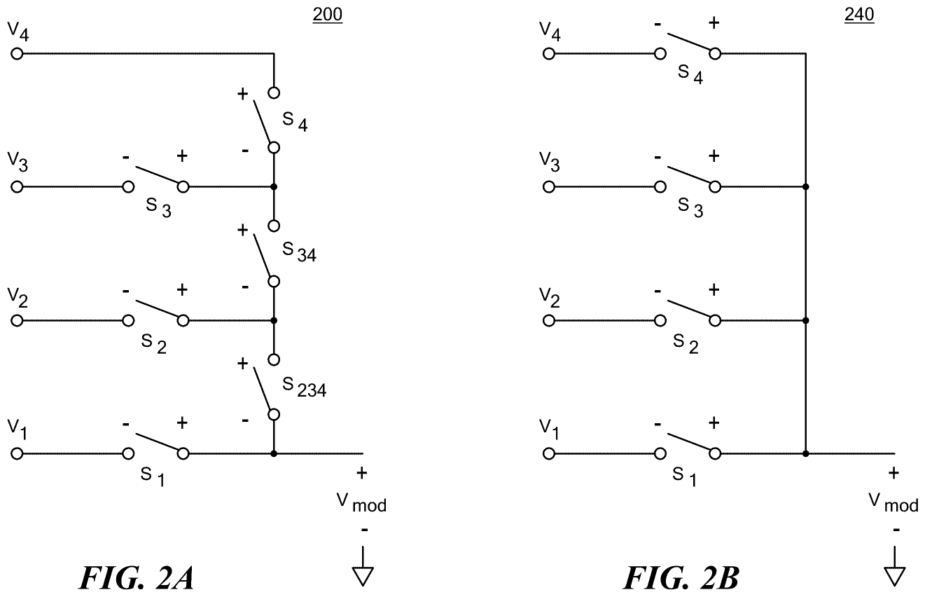

In some examples, one, some, or all of the supply modulators (e.g., supply modulator #1-supply modulator #n) in system 100 may comprise one or more switches to couple one or more voltages provided by a supply generator (e.g., supply generator 110) to PA supply terminals (as V_{SUPPLY} #1-V_{SUPPLY} #n, respectively). A variety of different switching circuits (e.g., circuits having switches arranged in any of a variety of different switch configurations or switch topologies) may be utilized to realize any of the supply modulator subsystems (e.g., supply modulator #1-supply modulator #n). For example, a supply modulator subsystem may comprise a plurality of switches configured to provide a “series” modulator (see, e.g., FIG. 2A). Alternatively, a supply modulator subsystem may comprise a plurality switches configured to provide a “parallel” modulator (see, e.g., FIG. 2B).

As shown in FIG. 1A, system 100 may include any number of subsystems connected to the voltage rails, and connected with their inputs in parallel with each other. For example, system 100 may include any number of supply modulators (e.g., supply modulator #1, . . . , supply modulator #n), optional filtering or regulation circuits (e.g., optional filtering or regulation circuit 130), and power amplifiers (e.g., power amplifiers PA #1, . . . , PA #n). A ground rail 125 may also be connected to various components in system 100. Given the example topology of system 100, the multiple subsystems may supply from the same energy source (e.g., energy source 105) and supply generator (e.g., supply generator 110), different powers (e.g., V_{SUPPLY} #1, . . . , V_{SUPPLY} #n) to any number of power amplifiers (e.g., PA #1, . . . , PA #n) based on each power amplifier's supply needs.

Although FIG. 1A illustrates system 100 as having one supply generator supporting multiple power amplifiers, and one supply modulator and optional filtering or regulation circuit for each power amplifier, the disclosure is not so limited. A person of ordinary skill in the art would recognize, for example, that multiple supply generators may be used to generate any number of voltage rails, and that a single supply modulator and/or filtering or regulation circuit may be used to provide a supply voltage to multiple power amplifiers.

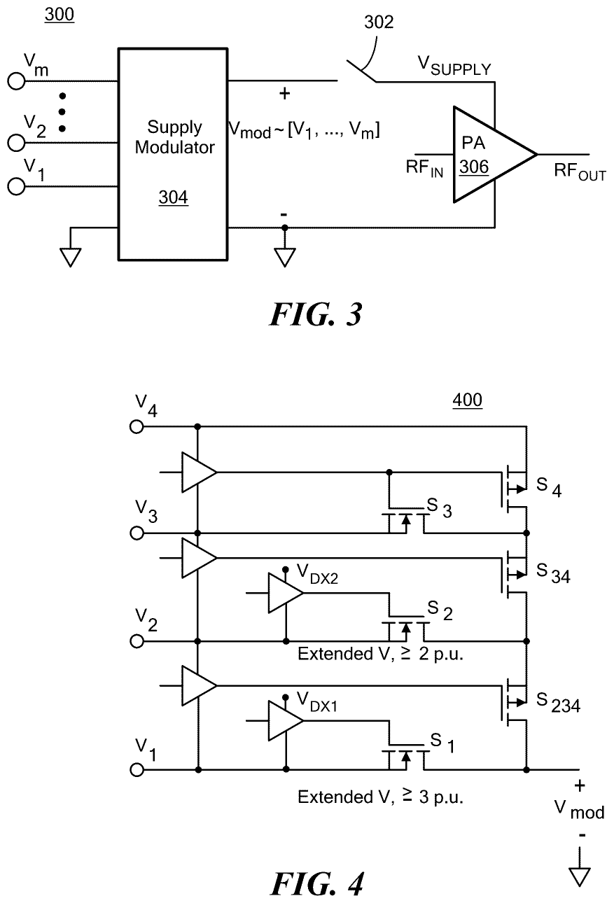

It is to be appreciated that the manner in which the voltages are synthesized by a supply generator (e.g., supply generator 110) of system 100 may affect the required ratings of the switches in the one or more supply modulators (e.g., supply modulator #1-supply modulator #n) of system 100. This may be a consideration in designing a system 100, as the required voltage ratings of the modulator switches may influence (and in some cases, highly influence) switching speed (and therefore achievable modulation rate) and modulator efficiency, both of which may be significant factors in a system. Regardless of the modulator switch topology used, if there are for example an m number of supply levels ordered in increasing voltage V₁, . . . , Vₘ (i.e., V₁<V₂< . . . <Vₘ), then it may be desired that the plurality (or chain) of switches coupled between the jₜₕ supply voltage Vⱼ and the supply modulator output voltage V_{MOD} be rated to block at least a negative voltage of a magnitude (Vₘ-Vⱼ) and a positive voltage that is either (Vⱼ-V₁) or Vⱼ depending upon whether the modulator sources a lowest voltage V₁ or in some cases is able to directly supply a voltage of zero volts (0V) to the PA. In some example systems having designs of the latter type (where the modulator may supply a voltage of 0V), where the power supply provided to the PA may need to be “cut off” (discharged to a zero volt power supply), a separate low-frequency “turn-off” or “disconnect” switch, such as switch 302 shown in FIG. 3, may be placed in series with the output of a supply modulator capable of sourcing modulator output voltages V₁, . . . , Vₘ. Such a turn-off switch may reduce the modulator switch chain voltage blocking requirements from Vⱼ to (Vⱼ-V₁).

In some examples, an RF power amplifier system, such as system 100, may comprise a “series” modulator in a form suitable for integrated circuit (IC) fabrication and for use with ratiometric supply voltages (e.g., V₂=2V₁, V₃=3V₁, V₄=4V₁). Such a design illustrates the impact of the supply levels on the required voltage rating of individual modulator devices. By correct selection of the level voltages, an advantageous use of integrated complimentary metal-oxide semiconductor (CMOS) processes may be made using core devices and/or extended voltage devices to achieve the required voltage blocking characteristics of the modulator switch chains. Moreover, such a circuit illustrates the use of the generated levels for gate drive of the devices. This type of drive circuit facilitates high efficiency and switching speed. However, to take advantage of driving device gates between adjacent level voltages (e.g., between Vⱼ and Vⱼ₋₁), level voltages for this design should be maintained with sufficient spacing. Otherwise, more sophisticated gate drive circuit designs may be required, which may limit achievable switching performance.

FIG. 1B shows another example system 150 that may utilize supply modulation for providing power to a PA 185 of an RF system. System 150 of FIG. 1B may include an energy source 160, supply generator 165, supply modulator 170, optional filter 180, and PA 185. For example, supply generator 165 may be implemented with a boost converter circuit (e.g., single inductor 3-output boost converter) that includes a single inductor (e.g., L₁), three capacitors (e.g., C₁, C₂, C₃), and four switches (e.g., S₀, S₁, S₂, S₃). The single inductor (e.g., L₁) may have a first terminal coupled to an energy source (e.g., voltage supply) 160 and a second terminal coupled to a node 152. Supply modulator 170 may be implemented with 3 switches (e.g., Sₘ₁, Sₘ₂, Sₘ₃) with one terminal of each switch connected in common at node 154. A second terminal of each of the switches may be coupled to a respective voltage node established via capacitor stack C₁, C₂, C₃ (e.g., a plurality of capacitors C₁, C₂, C₃ serially coupled between a first voltage node and ground so as to establish a plurality of voltage nodes V₁-V₃). A fourth switch (e.g., S₀) may have a first terminal coupled to node 152 and a second terminal coupled to ground. In the example of FIG. 1A, the second terminal of switches S₁, S₂, S₃ are coupled to respective ones of voltage nodes V₁, V₂, V₃.

In the example of FIG. 1B, node 154 is coupled to a supply terminal of a PA 185 through an optional filter circuit 180. Optional filter circuit 180 may be implemented as an LC (inductor, capacitor) filter with an inductor (e.g., L₂) connected in series with the supply input to PA 185, a resistor (e.g., R), and capacitor (e.g., C₄) connected in series with one another, and in parallel with PA 185, and a capacitor (e.g., C₅) connected in parallel with PA 185. In some embodiments, node 154 may be coupled to the supply terminal of PA 185 through other circuitry (e.g., circuitry other than or in addition to filter circuitry). In still other examples, node 154 may be directly coupled to the supply terminal of PA 185.

A ground rail 175 may be connected to various components in system 150. PA 185 may amplify an input RF signal 190 (e.g., RF_{IN}) and output the amplified RF signal as an output RF signal 195 (e.g., RF_{OUT}). Although FIG. 1B illustrates an example implementation of a system 150, the disclosure is not so limited. A person of skill in the art would recognize that there are additional ways to construct a supply generator 165, supply modulator 170, and filter circuit 180.

In some examples, the circuitry illustrated for system 150 may be used to implement at least portions of system 100 of FIG. 1A. For example, supply generator 165 of FIG. 1B may be used as supply generator 110, supply modulator 170 may be used as supply modulator 120, and optional filter 180 may be used as optional filtering or regulation circuit 130.

The systems illustrated in FIGS. 1A, 1B include two separate subsystems: (a) a supply generator that may synthesize multiple power supply voltages from a single input source, and possibly regulate one or more of those power supply voltages, and (b) one or more supply modulators that may each rapidly switch among the power supply voltages provided by the supply generator to provide a modulated supply voltage to a PA. The systems illustrated in FIGS. 1A and 1B are examples of systems that may be especially suitable for discrete supply modulation.

The manner in which these two subsystems are best implemented (or “realized”) may depend upon the power level, voltage level, and application space of the RF amplifier system. For many mobile applications (e.g., cell phones, smart phones, personal devices, and the like), it may be desirable to monolithically integrate electronic elements of both the supply generator and supply modulator on a single semiconductor die (e.g., in a CMOS process or a BCD (Bipolar-CMOS-DMOS) process). In some cases, it may be desirable to integrate electronics for the supply generator, supply modulator(s), and PAs on a single die. In other cases (e.g., at high power) it may be desirable to implement the subsystems with discrete components connected one or more printed circuit boards (PCBs).

A system (e.g., system 100 of FIG. 1A, system 150 of FIG. 1B) may include control and/or signal processing aspects not shown in FIG. 1A or 1B. For example, a change in RF PA supply voltage may typically cause a change in the RF PA gain and insertion phase, and perhaps also its memory effect characteristics. Therefore, it may be important that supply modulation (e.g., changes in PA supply voltage) be carefully coordinated with a digital pre-distortion (DPD) controller. Algorithms in a DPD controller may predict the non-idealities that may be imposed on the modulated RF signal by the RF PA, and may apply the inverse of these non-idealities. As a result, the inverse of a non-ideality may be passed through the PA (which also applies the non-ideality), resulting in an ideal or substantially ideal linear signal. Gain phase, memory, and/or other non-idealities may be compensated using DPD algorithms.

One or more controllers 155 may also operate to control switches in system 100 and/or system 150. For example, a person of skill in the art would recognize that one or more controllers may be used to control the on/off states and on/off timing of switches S₀-S₃ and/or Sₘ₁-Sₘ₃ via one or more signal lines (e.g., circuit connections) 157, for example, at high frequency. A person of skill in the art would recognize that, although only one signal line 157 is shown in FIG. 1B, system 150 may include a separate line from controller(s) 155 for each switch in system 150, to control each of the switches individually. Alternatively, some of the switches in system 150 may be controlled together with a single signal line, while others may be controlled individually with separate signal lines.

Controller(s) 155 may be used to switch on/off states and timing of switches S₀-S₃ so as to charge 3 different capacitors C₁-C₃ to three different voltages V₃-V₁, respectively. Controller(s) 155 may also be used to control on/off states and timing of switches Sₘ₁-Sₘ₃ to select from voltages V₁, V₂, V₃, respectively, for providing a selected voltage to optional filter 180 or PA 185. A person of ordinary skill in the art would appreciate that controller(s) 155 may receive one or more input signals 158, such as feedback or feedforward signals, via one or more signal lines, for use in determining how to control switches S₀-S₃ and Sₘ₁-Sₘ₃. For example, controller(s) 155 may be connected to V_{SUPPLY} to monitor the voltage at V_{SUPPLY} or the current being supplied to PA 185, and may change on/off states and/or timing of switches S₀-S₃ and/or Sₘ₁-Sₘ₃ to ensure a desired voltage or current is output. As another example, controller(s) 155 may monitor an RF signal amplitude of an RF signal (e.g., RF_{IN} 190) and adjust on/off states and/or timing of switches S₀-S₃ and/or Sₘ₁-Sₘ₃ to adjust a supply voltage or current to PA 185 based on the RF signal amplitude. A person of skill in the art would recognize that any number of signals (e.g., input voltage V_{IN}, current drawn from energy source I_{IN}, inductor current (i_{L1} and/or i_{L2}), voltages (V₁, V₂, V₃, and/or V_{SUPPLY}), current to PA 185) within system 150 may be monitored by controller(s) 155, and that controller(s) 155 may control the switches of system 150 based on these signals. In some embodiments, controller(s) 155 may comprise a feedforward current shaping controller.

A person of ordinary skill in the art would further recognize that controller(s) 155 may include circuitry and/or subsystems. For example, controller(s) 155 may have internal components, such as resistors, capacitors, inductors, diodes, comparators, oscillators, clocks, digital logic components (e.g., latches, flip flops), and/or amplifiers, for use in controlling a frequency of operation of a converter and making determinations about how to control a system (e.g., system 150) based on feedback/feedforward signal(s) 158. Controller(s) 155 may also include a voltage regulator or other power supply circuitry for powering controller(s) 155. Controller(s) 155 may further include protection subsystems, such as voltage or current protection subsystems. These subsystems may, for example, prevent over voltage or under voltage conditions from occurring or over current or under current conditions from occurring, such as by sensing when a voltage or current is exceeding a predetermined value and by, for example, shutting the converter circuit down temporarily or otherwise mitigating such a condition in order to prevent destruction of components in the circuit.

In some embodiments, controller(s) 155 may include a processor and memory. The memory may be programmed with instructions, such that the processor, when executing the instructions, controls the switches of a system (e.g., system 150) based on received feedback/feedforward signal(s) 158. In some embodiments, the components and/or subsystem of controller(s) 155 may be packaged together, such that controller(s) 155 is an integrated circuit (IC) containing these components/subsystems, for example.

Although not shown, controller(s) 155 may further receive an input command signal. For example, controller(s) 155 may be configured to receive commands from a user or other device that programs controller(s) 155 to perform certain functions, or to otherwise change the functioning of controller(s) 155. For example, controller(s) 155 may receive digital commands, such as digital control level (DCL) commands, for instructing controller(s) 155 on how to control switches of a system or for otherwise changing the functioning of controller(s) 155. Example techniques involving DCL commands are described in U.S. Pat. No. 12,069,580, titled “Power Management Control Over Transmission Line For Millimeter Wave Chip Sets For Cellular Radios,” which is commonly assigned and is hereby incorporated by reference herein in its entirety.

A person of ordinary skill in the art would further recognize that subsystems within controller(s) 155 may themselves have circuitry. For example, subsystems within controller(s) 155 may have internal components, such as resistors, capacitors, inductors, diodes, comparators, oscillators, clocks, digital logic components (e.g., latches, flip flops), and/or amplifiers, for use in controlling a frequency of operation of a converter circuit and making determinations about how to control a system (e.g., system 150) based on feedback/feedforward signal(s) 158. In some embodiments, a subsystem may itself include a processor and memory. The memory may be programmed with instructions, such that the processor, when executing the instructions, can output signals and/or commands based on certain input signals being received by the subsystem.

In some embodiments, one or more controllers may be used to operate some of the switches in a system (e.g., system 150), while one or more other controllers may be used to operate other switches in the system, though the disclosure is not so limited. For example, a first set of one or more controllers 155 may operate to control on/off states and on/off timing of switches S₀-S₃ via a first set of one or more signal lines (e.g., circuit connections) 157, thereby controlling supply generator 165. A second set of one or more controllers 155 may operate to control on/off states and on/off timing of switches Sₘ₁-Sₘ₃ via a second set of one or more signal lines (e.g., circuit connections) 157, thereby controlling supply modulator 170. In some embodiments, the first set of one or more controllers 155 may operate switches S₀-S₃ at a different frequency and/or duty cycle than the frequency and/or duty cycle at which the second set of one or more controllers 155 may operate switches Sₘ₁-Sₘ₃. In some embodiments, a first set of one or more controllers 155 may receive a first set of one or more feedback/feedforward signals 158 and a second set of one or more controllers 155 may receive a second set of feedback/feedforward signals 158 that may be different than the first set of feedback/feedforward signals 158.

In some embodiments, one or more controllers 155 may be implemented on the same die as one or more supply generators (e.g., supply generator 165), one or more supply modulators (e.g., supply modulator 170), one or more filters (e.g., filter 180), and/or one or more PAs (e.g., PA 185). In other cases, it may be desirable to implement one or more controllers 155 as a discrete component connected on one or more printed circuit boards (PCBs).

A variety of different switching circuits may be utilized to implement/realize a supply modulator subsystem. Two illustrative networks are shown in FIGS. 2A, 2B. FIG. 2A illustrates an example series modulator 200 having switches S₁-S₄, S₃₄, and S₂₃₄, connected as shown. FIG. 2B illustrates an example parallel modulator 240 having switches S₁-S₄ connected as shown. Additionally, filtering networks, including passive filters and/or active filters and/or additional circuits for regulating a voltage (e.g., including low-dropout regulator(s) (LDOs)) to the PA (e.g., V_{SUPPLY}) from the modulated voltage (e.g., V_{MOD}) may be utilized, as illustrated in FIGS. 1A, 1B.

Referring now to FIG. 3, in some embodiments, the modulated power supply provided to the PA (e.g., V_{SUPPLY}) may need to be “cut off” (e.g., discharged to a zero volt level). For example, this may be used to enable reduction of the modulator switch voltage ratings in cases when a zero output must be provided to the PA. In such cases, a circuit 300 may include a separate low-frequency turn-off switch 302 (or “disconnect switch”) coupled in series between an output of a supply modulator 304 (capable of sourcing modulator output voltages V₁, . . . , Vₘ) and a PA 306.

FIG. 4 shows an example implementation of the series modulator of FIG. 2A, in a form suitable for integrated circuit (IC) fabrication and for use with ratiometric supply voltages (e.g., V₂=2V₁, V₃=3V₁, V₄=4V₁). An illustrative circuit 400 includes switches S₁, S₂, and S₃ implemented as N-channel MOS (NMOS) transistors and switches S₄, S₃₄, and S₂₃₄ implemented as P-channel MOS (PMOS) transistors. Circuit 400 also includes CMOS gate drivers powered differentially among levels.

Circuit 400 illustrates the impact of the supply levels on the required voltage rating of individual modulator devices. By correct selection of the level voltages, an advantageous use of integrated CMOS processes may be made using core devices and/or extended voltage devices to achieve the required voltage blocking characteristics of the modulator switch chains. Moreover, circuit 400 illustrates the use of the generated levels for gate drive of devices (e.g., transistors). This type of drive circuit approach may facilitate high efficiency and switching speed. The possibility of incorporating NMOS-type devices may bring additional advantages of smaller size and improved performance, provided the gate drive requirements may be accommodated.

To take advantage of driving the device gates between adjacent level voltages (e.g., between Vⱼ and Vⱼ₋₁), level voltages for this design should be maintained with sufficient spacing. Otherwise, more sophisticated gate drive designs may be required, which may limit achievable switching performance. Systems, methods, circuits, devices, and techniques described herein facilitate maintaining voltage levels that are suitable for achieving integrated circuit-based modulators and high-performance gate drive circuits through the ability to maintain desired voltage relationships among the levels.

Supply generators may be realized through a variety of methods. For example, supply generators may be realized using multiple separate converters, multiple-output magnetic converters, multiple-output switched-capacitor converters, and hybrid magnetic/switched-capacitor converters providing a ratiometric set of output voltages. A further approach is to realize a multiple-output supply generator that creates two independently controllable direct current (DC) voltages (e.g., with a magnetic conversion stage) and further uses a differential capacitive energy transfer stage to realize one or more further DC supply voltages that are ratiometrically distributed between or around the two independently controllable voltages. One may generate further levels or degrees of regulation by introduction of one or more linear regulators (including series regulators and/or shunt regulators). Each of these approaches may have limitations in terms of achievable size, cost, efficiency, and/or performance (e.g., modulation bandwidth) of supply-modulated RF amplifier systems.

Use of multiple separate power converters to generate multiple supply voltages may yield a solution that is flexible, allowing each output voltage to be independently regulated to desired values independent of input voltage variations and providing the ability to continuously adjust the output voltages over time (e.g., to provide for adaptive bias of the PA). Unfortunately, this solution may be inherently large and expensive, owing to the large numbers of physically large power supply components (e.g., magnetic components) required.

Single-input multiple-output converters (sometimes referred to as “SIMO” converters) may allow multiple output voltages to be independently regulated while only requiring a single magnetic component, somewhat mitigating the size challenge of multiple power converters. However, SIMO designs may inherently utilize time-sharing of the inductor to supply the multiple outputs, and therefore performance and efficiency may degrade and control complexity may increase with increasing numbers of outputs. This characteristic may limit the efficacy of this approach in multilevel supply modulator systems, which typically utilize between three and seven supply levels to achieve high performance (with even more levels potentially desirable in some cases).

Some types of converters, such as conventional multiple-output magnetic converters (e.g., multi-output flyback converters), multiple-output switched-capacitor converters and hybrid magnetic/switched-capacitor converters may yield multiple ratiometrically related output voltages while reducing the numbers of magnetic components required as compared to using multiple independent power converters. Traditional multiple-output magnetic converters typically utilize transformers with scaled turns ratios to generate multiple ratiometrically scaled output voltages. These designs may only regulate a single output, with the ratiometric relations of the other outputs approximately maintained by the transformer turns ratios (unless additional “post regulation” is provided to the other outputs, such as through use of added linear regulators). The use of transformers tends to lower achievable efficiency in these designs (sometimes to unacceptable levels), and such designs may suffer significant cross regulation among the outputs in practice (i.e., one output voltage varying depending upon the load on a different output). This may result in undesirable performance in RF amplifier system unless additional post regulation is used, which may further degrade performance.

Multiple-output switched-capacitor converter circuits may generate multiple ratiometrically related output voltages while achieving very high efficiency and small size, with the rational (ideal) ratios among output voltages determined by the circuit topology and/or switching pattern. However, with this type of circuit, the output voltages are all scaled versions of the input voltage, which does not provide a way to continuously regulate the output voltages independent of variations in the input voltage.

Some possible limitations of these previous approaches to multiple-output supply generation may be addressed via hybrid magnetic/switched-capacitor circuits having ratiometrically scaled outputs. In these designs, a magnetic regulation stage may independently regulate a single output voltage (independent of the system input voltage) with additional ratiometrically-related output voltages synthesized and enforced through action of a switched-capacitor voltage balancer stage. For example, in an m-output supply generator, the magnetic stage may take an input voltage Vx and regulate a single output voltage V_{Y}, with the switched capacitor voltage action synthesizing (ideally) voltage k₁*V_{Y}, k₂*V_{Y}, . . . , kₘ₋₁*V_{Y}, where constants k₁, . . . , kₘ₋₁ are rational numbers that may be determined by the circuit topology and/or switching pattern. Advantages of this approach may include relatively high efficiency and small size requirements for synthesizing multiple related output voltages and relative simplicity of control.

Merits of the above design approaches notwithstanding, designs yielding ratiometric supply generator voltage outputs may have limitations for PA systems utilizing multiple level supply modulation.

One possible limitation of ratiometric outputs relates to the usable supply voltage ranges for available PAs. Some PAs may function well with wide supply voltage ranges of up to 4:1 or even larger (e.g., function well across a power supply voltage range from a maximum voltage of Vₘₐₓ down to a minimum voltage equal to or less than Vₘᵢₙ=Vₘₐₓ/4). Many other PAs-including those typically used in applications such as WiFi, mobile handset, and multiple input multiple output (MIMO) transmitters for Long Term Evolution (LTE) and 5G applications may only operate over much narrower supply voltage ranges (e.g., 3:1 or even less). With ratiometric supply voltages, if the maximum voltage generated is reduced (e.g., for conditions of reduced average PA output power), then the synthesized ratiometric voltages may be reduced proportionally. This often means that one or more of the lowest synthesized voltages may become unusable for supply modulation under such conditions, as they may fall below the allowed minimum PA power supply voltage. This in turn may reduce the achievable PA efficiency enhancements that may be provided through supply modulation under these conditions. In many applications, it may be desirable if the power supply voltages were not maintained as a fixed set of ratios, such that all (or nearly all) of the synthesized supply voltage levels may remain above the allowed minimum voltage for the PA under reduced power operation.

Another possible limitation of ratiometric outputs relates to how the spacing between voltages may vary as the largest supply voltage synthesized is reduced. In a ratiometric-output supply generator, two adjacent voltages may be expressed as kⱼ*V_{Y} and kⱼ₋₁*V_{Y}, where k is a scaling value, j is an integer index, V is a voltage, Y is an index corresponding to the number of voltage levels, V_{Y} is the Y^{th} voltage level, and where the value of V_{Y} may be scaled up or down as the average transmit power of the PA is adjusted. The difference between voltage levels may thus be expressed as (kⱼ-kⱼ₋₁)*V_{Y}, which may scale up and down proportional to V_{Y}. As described above with respect to FIG. 4, this may be problematic for driving integrated modulator switches, especially where the gate drive voltages are derived from interlevel voltages (i.e., voltage differences between levels). This may result in increased gate drive complexity in an integrated modulator, and may limit achievable switching performance of the modulator. In many applications, it may be desirable for the power supply voltages to not be maintained as a fixed set of ratios, such that the spacing between adjacent levels may be controlled independently of the maximum supply voltage synthesized.

### A Hybrid Power Supply Generator and Supply Modulator

For PA architectures using supply modulation, it may be desirable to provide a system that provides very rapid variations in modulated power supply voltage (e.g., among multiple discrete levels) while also providing the ability to slowly adapt the voltages of the discrete levels over a desired range.

In particular, and as previously discussed, it may be useful to be able to inexpensively, efficiently and/or compactly generate a set of m discrete levels for supply to a PA. In some embodiments, one of the m discrete levels may be independently controllable, and the other m-1 voltage levels may be distributed in a prescribed relation to the one independently-controlled level. In some embodiments, two of the m voltage levels may be independently controllable and the other m-2 voltage levels distributed in a prescribed relation to the two independently-controlled levels.

While not quite as flexible as truly independent control of all voltages, one would gain most of the practical benefits available from supply modulation (e.g., in terms of PA efficiency) while avoiding the above-described possible limitations associated with providing truly independent voltage level control. Such a design may provide significant advantages in combinations of size, cost, efficiency, and performance as compared to existing approaches.

It may be further beneficial if one only needed to generate one or two regulated supply voltages and be able to directly provide one or more additional supply voltage levels to the PA, without the necessity of having a separate supply generator element to generate these additional levels cascaded with a supply modulator to select among the levels. Merging the functions of intermediate level generation and supply modulation may reduce the number and size of passive components (e.g., capacitors) required as well as the number, required area, and loss of semiconductor elements (e.g., switches). Such a merged intermediate level generation and supply modulation system may be referred to herein as a “hybrid supply generator and supply modulator.” For example, switches of the hybrid supply generator and supply modulator may be controlled to generate a set of voltages V_{IN}, (2/3)*V_{IN}, and (1/3)*V_{IN}. As another example, switches of a hybrid supply generator and supply modulator may be controlled to generate voltages V_{IN} and (1/2)*V_{IN}.

It may still further be beneficial to provide a system that includes one or more hybrid supply generator and supply modulators that includes a network of switches and one or more capacitors configured as a hybrid supply generator and supply modulator and one or more controllable linear regulators. Using a linear regulator in such a system may be advantageous in that linear regulators are small in size and relatively inexpensive. By providing both a controllable linear regulator and a network of switches and one or more capacitors configured as a hybrid supply generator and supply modulator, the linear regulator may be controlled to supply a regulated voltage V_{R} at a desired level, and the network of switches and one or more capacitors may be controlled to generate and supply one or more voltages based on the regulated voltage V_{R}.

It may also be beneficial to provide one or more reconfigurable hybrid supply generator and supply modulators. In some embodiments, switches of a reconfigurable hybrid supply generator and supply modulator may be controlled to provide different sets of possible output voltages. For example, in one operating mode, switches of a hybrid supply generator and supply modulator may be controlled to generate and supply an output from a set of voltages V_{IN}, (2/3)*V_{IN}, and (1/3)*V_{IN}. In another operating mode, switches in a hybrid supply generator and supply modulator may be controlled to generate and supply voltages V_{IN} and (1/2)*V_{IN}. Providing for such switching between different operating modes to generate and supply different output voltages may be beneficial in applications where a voltage level of an energy source (e.g., battery) may vary over time (e.g., as a battery discharges/recharges), for example.

It may be further beneficial to provide one or more hybrid supply generator and supply modulators comprising one or more controllable linear regulators coupled to one or more networks of switches and capacitors configured as one or more hybrid supply generator and supply modulators. Using such a system may improve flexibility in selecting voltages to output to a load (e.g., PA), as both the output voltage V_{R} of the linear regulator and the set of possible output voltages that can be generated and supplied by the network of switches and capacitors can be controlled. That is, going back to the previous example, the first operating mode may now reconfigure the network of switches and capacitors receiving an input voltage V_{R} (generated by the linear regulator) to generate and/or supply an output voltage from a set of voltages V_{R}, (2/3)*V_{R}, and (1/3)*V_{R}, while the second operating mode may reconfigure the network of switches and capacitors to generate and/or supply an output voltage from a set of voltages V_{R} and (1/2)*V_{R}. The ability to separately control the level of the regulated voltage V_{R} and the configuration of the network of switches and capacitors may provide the ability to generate and supply an output voltage from a wide range of possible output voltages at low cost and small size (e.g., without requiring use of any magnetic components (e.g., inductors)).

Such a system including a hybrid supply generator and supply modulator comprising a controllable linear regulator and a network of switches and one or more capacitors may be beneficial in that the system provides a greater number of possible supply levels than systems using a supply generator that cannot be reconfigured. For example, in applications where the input voltage is a battery voltage, the battery voltage may vary over time. As one example, a battery voltage may initially be 5V when a battery is fully charged, but may discharge over time. If the battery has discharged such that its voltage level is 4V, it may be desirable to operate the hybrid supply generator and supply modulator in a second operating mode as described above, such that the hybrid supply generator and supply modulator can generate and supply a voltage at 2V. If the battery has discharged such that its voltage level is 3V, it may be desirable to operate the hybrid supply generator and supply modulator in a first operating mode as described above, such that the hybrid supply generator and supply modulator can generate and supply a voltage at 2V, because half of 3V (1.5V) (as would be generated by the second operating mode) may be too low to drive components of a system. Reconfiguring a hybrid supply generator and supply modulator between different operating modes may also have advantages when the amount of power to be supplied to a PA varies (e.g., using envelope tracking to change the power to the PA as the RF amplitude input to the PA varies).

As discussed above, it may be advantageous to provide a low-cost power supply system that may yield high performance in applications such as mobile WiFi systems or cellular systems, where size and cost may be constraints. One might just use a linear regulator coupled between a battery and a PA to provide a fixed power supply. However, as discussed above, such a solution may be inefficient as the linear regulator dissipates power to provide the desired output voltage.

Systems, methods, circuits, devices, and techniques disclosed herein provide for power supply designs that provide efficient discrete supply modulation with reduced cost and/or smaller size.

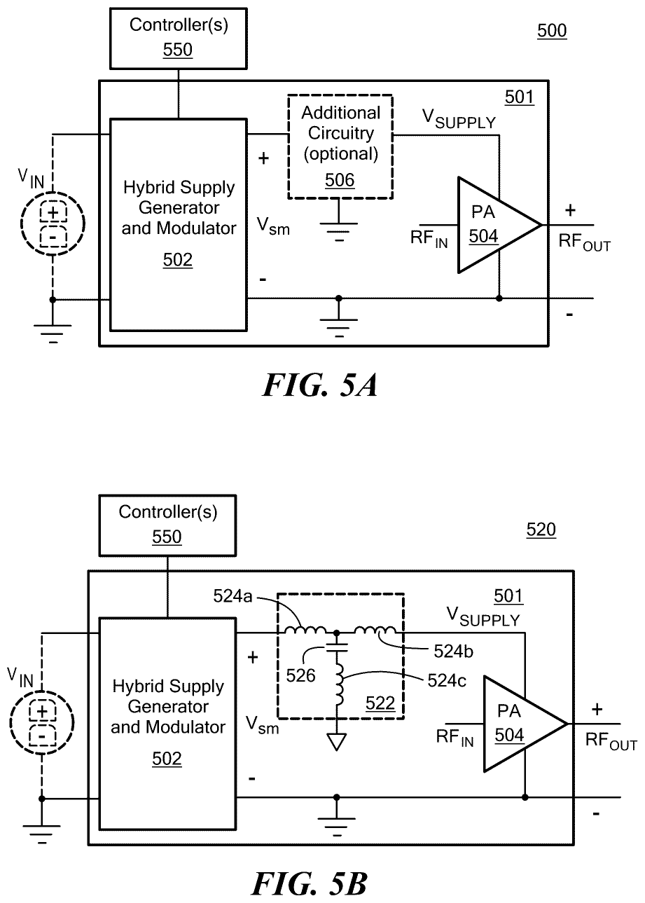

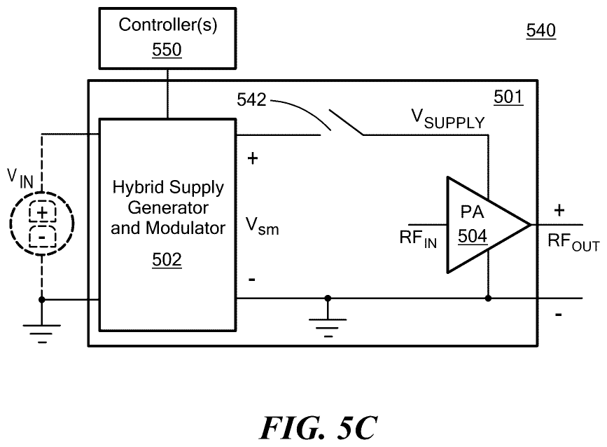

FIG. 5A is a diagram of an example RF amplifier system (or “RF module”) comprising a hybrid supply generator and supply modulator 502 configured to generate and provide a modulated supply voltage V_{SM} to a PA 504. In some embodiments, the hybrid supply generator and supply modulator 502 may comprise a hybrid magnetic/switched-capacitor converter that may synthesize three or more discrete levels (which may be related discrete voltage levels) at its output (i.e., voltage V_{SM} may correspond to one of three or more discrete voltage levels at any instant in time). As described above, voltage V_{SM} may be based upon a pair of two independently controlled direct current (DC) supply voltages that it synthesizes from an input voltage V_{IN}. In some implementations, one of the two DC supply voltages may be directly equal to voltage V_{IN}, and the second supply voltage may be independently controlled.

Of note, “hybrid magnetic/switched-capacitor converters” are a broad class of converters. Disclosed systems described as “hybrid supply generator and supply modulator” in some cases may be considered a specific and subtype of this broad class, and in other cases may include hybrid magnetic/switched-capacitor converters along with other elements (e.g., linear regulators, switched-capacitor converters, etc.). Also of note, in the term, “hybrid magnetic/switched-capacitor converters,” the word “hybrid” refers to hybridization of a magnetic converter and a switched-capacitor converter together. In contrast, in the term “hybrid supply generator and supply modulator,” the word “hybrid” refers to hybridization of the supply generator and supply modulator. Disclosed systems described as “hybrid supply generator and supply modulator” in some cases may comprise a network of switches and one or more capacitors (in some cases along with other elements such as one or more linear regulators and/or switched-capacitor converters), and in some cases may not include a magnetic component.

As shown in FIG. 5A, system 500 may optionally include additional circuitry 506 coupled between an output of hybrid supply generator and supply modulator 502 and PA 504. Additional circuitry 506 may comprise, for example, a disconnect switch, filtering network(s) including passive filters and/or active filters, low-dropout regulator(s), LDO(s), and/or additional means of regulating or controlling the PA supply voltage, V_{SUPPLY}, from the modulated voltage, V_{SM}. In some embodiments, additional circuitry 506 may have more than two terminals. For example, additional circuitry 506 may optionally be connected to ground, as shown.

System 500 may also include one or more controllers 550 to operate switches and/or other devices of hybrid supply generator and supply modulator 502 using control techniques described in detail below. For example, the one or more controllers 550 may implement, execute, or otherwise utilize one or more state machines (examples of which are described herein) for modulating V_{SM}. In some embodiments, hybrid supply generator and supply modulator 502 may include a multi-output regulation stage (or “first stage”) and a differential multilevel converter (or “second stage”) and one or more controllers 550 may include at least one controller to control the switching state of the multi-output regulation stage and at least one controller to control the switching state of the differential multilevel converter. These may be the same controller or different controllers. In some embodiments, at least one of controller(s) 550 may be configured to receive commands (e.g., from a DPD controller over a DCL interface) for selecting and/or controlling a voltage level of the modulated voltage V_{SM}. In some embodiments, controller(s) 550 may be configured as controller(s) 155 (previously discussed), though the disclosure is not so limited. As discussed with respect to controller(s) 155, controller(s) 550 may include one or more signal lines for controlling one or more switches of a hybrid supply generator and supply modulator. As also discussed with respect to controller(s) 155, controller(s) 550 may receive one or more signals including feedforward and/or feedback signals regarding one or more characteristics of the converter, and may modify one or more aspects of the converter accordingly (e.g., by controlling switches of the converter) to achieve a desired output.

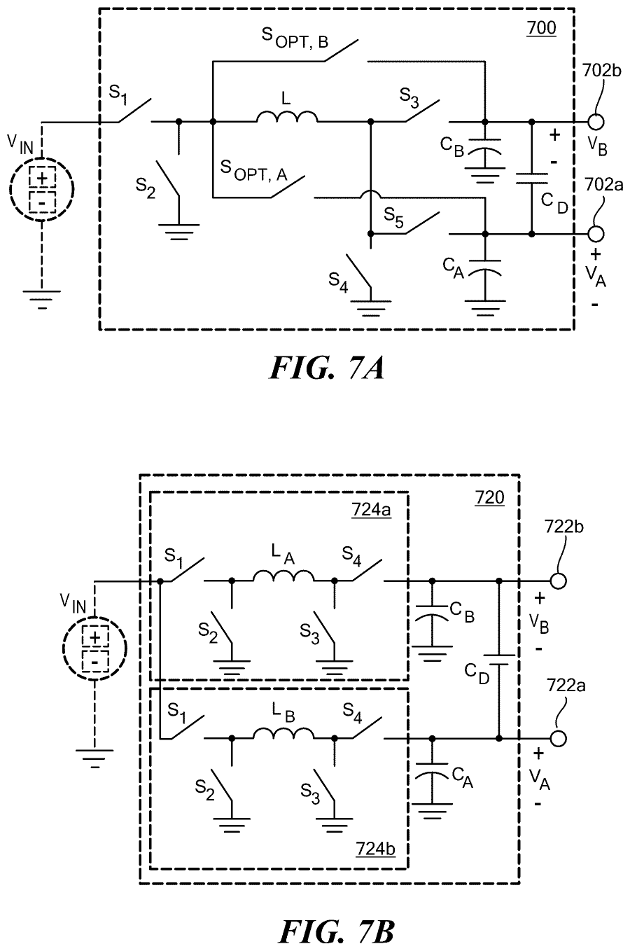

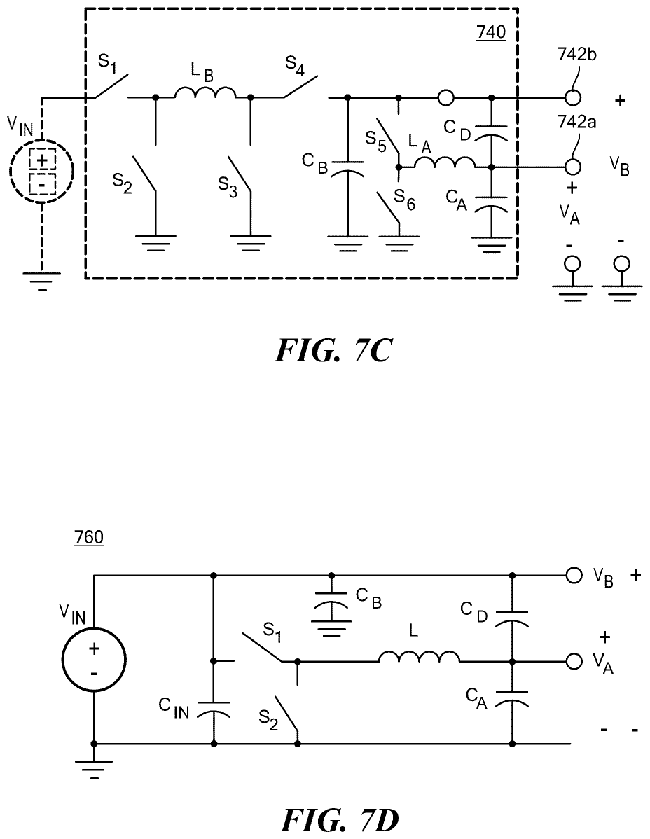

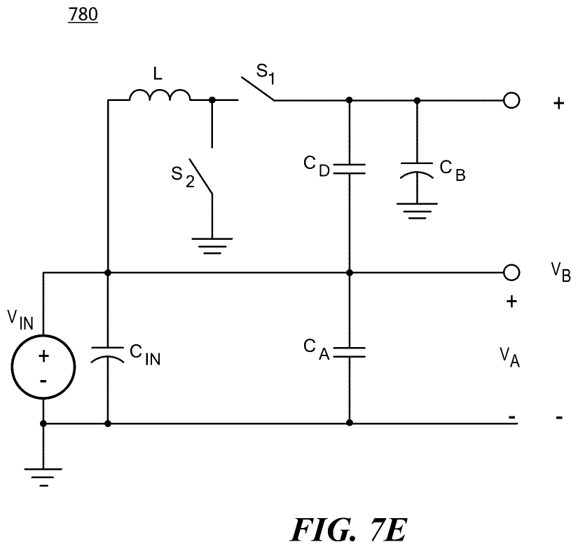

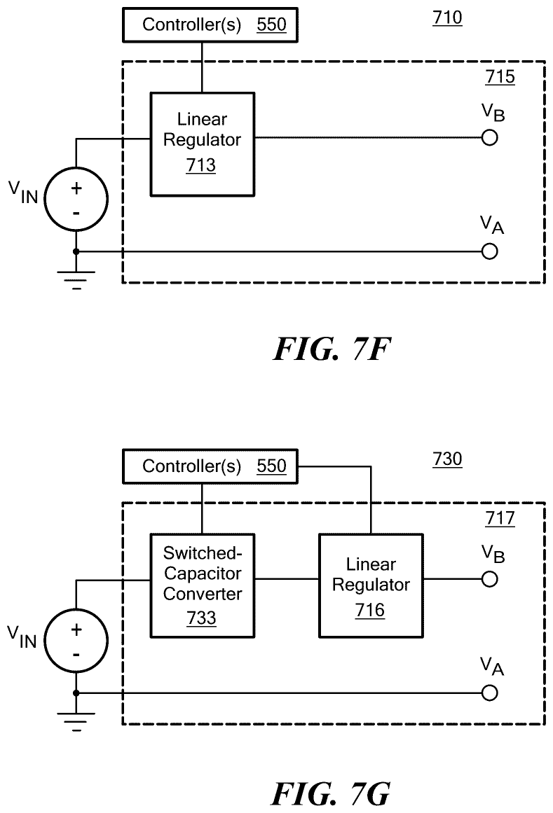

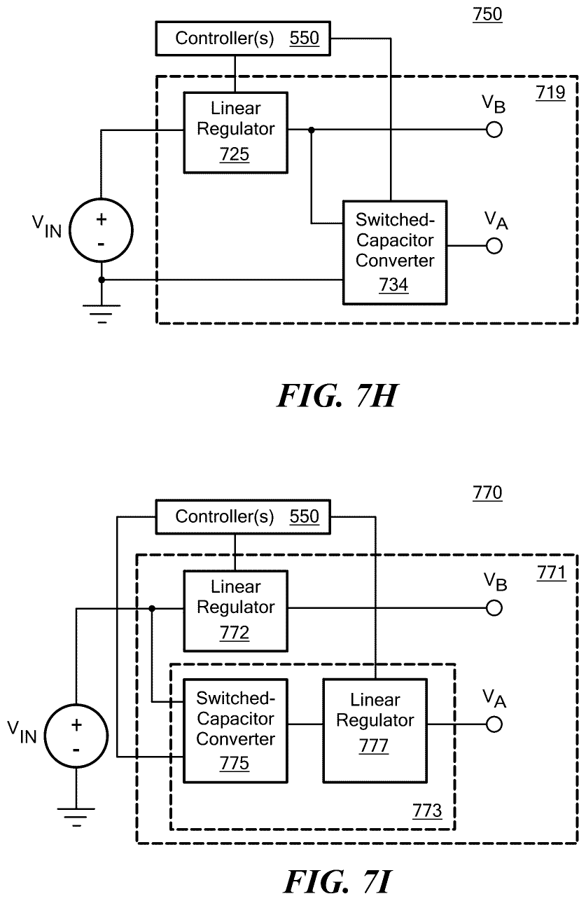

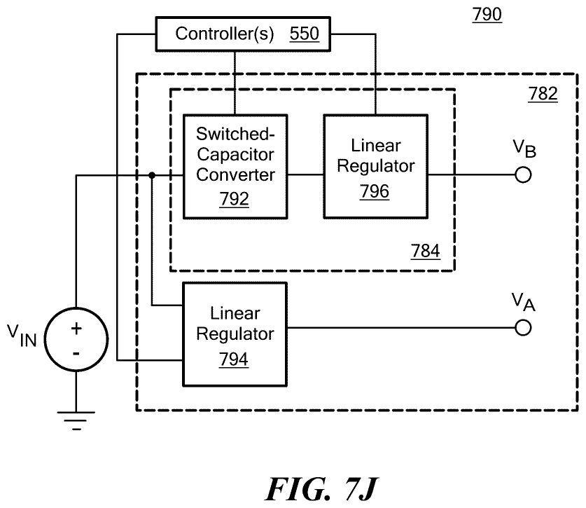

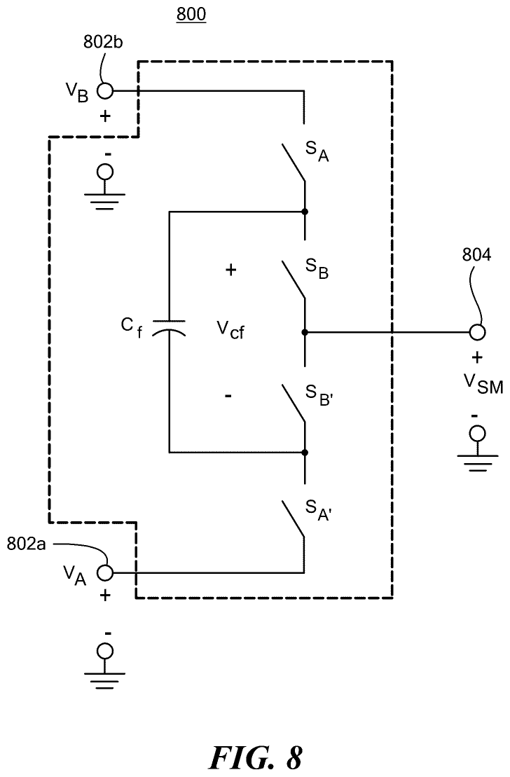

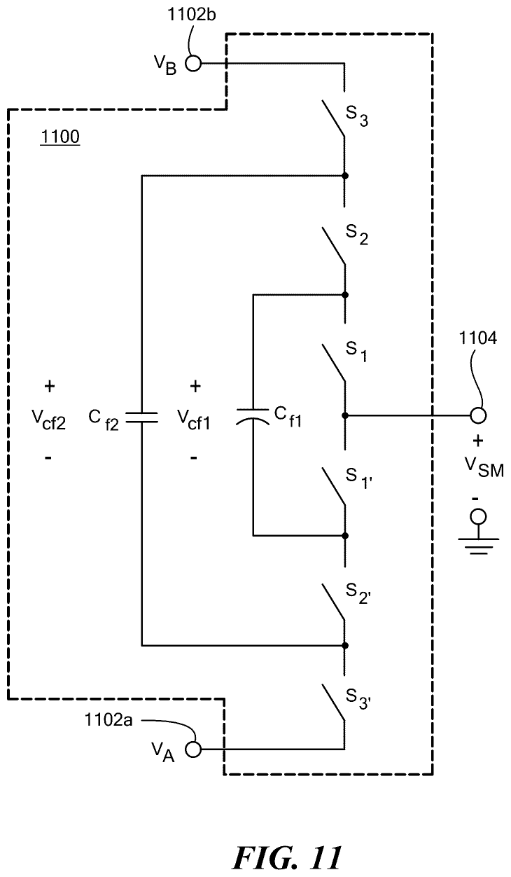

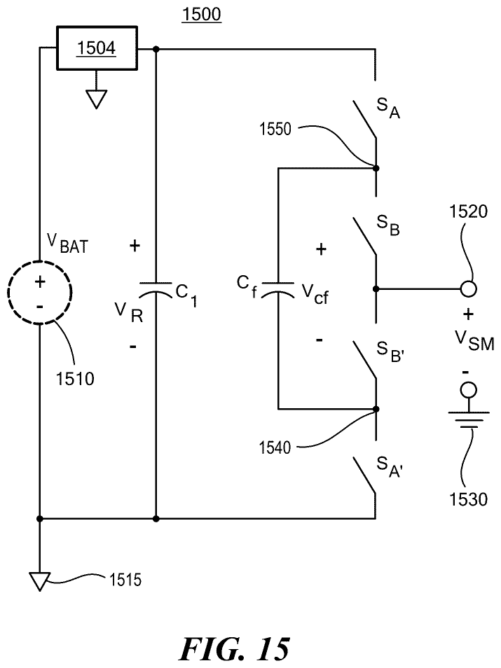

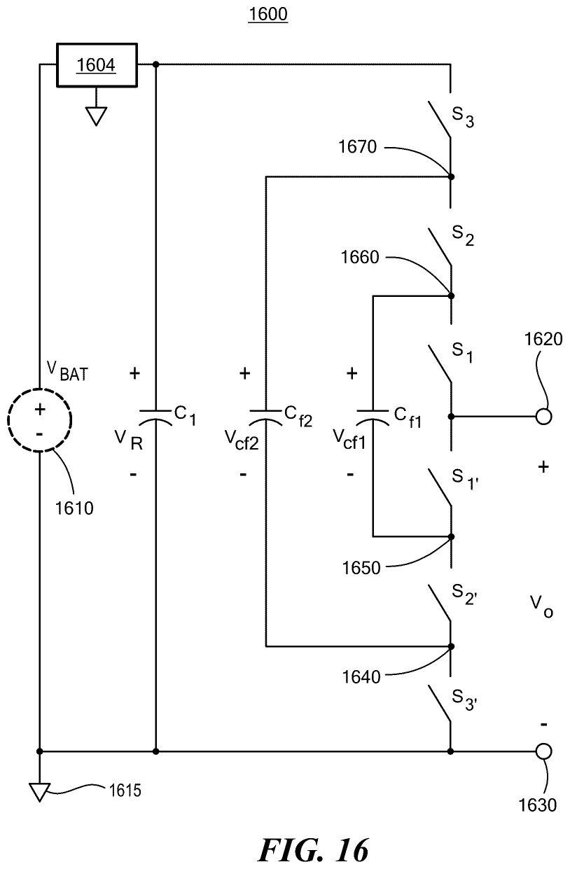

In some embodiments, controller(s) 550 may include a digital controller configured to provide one or more control signals to one or more hybrid supply generator and supply modulators. In response, the hybrid supply generator and supply modulators may provide variable supply voltages to one or more RF amplifiers. That is, the control signals may be used to select discrete supply voltages for the amplifiers from among multiple independent supply voltages generated by the hybrid supply generator and supply modulators. In more detail, the control signals may be used to directly, or indirectly, operate one or more switches within the hybrid supply generator and supply modulator (e.g., switches within a regulation stage such as illustrated in any of FIGS. 7A-7J and/or switches within the multilevel converter such as illustrated in FIG. 8, FIG. 11, FIG. 15, or FIG. 16).

FIG. 5B shows an example RF amplifier system 520 similar to that of FIG. 5A, wherein additional circuitry 506 is implemented as a filter network 522. Illustrative filter network 522 includes first and second inductors 524a, 524b connected in series between an output of hybrid supply generator and supply modulator 502 and an input of PA 504. Filter network 522 further includes a capacitor 526 having one terminal connected between first and second inductors 524a, 524b, and a third inductor 524c connected between the other terminal of capacitor 526 and ground. Filter network 522 may sometimes be referred to as a pulse-shaping network (PSN).

Filter network 522 of FIG. 5B is merely one example and other types of filter networks may be used. For example, a reconfigurable filter may be used, whereby one or more switches are configured to change the filtering parameters (or characteristics) of the filter network.

FIG. 5C shows an example RF amplifier system 540 similar to that of FIG. 5A, wherein additional circuitry 506 is implemented as a PA turn-off switch 542 (or “disconnect” switch). As previously discussed, in some cases, the modulated power supply provided to the PA (e.g., V_{SUPPLY}) may need to be “cut off” (discharged to a zero-volt level). For example, this may be used to enable reduction of the modulator switch voltage ratings in cases when a zero output must be provided to the PA. In such cases, a low-frequency turn-off switch 542 may be connected in series between an output of hybrid supply generator and supply modulator 502 and an input of PA 504, as shown. Turn-off switch 542 may be used to selectively isolate the output of the multi-output regulation stage from the RF amplifier.

In some embodiments, RF amplifier system 540 may be part of a transceiver system having a modem among other components external to the RF amplifier system. The modem or another one of the components may directly or indirectly generate control signals to cause the turn-off switch 542 to be actuated in conjunction with enabling/disabling the RF amplifier.

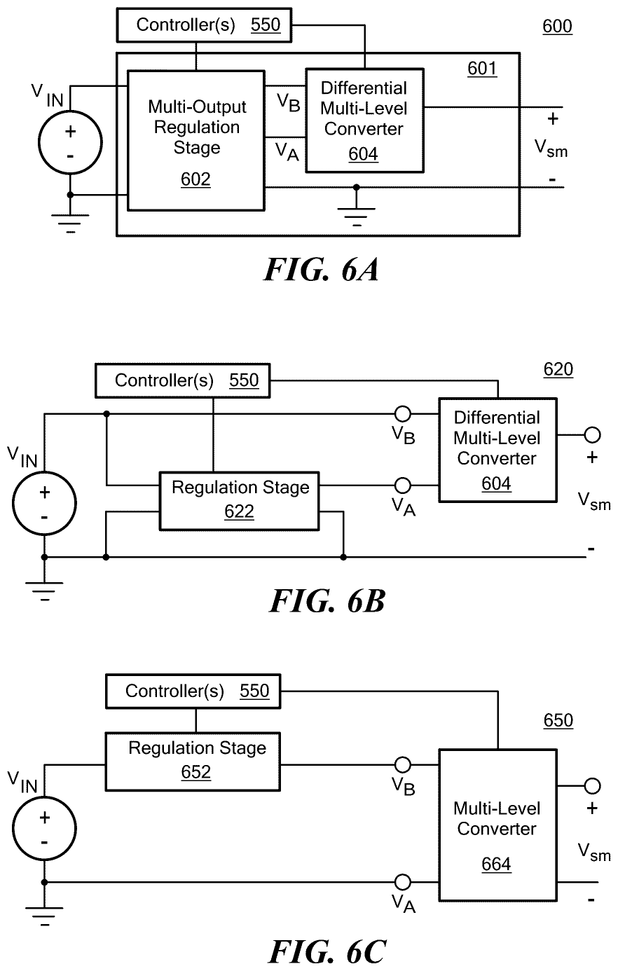

FIG. 6A shows an example system 600 including a hybrid supply generator and supply modulator 601, according to some embodiments. Illustrative hybrid supply generator and supply modulator 601 may be provided within system 500 of FIG. 5A, system 520 of FIG. 5B, or system 540 of FIG. 5C, for example. For example, hybrid supply generator and supply modulator 601 of FIG. 6A may correspond in whole or in part to hybrid supply generator and supply modulator 502 of FIG. 5A, 5B, or 5C.

Illustrative hybrid supply generator and supply modulator 601 includes a multi-output regulation stage 602 and a differentially coupled multilevel converter 604.

Multi-output regulation stage 602 is configured to receive, couple, or otherwise take an input voltage V_{IN} and synthesize two intermediate voltages V_{A} and V_{B}. In some embodiments, intermediate voltages V_{A} and V_{B} may be independently controllable. In some embodiments, multi-output regulation stage 602 may be provided as a magnetic or hybrid magnetic/switched-capacitor regulation stage. In some embodiments, multi-output regulation stage may comprise one or more linear regulators, or one or more linear regulators and one or more switched-capacitor converters, as further discussed herein.

Differentially coupled multilevel converter 604 has input differentially connected or otherwise coupled between intermediate voltages V_{A} and V_{B} and is configured to synthesize three or more instantaneous output voltage levels V_{SM} therefrom. In some embodiments, differentially coupled multilevel converter 604 may use switched capacitors to synthesize instantaneous levels while enabling desired voltage/charge-balance on the capacitors. Differentially coupled multilevel converter 604 may be based on a differentially connected flying-capacitor multilevel converter (FCML) or on some other capacitor-based energy-transfer topology, including those in which the charge transfer requirements prevent one or more of the synthesizable levels to be continuously provided without switching of the differentially connected multilevel converter.

Multi-output regulation stage 602 and differentially coupled multilevel converter 604 may include one or more devices (e.g., switches) configured to be controlled according to one or more control techniques described in detail below.

Multi-output regulation stage 602 and/or differential multilevel converter 604 may be controlled by one or more controllers, such as controller(s) 550 of FIG. 5.

FIG. 6B is a diagram of another system 620 including a hybrid supply generator and supply modulator, wherein one of the intermediate voltages directly corresponds to the input voltage. The illustrative hybrid supply generator and supply modulator of FIG. 6B may be provided within system 500 of FIG. 5A, system 520 of FIG. 5B, or system 540 of FIG. 5C, for example. As shown, the input voltage V_{IN} may be provided as input to a regulation stage 622 and also connected to provide intermediate voltage V_{B} to differential multilevel converter 604. The other intermediate voltage V_{A} provided to differential multilevel converter 604 may be generated by regulation stage 622. In other words, voltage V_{B} may be said to bypass regulation stage 622. Regulation stage 622 may be similar to any of the multi-output regulation stage implementations described herein or portions thereof, but adapted to have only a signal output and associated circuitry. While FIG. 6B shows an example where V_{B} corresponds to V_{IN}, in other examples the same general approach may be used to have V_{A} correspond to V_{IN}.

FIG. 6C is a diagram of still another system 650 including a hybrid supply generator and supply modulator, wherein one of the intermediate voltages corresponds to a ground potential voltage (e.g., 0V). The illustrative hybrid supply generator and supply modulator of FIG. 6C may be provided within system 500 of FIG. 5A, system 520 of FIG. 5B, or system 540 of FIG. 5C, for example. As shown, the input voltage V_{IN} may be provided as input to a regulation stage 652. Regulation stage 652 may then generate a voltage V_{B} from input voltage V_{IN}, and provide voltage V_{B} as an input to multi-level converter 664. A ground reference potential voltage (e.g., 0V) may connected to multi-level converter 664 as an input voltage V_{A}. Regulation stage 652 may be similar to any of the multi-output regulation stage implementations described herein or portions thereof, but adapted to have only a signal output and associated circuitry.

Multi-output regulation stage 602 and/or differential multilevel converter 604 may be controlled by one or more controllers, such as controller(s) 550 of FIG. 5A.

Referring now to FIGS. 7A-7J, shown are implementations of example regulation stages which may be provided within a hybrid supply generator and supply modulator. For example, any of the regulation stages shown in FIG. 7A-7C, 7H, 7I, or 7J may be provided as multi-output regulation stage 602 of FIG. 6A, in accordance with embodiments of the present disclosure. As another example, any of the regulation stages shown in FIG. 7D or 7E may be provided as regulation stage 622 of FIG. 6B. As still another example, any of the regulation stages shown in FIG. 7F or 7G may be provided as regulation stage 652 of FIG. 6C.

FIG. 7A is a diagram of an example magnetic regulation stage that may be used in a hybrid supply generator and supply modulator. FIG. 7A shows a multi-output regulation stage 700 comprising a two-output single-input-multiple-output (SIMO) converter based upon a 4-switch buck-boost converter, but with an additional output and switch. Multi-output regulation stage 700 has two outputs 702a and 702b (e.g., terminals) at which respective ones of synthesized voltages V_{A} and V_{B} may be provided. A first switch S₁ is connected between a voltage source, V_{IN}, and an inductive element, L. A second switch S₂ is connected at one end between S₁ and L and at the other end to ground (or, more generally, to a reference voltage). A third switch S₃ is connected between L and an output 702b (providing a voltage V_{B}). A fourth switch S₄ is connected at one end between L and S₃ and at the other end to ground. A fifth switch S₅ is connected at one end between S₄, L, and S₃ and at the other end to another output 702a (providing a voltage V_{A}). Independent decoupling capacitors C_{A} and C_{B} may be connected to respective outputs 702a and 702b, as shown.

As shown, additional optional switches S_{opt,A} and S_{opt,B} may be included to enable direct energy transfer from output 702a to output 702b or vice versa. Also as shown, a differential decoupling capacitor C_{D} may be optionally included and connected across the two outputs 702a, 702b.

FIG. 7B is a diagram of another example magnetic regulation stage that may be used in a hybrid supply generator and supply modulator. FIG. 7B illustrates a multi-output regulation stage 720 having two outputs 722a and 722b (e.g., terminals) at which respective ones of voltages V_{A} and V_{B} may be provided. The voltages V_{A} and V_{B} may be synthesized using separate 4-switch buck-boost converters 724a and 724b, respectively. As shown, each buck-boost converter 724a, 724b has four switches S₁-S₄ and an inductive element (L_{A} or L_{B}). Optional output decoupling capacitors C_{A}, C_{B}, and/or C_{D} may also be provided, as shown.

While the embodiment of FIG. 7B includes two buck-boost converters, depending upon voltage range requirements, two different types of converters may be used. For example, in other embodiments, one converter may be implemented as a 4-switch buck-boost converter, while the other converter may be implemented either as a simple buck converter (e.g., to supply the smaller of the two voltages V_{A} and V_{B}) or as a simple boost converter (to supply the larger of the two voltages V_{A} and V_{B}).

FIG. 7C is a diagram of still another example magnetic regulation stage that may be used in a hybrid supply generator and supply modulator. FIG. 7C illustrates a multi-output regulation stage 740 which includes a 4-switch buck-boost converter to synthesize a first output voltage V_{B} at an output 742b and includes a buck converter powered from voltage V_{B} to synthesize a second independently regulated voltage V_{A} at another output 742a, where V_{A} is less than or equal to V_{B}. In more detail, the buck-boost converter comprises switches S₁-S₄ and inductive element L_{B}, whereas the buck converter comprises switches S₅, S₆ and inductive element L_{A}. Optional output decoupling capacitors C_{A}, C_{B}, and/or C_{D} may also be provided, as shown.

It should be appreciated that other like conversion approaches may be used to synthesize two independently controllable voltages V_{A} and V_{B}. For example, the structure of FIG. 7C may be adapted such that the initial buck-boost stage is omitted, and the input (V_{IN}) is directly connected to capacitor C_{B}, such that voltage V_{B} equals the input voltage and voltage V_{A} is independently controllable. Like structures may be created such that voltage V_{A} equals the input voltage and voltage V_{B} is independently controllable (e.g., derived from voltage V_{A} with a boost converter).

FIG. 7D is a diagram of a further example magnetic regulation stage that may be used in a hybrid supply generator and supply modulator. FIG. 7D illustrates a multi-output regulation stage 760 wherein a voltage V_{B} directly corresponds to the input voltage V_{IN} and voltage V_{A} is generated from V_{IN} using a buck converter such that V_{A}<V_{B}. The buck converter may include, for example, an input capacitor C_{IN}, a pair of switches S₁, S₂, and an inductor L, connected as shown. Output decoupling capacitors C_{A}, C_{B}, and/or C_{D} may optionally be provided.

FIG. 7E is a diagram of a still further example magnetic regulation stage that may be used in a hybrid supply generator and supply modulator. FIG. 7E illustrates a multi-output regulation stage 780 wherein a voltage V_{A} directly corresponds to the input voltage V_{IN} and a voltage V_{B} is generated from V_{IN} using a boost converter such that V_{A}<V_{B}. The boost converter may include, for example, a pair of switches S₁, S₂, an inductor L, and at least one of capacitors C_{B} or C_{D}, connected as shown. Decoupling capacitors C_{A} and/or C_{IN} may optionally be provided.

Of note, whereas the hybrid supply generator and supply modulator 620 of FIG. 6B provides the input voltage as one of the intermediate voltages by bypassing regulation stage 622, the same result may be achieved without bypassing the regulation stage, such as using the regulation stage implementation of FIG. 7D or FIG. 7E.

The various switches illustrated in FIGS. 7A-7E may be controlled by one or more controllers, such as by one or more controllers 550 of FIG. 5A, 5B, 5C, 6A, 6B, or 6C. For example, one or more controllers may generate control signals that are coupled to selectively turn individual switches on or off.

FIGS. 7F-7J provide diagrams of example non-magnetic regulation stages that may be used in a hybrid supply generator and supply modulator. For example, while magnetic regulation stages may be efficient, the inductive components of these regulators may make them too bulky and/or expensive for some applications. As previously discussed, it may be advantageous to provide a low-cost power supply system that may yield high performance in applications such as mobile WiFi systems or cellular systems, where size and cost may be constraints. Systems, methods, circuits, devices, and techniques disclosed herein provide for power supply designs that provide efficient discrete supply modulation with reduced cost and/or size.

FIG. 7F is a diagram 710 of an example non-magnetic regulation stage that may be used in a hybrid supply generator and supply modulator. In some embodiments, regulation stage 652 of FIG. 6C may be implemented as regulation stage 715 of FIG. 7F, though the disclosure is not so limited. Regulation stage 715 may include a linear regulator 713, such as a low dropout (LDO) regulator, for outputting a regulated voltage V_{B}. A linear regulator may receive input voltage V_{IN} from an energy source (e.g., battery) and may output an output voltage (e.g., V_{R}, or V_{B} in FIG. 7F) lower than the input voltage. As is known, a linear regulator may include one or more transistors (e.g., metal oxide semiconductor (MOS) transistors), such that the bias of the transistor(s) may be adjusted by one or more controllers (e.g., controller(s) 550) to cause a voltage drop within the linear regulator and to thereby output a desired output voltage lower than the input voltage. That is, one or more transistors within the linear regulator may operate similar to resistors, except that the resistance (and associated dissipative loss/voltage drop) of the linear regulator may be adjusted by adjusting the bias of the transistor(s). In some embodiments, the output voltage of the linear regulator may be set by an output reference voltage. In some embodiments, this output reference voltage may be selected from among multiple discrete regulation points (e.g., a feedback signal for the controller controlling the linear regulator may be sensed at different nodes in the system). A person of ordinary skill in the art would recognize that a variety of different types of linear regulators are known, and any of these known types should be considered to be within the scope of the disclosure herein.

As shown in FIG. 7F, a separate voltage of 0V or ground may be output from a negative terminal of an energy source V_{IN} as a second voltage V_{A}. One or more controller(s) 550 may be used to control linear regulator 713 to output a desired voltage V_{B}.

FIG. 7G is a diagram 730 of another example non-magnetic regulation stage that may be used in a hybrid supply generator and supply modulator. In some embodiments, regulation stage 652 of FIG. 6C may be implemented as regulation stage 717 of FIG. 7G, though the disclosure is not so limited. Regulation stage 717 may include one or more switched capacitor converters (e.g., switched capacitor converter 733) and one or more linear regulators (e.g., linear regulator 716). A switched capacitor converter may be less lossy than a linear regulator. Thus, there may be efficiency gains in using a switched capacitor converter (e.g., switched capacitor converter 733) in cascade with a linear regulator (e.g., linear regulator 716). Switched capacitor converter 733 may operate to output a voltage that is proportional (e.g., with a proportionality constant that is a rational number) to the input voltage V_{IN} (e.g., a ratio of V_{IN})—or output a current that is proportional to its input current, and linear regulator 716 may further operate to output a regulated voltage V_{B} that may be set to any of a variety of discrete voltage levels. Using a switched capacitor converter in cascade with a linear regulator may increase the number of components in a regulator, but may make the regulator more efficient since the linear regulator does not have to generate as much loss in producing a desired output voltage V_{B}. It should also be noted that in some instances linear regulator 716 may be omitted, and the switching frequency and/or duty ratio employed in switched-capacitor converter 733 may be adjusted to regulate the output of the switched-capacitor converter to a desired voltage, providing the equivalent function to the cascade of a switched-capacitor converter and linear regulator.

As shown in FIG. 7G, a separate voltage of 0V or ground may be output from a negative terminal of an energy source V_{IN} as a second voltage V_{A}. One or more controller(s) 550 may be used to control the switches in switched capacitor converter 733 to reconfigure switched capacitor converter 733 to output a desired voltage and/or may control linear regulator 716 to output a desired voltage V_{B}.

FIG. 7H is a diagram 750 of still another example non-magnetic regulation stage that may be used in a hybrid supply generator and supply modulator. In some embodiments, regulation stage 602 of FIG. 6A may be implemented as regulation stage 719 of FIG. 7H, though the disclosure is not so limited. Regulation stage 719 may include a linear regulator 725 (e.g., LDO) coupled to an energy source V_{IN} to generate an output voltage V_{B}, and a switched capacitor converter 734 connected to linear regulator 725 in cascade to generate an output voltage V_{A}. Thus, regulator 719 of FIG. 7H is an example of a multi-output regulator. As discussed above with respect to FIG. 7G, a switched capacitor converter may be less lossy than a linear regulator. Thus, there may be efficiency gains in using a switched capacitor converter (e.g., switched capacitor converter 734) in cascade with linear regulator 725 to generate output voltage V_{A}. Switched capacitor converter 734 may output one or more voltages that are proportional (e.g., with a proportionality constant that is a rational number) to the output of linear regulator 725, or may be controlled (via modulating a switching frequency and/or duty ratio) to provide one or more voltages that deviate from being proportional to the output of linear regulator 725. Thus, the regulator approach in FIG. 7H may also be advantageous in that two or more output voltages may be generated without having to introduce additional linear converters.

FIG. 7H also illustrates switched capacitor converter 734 as being connected to ground. In some embodiments, an internal switch in switched capacitor converter 734 may be controlled to directly couple ground to its output, such that a ground voltage (e.g., 0V) is optionally output as voltage V_{A}.

One or more controllers 550 may be used to control the switches in switched capacitor converter 734 to reconfigure switched capacitor converter 734 to output a desired voltage V_{A} and/or may control linear regulator 725 to output a desired voltage V_{B} and/or to output a desired input voltage to switched capacitor converter 734.

FIG. 7I is a diagram 770 of a further example non-magnetic regulation stage that may be used in a hybrid supply generator and supply modulator. In some embodiments, regulation stage 602 of FIG. 6A may be implemented as regulation stage 771 of FIG. 7I, though the disclosure is not so limited. Regulation stage 771 may include two linear regulators 772, 777 and a switched capacitor converter 775. One of the linear regulators (linear regulator 772) may be coupled to an energy source V_{IN} and may output a voltage V_{B}. A switched capacitor converter 775 may be coupled between the energy source and linear regulator 777, and linear regulator 777 may output a voltage V_{A}. Thus, regulator 770 of FIG. 7I is an example of a multi-output regulator. As discussed above, a switched capacitor converter may be less lossy than a linear regulator. Thus, there may be efficiency gains in using a switched capacitor converter (e.g., switched capacitor converter 775) in cascade with a linear regulator (e.g., linear regulator 777 outputting V_{A}) to generate an output voltage V_{A}. Switched capacitor converter 775 may output one or more voltages that are proportional (e.g., with a proportionality constant that is a rational number) to the input voltage V_{IN}. As discussed above, linear regulator 777 in 773 may optionally be eliminated and output V_{A} may be controlled by modulated operation of switched-capacitor converter 775.

One or more controllers 550 may be used to control the switches in switched capacitor converter 775 to reconfigure switched capacitor converter 775 to output a desired voltage to linear regulator 777 outputting voltage V_{A}, to control linear regulator 772 to control the voltage V_{B} output from linear regulator 772, and/or to control linear regulator 777 to control the voltage V_{A} output from linear regulator 777 and/or to control switched-capacitor converter 775 to control the voltage V_{A}.

FIG. 7J is a diagram 790 of a still further example non-magnetic regulation stage that may be used in a hybrid supply generator and supply modulator. In some embodiments, regulation stage 602 of FIG. 6A may be implemented as regulation stage 782 of FIG. 7J, though the disclosure is not so limited. Regulation stage 782 may include two linear regulators 794, 796 and a switched capacitor converter 792. A linear regulator 794 may be coupled to an energy source V_{IN} and may output a voltage V_{A}. A switched capacitor converter 792 may be coupled between the energy source and linear regulator 796, and linear regulator 796 may output a voltage V_{B}. Thus, regulator 782 of FIG. 7J is an example of a multi-output regulator. As discussed above, a switched capacitor converter may be less lossy than a linear regulator. Thus, there may be efficiency gains in using a switched capacitor converter (e.g., switched capacitor converter 792) in cascade with a linear regulator (e.g., linear regulator 796 outputting V_{B}) to generate an output voltage V_{B}. Switched capacitor converter 792 may output one or more voltages that are proportional (e.g., with a proportionality constant that is a rational number) to the input voltage V_{IN}. As discussed above, linear regulator 796 in 784 may optionally be eliminated and output V_{B} may be controlled by modulated operation of switched-capacitor converter 792.

One or more controllers 550 may be used to control the switches in switched capacitor converter 792 to reconfigure switched capacitor converter 792 to output a desired voltage to linear regulator 796 outputting voltage V_{B}, to control linear regulator 796 to control the voltage V_{A} output from linear regulator 796, and/or to control the linear regulator 794 to control the voltage V_{B} output from linear regulator 794 and/or to control switched-capacitor converter 792 to control the voltage V_{B}.

In some embodiments, a cascaded linear regulator and switched capacitor converter (e.g., switched capacitor converter 733 and linear regulator 716, switched capacitor converter 775 and linear regulator 777, switched capacitor converter 792 and linear regulator 796) may be replaced by a regulating switched capacitor converter. For example, the cascaded switched capacitor converter 733 and linear regulator 716 of FIG. 7G, the cascaded switched capacitor converter 775 and linear regulator 777 of FIG. 7I (773), and/or the cascaded switched capacitor converter 792 and linear regulator 796 of FIG. 7J (784) may be replaced by a regulating switched capacitor converter. One or more controllers 550 may control a regulating switched capacitor converter, such as by controlling a frequency and/or duty ratio at which switches of a switched capacitor converter are operated, to regulate one or more outputs of a switched capacitor converter. A regulating switched capacitor converter may be more efficient than a linear regulator, and may allow a similar variety of output voltages to be generated as a linear regulator, though at the possible tradeoff of increased complexity and number of components.

FIG. 8 shows an example structure of an illustrative multilevel converter 800, which may be used in a hybrid supply generator and supply modulator. Multilevel converter 800 may be the same as or similar to the differential multilevel converter described in conjunction with FIG. 6A or 6B, for example. Multilevel converter operates from two voltages V_{A} and V_{B} received at respective inputs 802a and 802b (e.g., terminals). The two voltages V_{A}, V_{B} may, for example, be synthesized by a multi-output regulation stage, which may be the same as or similar to one of the multi-output regulations stages described above in conjunction with FIG. 7A-7C, 7H, 7I, or 7J, for example. Alternatively, a voltage V_{B} or V_{A} may be synthesized by a regulation stage, with the other of voltage V_{B} or V_{A} corresponding to an input voltage V_{IN}, as discussed with respect to FIG. 7D or 7E, for example. When voltages V_{A}, V_{B} correspond to different non-zero voltage levels, multilevel converter may be referred to as a differential multilevel converter. In some embodiments, input 802a may be coupled to a V_{A} of ground, or 0V, such as by connecting to a V_{A} terminal of a regulation stage of FIG. 7F or 7G, for example. In such an embodiment, multilevel converter 800 may be the same or similar to the multilevel converter described in conjunction with FIG. 6C, for example. In some embodiments, voltage V_{B} may be controlled to be larger than voltage V_{A}. In some embodiments, V_{B} or V_{A} may correspond to an input voltage V_{IN}.

Multilevel converter 800 comprises four switches, S_{A}, S_{B}, S_{A}′, S_{B}′, connected in series between the two inputs 802a, 802b, and a flying capacitor C_{f} connected at one end between S_{A} and S_{B} and at the other end between S_{A}′ and S_{B}′. An output 804 (e.g., a terminal) may be connected between S_{B} and S_{B}′, as shown, to provide a modulated output voltage V_{SM}, which may be referenced to ground, for example. Converter 800 may optionally include a differential decoupling capacitor C_{D} (not shown) coupled between inputs 802a, 802b.

The structure of converter 800 may be partially similar to that of a flying capacitor multilevel converter (FCML) with distinctions that: (1) the output 804 is taken with discrete levels instead of being filtered to provide a continuously-variable output; and (2) the DC input 802a, 802b may be taken differentially between V_{A} and V_{B} rather than from an input source and common. The ground referenced output voltage V_{SM} may thus take on discrete values distributed between voltage values V_{A} and V_{B}, with energy transferred from and between V_{A} and V_{B} and the output 804.

The switches S_{A}, S_{B}, S_{A}′, S_{B}′ may be implemented in a variety of manners with some or all of the switches having unidirectional blocking capability. For example, one or all of the switches may be configured to block less than or equal to the maximum difference between V_{A} and V_{B}, but more than half the maximum difference therebetween.

In a complementary metal-oxide semiconductor (CMOS) or Bipolar-CMOS-DMOS (BCD) process, one or more of the switches S_{A}, S_{B}, S_{A}′, S_{B}′ may be realized as all NMOS devices or a combination of NMOS and PMOS devices, or all as PMOS devices. In some implementations, one may choose to implement switches S_{A} and S_{A}′ as a CMOS pair and switches S_{B} and S_{B}′ as a CMOS pair. Selection of a particular implementation may be based on size/performance of the switches and/or gate drive convenience of the switches, with gate-drive levels optionally derived from V_{A} and V_{B}.

In some embodiments, the multilevel converter of FIG. 8 may be operated according to four (4) different switch states, providing the output voltage V_{SM} indicated in Table 1. That is, a controller (e.g., the one or more controllers 550 of FIG. 5) may be connected and configured to turn individual switches S_{A}, S_{B}, S_{A}′, S_{B}′ on or off to achieve a given one of the states set forth in Table 1. As shown below in Table 1, the multilevel converter of FIG. 8 may be configured to provide three (3) different voltage levels L₁, L₂, and L₃.

TABLE 1

| | Switches | | | | |
|---|---|---|---|---|---|
| State | On | V_{SM} | V_{SM} = | Level | V_{cf} |
| 1 | S_{A}, S_{B} | V_{B} | V_{B} | L3 | Unchanging |
| 2 | S_{A}, S_{B}′ | V_{B} − V_{cf} | (V_{A} + V_{B})/2 | L2 | Increasing |
| | | | | | (under load) |
| 3 | S_{B}, S_{A}′ | V_{A} + V_{cf} | (V_{A} + V_{B})/2 | L2 | Decreasing |
| | | | | | (under load) |
| 4 | S_{B}′, S_{A}′ | V_{A} | V_{A} | L1 | Unchanging |

Table 1 shows the behavior of the multilevel converter of FIG. 8 for different switch states. In the table, V_{cf} denotes the voltage across flying capacitor C_{f}. State one (1) passes V_{B} to V_{SM}, while state four (4) passes V_{A} to V_{SM}. State two (2) results in V_{SM}=V_{B}−V_{cf}, while state three (3) results in V_{SM}=V_{A}+V_{cf}. It should be appreciated that, with suitable switching control of the converter (i.e., appropriate selections between states two (2) and three (3)), V_{cf} may be maintained near (V_{B}−V_{A})/2, which may result in both states two (2) and three (3) providing an output voltage V_{SM}=(V_{A}+V_{B})/2, as indicated in Table 1.

When controlled using the switch states of Table 1, converter 800 enables three effective levels (i.e., approximate level values) (L1, L2, L3) to be synthesized at its output 804: V_{A}, V_{B}, and (V_{A}+V_{B})/2. Converter 800 may thus be utilized to provide similar functionality to a 3-level supply modulator producing levels L₁=V_{A}, L₃=V_{B}, and L₂=(V_{A}+V_{B})/2, for example.

A benefit of the design of FIG. 8 is that it combines the capacitive energy transfer supply generation function with the supply modulation function, reducing device area and component size as compared to using a separate supply generator and supply modulator.

In some embodiments, V_{cf} (the voltage across flying capacitor C_{f}) may be maintained near (V_{B}−V_{A})/2 by appropriately selecting between states two (2) and three (3) of Table 1 when seeking to synthesize an output voltage level near (V_{A}+V_{B})/2. Under a positive load current (e.g., deriving from a PA), V_{cf} may increase over time in state two (2) and may decrease over time in state three (3).

In some embodiments, when selecting which of states two (2) or three (3) to use to supply a voltage close to (V_{A}+V_{B})/2 at the modulator output (i.e., synthesizing L2), state two (2) may be selected if V_{cf} falls too far below (V_{B}−V_{A})/2, where “too far” may be defined using one or more threshold values as described below.

In some embodiments, switching between states two (2) and three (3) may be controlled on a hysteretic basis and/or with clocked switching transitions. For example, such switching may occur instantaneously when the voltage V_{cf} exceeds an allowed voltage deviation ΔV above or below (V_{B}−V_{A})/2, or with transitions clocked, such as at a discrete supply modulation clocking rate. In some embodiments, the allowed voltage deviation ΔV value may be hardcoded in the controller, may be a programmable value of the controller, or may be conveyed via an external signal.

It should be appreciated that circuitry may be provided to measure/detect and/or infer the voltage V_{cf} across the flying capacitor C_{f}. For example, a differential sensor (not shown) (e.g., differential amplifier and/or comparator) may be provided, with each of its two inputs connected to a different terminal of C_{f} and its output connected to the controller controlling the switch states.

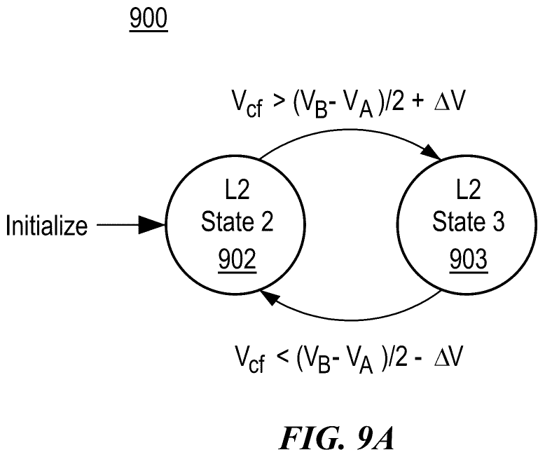

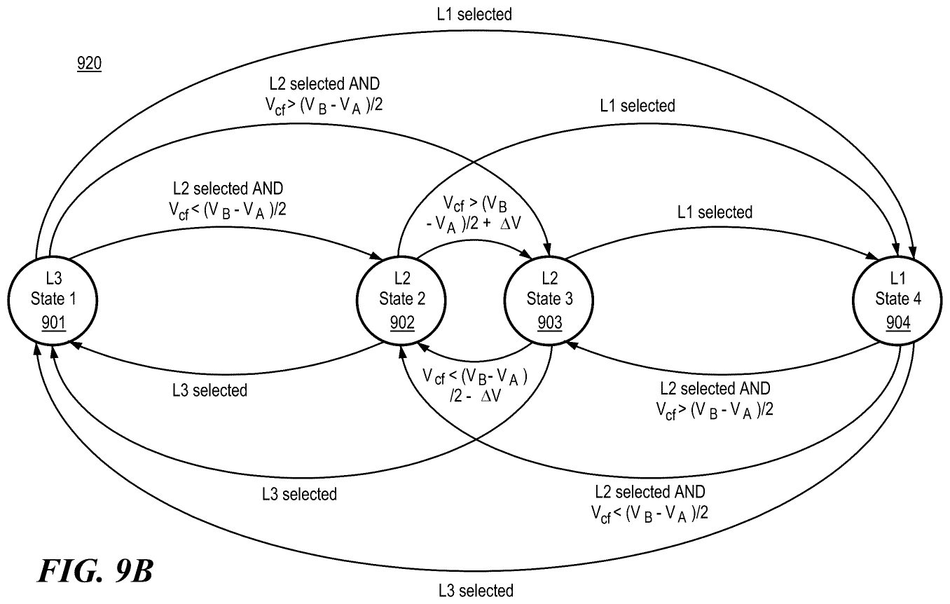

Referring now to FIG. 9A, shown is an illustrative state machine 900 that may be used to control the switch state of the multilevel converter 800 to maintain L2 (i.e., V_{SM}=(V_{A}+ V_{B})/2) by transitioning back and forth (e.g., alternating) between states two (2) and three (3). For example, when L2 is selected (e.g., when the hybrid supply generator and supply modulator is commanded to output the voltage level L2), the controller may use state machine 900 to determine whether state two (2) or three (3) is to be used to synthesize L2.

In the example of FIG. 9A, transitions between state two (2) 902 and state three (3) 903 may be a function of the capacitor voltage V_{cf}. In more detail, starting from state two (2) 902, state machine 900 may transition to state three (3) 903 when V_{cf} is greater than (V_{B}−V_{A})/2+ΔV. State machine 900 may transition back to state two (2) 902 when V_{cf} is less than (V_{B}−V_{A})/2−ΔV.

Such state transitions may be made on either an instantaneous or clocked basis. The allowed deviation ΔV of V_{cf} from (V_{B}−V_{A})/2 may determine the maximum deviation of the L2 output voltage from (V_{A}+V_{B})/2, and may be used as a fixed value or a programmable value. Reducing ΔV may give a more precise supply modulator output voltage for L2 (smaller difference between the two states synthesizing L2), but may require more frequent switching between states.

In some embodiments, state machine 900 may be re-initialized each time L2 is selected (i.e., transitioning from L1 or L3), with the initialization dependent upon voltage V_{cf}. For example, it may be desirable to initialize the state machine to state two (2) 902 if V_{cf}<(V_{B}−V_{A})/2 and to initialize the state machine to state three (3) 903 if V_{cf}>(V_{B}−V_{A})/2. Such a selection—or a similar one with different threshold(s)—may reduce the number of transitions required between states two (2) and three (3) to synthesize L₂, and hence improve efficiency.

Turning to FIG. 9B, according to some embodiments, the illustrative state machine of FIG. 9A for maintaining L2 voltage may be integrated into a larger state machine 920 for controlling all three levels L1, L2, and L3. In addition to state 2 902 and state 3 903 corresponding to L2, illustrative state machine 920 also includes state 1 901 corresponding to L3 and state 4 904 corresponding to L1.

In some cases, state machine 902 may be initialized (e.g., at startup/power up) to one of states 901-904 based on a default voltage level programmed or hardcoded into controller, for example.

State machine 920 may transition between states 901-904 in response to level select commands, such as commands received from an external circuit or control unit. For example, as shown, state machine 920 may transition to state 4 904 when L1 is selected and may transition to state 1 901 when L3 is selected. When L2 is selected, state machine 920 may transition to either state 2 902 or state 3 903 depending on Vof, the voltage across the flying capacitor.

One or more system controllers (e.g., controller(s) 550 of FIG. 5) may implement, execute, or otherwise utilize the state machine of FIG. 9A and/or FIG. 9B to control a multilevel converter.

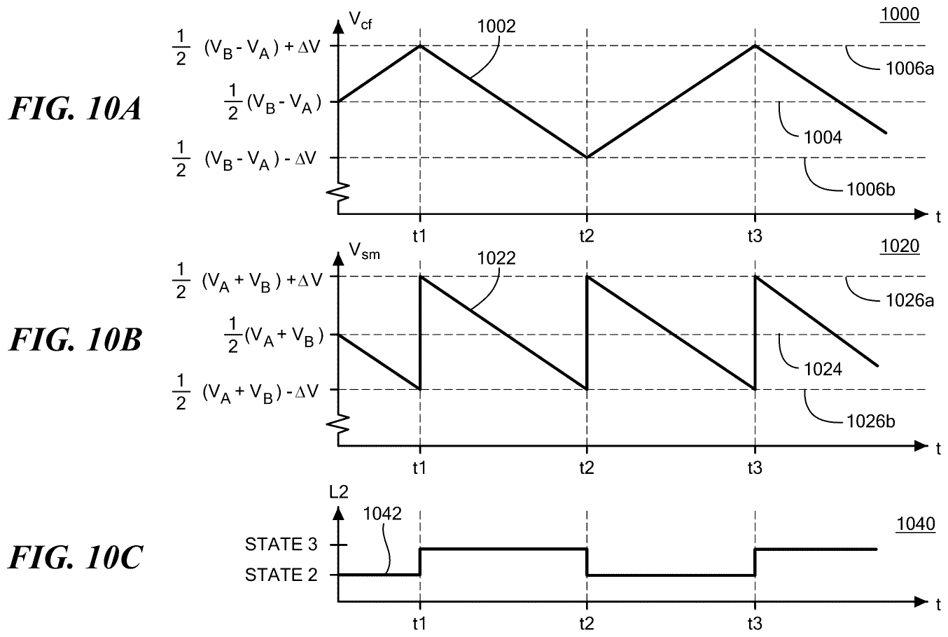

FIGS. 10A-10C illustrate voltage patterns (FIGS. 10A, 10B) and state transitions (FIG. 10C) associated with the state machine of FIG. 9B when used on an unclocked basis.

FIG. 10A shows a plot 1000 having a vertical axis corresponding to voltage and a horizontal axis corresponding to time t. A curve 1002 represents Vof over time. Horizontal line 1004 indicates (V_{A}−V_{B})/2, horizontal line 1006a indicates (V_{B}−V_{A})/2+ΔV, and horizontal line 1006b indicates (V_{B}−V_{A})/2−ΔV.

FIG. 10B shows a plot 1020 having a vertical axis corresponding to voltage and a horizontal axis corresponding to time t. A curve 1022 represents V_{SM} over time. Horizontal line 1024 indicates (V_{A}+V_{B})/2 (i.e., the effective L2 value), horizontal line 1026a indicates (V_{A}+V_{B})/2+ΔV, and horizontal line 1026b indicates (V_{A}+V_{B})/2−ΔV.

FIG. 10C shows a plot 1040 having a vertical axis corresponding to the L2 switch state (i.e., state two (2) or state three (3)) and a horizontal axis corresponding to time t. A curve 1042 indicates the L2 state, which is a function of V_{cf} (FIG. 10A). For example, at time t1, curve 1042 changes from state (2) to state (3) when curve 1002 crosses (or approaches) horizontal line 1006a. Subsequently, at time t2, curve 1042 changes from state three (3) to state two (2) when curve 1002 crosses (or approaches) horizontal line 1006b.

From FIGS. 10A-10C, it can be seen that the approach of transitioning between switch states as a function of V_{cf} maintains V_{cf} with a maximum voltage deviation ΔV from a center voltage (V_{B}−V_{A})/2, and maintains the supply modulator voltage V_{SM} within a maximum voltage deviation ΔV from a center voltage (V_{B}+V_{A})/2.

In some embodiments, a voltage deviation value ΔV for an amount of voltage deviation above a center voltage may be the same as a voltage deviation value ΔV for an amount of voltage deviation below a center voltage. In other embodiments, a voltage deviation value ΔV for an amount of voltage deviation above a center voltage may be different from a voltage deviation value ΔV for an amount of voltage deviation below a center voltage. In some embodiments, voltage deviation values may be predetermined and set, for example, by reference voltage inputs to comparators. In other embodiments, voltage deviation values may be determined by one or more controller(s) 550 based on one or more conditions of an RF amplifier system and set accordingly.

L2 state selection may additionally or alternatively be done on a clocked basis. One way to do this is, for example, to use a state machine like that in FIG. 9A or 9B to select how L2 is synthesized, with the state of a state machine updated on a clock edge. The clock may be the same clock as that used to make level selections, or may be derived from it.

In some embodiments, when transitioning L2 states on a clocked basis, the manner in which L2 is synthesized on each clock cycle may be updated, choosing state two (2) if V_{cf}< (V_{B}−V_{A})/2 or state three (3) if V_{cf}>(V_{B}−V_{A})/2, optionally using a small degree of hysteresis in a comparator upon which the decision is made. For a fully clocked selection, this approach may lead to a minimum deviation in V_{SM} from (V_{B}+V_{A})/2, at the expense of a possibly high number of transitions to do so.

Turning to FIG. 11, the general concepts, structures, and techniques described above may be extended to provide a hybrid supply generator and supply modulator having more than three (3) output levels.

FIG. 11 shows a multilevel converter 1100 for a hybrid supply generator and supply modulator capable of providing four (4) output levels. When terminal 1102a (V_{A}) is coupled to a nonzero voltage (e.g., connecting to any of regulators 7A-7E, 7H, 7I, 7J), the converter is a differential multilevel converter for a hybrid supply generator and supply modulator. Converter 1100 may operate from two voltages V_{A} and V_{B} received at respective inputs 1102a and 1102b, and may synthesize a voltage V_{SM} at output 1104. In some embodiments, voltage V_{B} may be controlled to be larger than voltage V_{A}. In some embodiments, voltage V_{B} or voltage V_{A} may correspond to an input voltage V_{IN}. In some embodiments, voltage V_{A} may correspond to a voltage of 0V.

Converter 1100 includes two (2) flying capacitors C_{f1}, C_{f2}, and three (3) complementary switch pairs S₁/S₁′, S₂/S₂′, and S₃/S₃′. The switch pairs may be operated (e.g., by a controller, such as controller(s) 550) according to eight (8) different switch states to provide four (4) effective output levels (V_{SM}).

A voltage V_{cf1} across flying capacitor Cm may be controlled to be near (V_{B}−V_{A})/3 and a voltage V_{cf2} across second flying capacitor C_{f2} may be controlled to be near 2*(V_{B}−V_{A})/3, enabling one to synthesize four effective output levels:

$$L 1 = {V}_{A} ;$$

$$L 2 = {V}_{B} - 2 * ( {V}_{B} - {V}_{A} ) / 3 \approx {V}_{A} + ( {V}_{B} - {V}_{A} ) / 3 ;$$

$$L 3 = {V}_{B} - ( {V}_{B} - {V}_{A} ) / 3 \approx {V}_{A} + 2 * ( {V}_{B} - {V}_{A} ) / 3 ; and$$

$$L 4 = {V}_{B} .$$

There is thus an evenly spaced distribution of effective output levels between V_{A} and V_{B}.

In some embodiments, switches S₁, S₁′, S₂, S₂′, S₃, S₃′ may be selected to have a voltage rating of more than ⅓ the maximum difference between V_{B} and V_{A}, but need not be rated for more than the maximum difference between V_{B} and V_{A}. Again, gate drive sources for the switches may be derived from input voltages V_{A}, V_{B}, and/or flying capacitor voltages V_{cf1}, V_{cf2}.

Table 2 shows the behavior of the multilevel converter 1100 of FIG. 11 for eight (8) different switch states.

TABLE 2

| State | Switches On | V_{SM} | V_{SM}≈ | Level | V_{cf1} | V_{cf2} |
|---|---|---|---|---|---|---|
| 1 | S₁′, S₂′, S₃′ | V_{A} | V_{A} | L1 | Unchanging | Unchanging |
| 2 | S₁′, S₂′, S₃ | V_{B} − V_{cf2} | V_{B} − 2*(V_{B} − V_{A})/3 | L2 | Unchanging | Increasing |
| 3 | S₁′, S₂, S₃′ | V_{A} + V_{cf2} − V_{cf1} | V_{B} − 2*(V_{B} − V_{A})/3 | L2 | Increasing | Decreasing |
| 4 | S₁′, S₂, S₃ | V_{B} − V_{cf1} | V_{B} − (V_{B} − V_{A})/3 | L3 | Increasing | Unchanging |
| 5 | S₁, S₂′, S₃′ | V_{A} + V_{cf1} | V_{B} − 2*(V_{B} − V_{A})/3 | L2 | Decreasing | Unchanging |
| 6 | S₁, S₂′, S₃ | V_{B} − V_{cf2} + V_{cf1} | V_{B} − (V_{B} − V_{A})/3 | L3 | Decreasing | Increasing |
| 7 | S₁, S₂, S₃′ | V_{A} + V_{cf2} | V_{B} − (V_{B} − V_{A})/3 | L3 | Unchanging | Decreasing |
| 8 | S₁, S₂, S₃ | V_{B} | V_{B} | L4 | Unchanging | Unchanging |

As can be seen from Table 2, there is one way to synthesize L1 (i.e., state one (1)), one way to synthesize L4 (i.e., state eight (8)), and three ways to synthesize each of the two intermediate effective output levels L2 and L3. In particular, L2 may be synthesized with states two (2), three (3), and five (5), while L3 may be synthesized with states four (4), six (6), and seven (7).

Selection of the states (e.g., states 1-8) may be controlled to provide a desired output level while maintaining the capacitor voltages V_{cf1} and V_{cf2} within or near a desired range close to their ideal voltages. Thus, a controller (e.g., controller(s) 550) may receive (1) one or more inputs conveying a commanded level (e.g., L1, L2, L3, or L4), such as from another controller(s) 550, and (2) one or more inputs (e.g., binary input(s)) indicating whether a capacitor voltage (e.g., V_{cf1}, V_{cf2}) is above or below a threshold voltage level (e.g., above or below a voltage deviation ΔV) from a desired voltage level). For example, input(s) conveying a commanded level may be received (e.g., as DCL command(s)) from a level select controller within a modem, for example. Input(s) indicating whether a capacitor voltage is above or below a threshold voltage level may be provided as feedback signals, such as by monitoring a capacitor voltage with a comparator and providing an output signal of the comparator to controller(s) 550.

In some embodiments, the input(s) indicating whether a capacitor voltage is above or below a threshold level may comprise binary inputs relating to each capacitor voltage (i.e., V_{cf1} and V_{cf2}) indicating whether that capacitor voltage is (1) above a desired maximum voltage or (2) below a desired minimum voltage. For example, the binary signals may each be generated by comparator(s) in a hysteretic “windowing” configuration with thresholds set at the ideal capacitor voltage +/−a maximum deviation voltage (e.g., a window circuit for V_{cf1} having thresholds (V_{B}−V_{A})/3+/−ΔV₁ and a window circuit for V_{cf2} having thresholds 2*(V_{B}−V_{A})/3+/−ΔV₂). However, the disclosure is not so limited. A person of ordinary skill in the art would recognize that many similar known techniques may be utilized to define and indicate allowable voltages.

In some embodiments, the binary inputs may be defined as signals V_{cf}1>> (true if V_{cf1} is above its desired range) (e.g., V_{cf1} is “too big”), V_{cf1}<< (true if V_{cf1} is below its desired range) (e.g., V_{cf1} is “too small”), V_{cf2}>> (true if V_{cf2} is above its desired range) (e.g., V_{cf2} is “too big”), and V_{cf2}<< (true if V_{cf2} is below its desired range) (e.g., V_{cf2} is “too small”). However, the disclosure is not so limited. For example, in some embodiments, a complement of these conditions may be utilized. As one example, a binary input may be defined as V̅_̅{̅c̅f̅2̅}̅>̅>̅ (true if V_{cf2} is NOT above the desired range (e.g., V_{cf2} “NOT too big”), with the overbar identifying a NOT condition.

The combination of the binary inputs and the commanded level may be sufficient to determine an allowable set of states that may be used to provide corrective action to keep the capacitor voltages close to their desired voltages while providing the commanded output level.

The states synthesizing each of the two intermediate effective levels (e.g., L2 and L3) may each have different effects on the charging and discharging of C_{f1} and C_{cf2} (i.e., V_{cf1} or V_{cf2} increasing or decreasing under load). By dynamically choosing which state is used to synthesize a desired intermediate output level, the capacitor voltages V_{cf1} and V_{cf2} may be maintained each near their target voltage of (V_{B}−V_{A})/3 and 2*(V_{B}−V_{A})/3. These control selections may be performed through a variety of means including through use of one or more appropriate state machines. For example, a control scheme/state machine may be selected to have Voff to be maintained within a voltage ΔV₁ of the target voltage (V_{B}−V_{A})/3 and V_{cf2} to be maintained within a voltage ΔV₂ of the target voltage 2*(V_{B}−V_{A})/3. In some embodiments, the values ΔV₁ and ΔV₂ may be predetermined and set, for example, by reference voltage inputs to comparators or differential amplifiers. In other embodiments, the values ΔV₁ and ΔV₂ may be hardcoded in the controller, may be programmable values of the controller, or may be conveyed via one or more external signals.

In some embodiments, a voltage deviation value ΔV₁ may be the same as a voltage deviation value ΔV₂. In other embodiments, a voltage deviation value ΔV₁ may be different than a voltage deviation value ΔV₂. In some embodiments, a voltage deviation value (e.g., ΔV₁, ΔV₂) for an amount of voltage deviation above a center voltage may be the same as a corresponding voltage deviation value (e.g., ΔV₁, ΔV₂) for an amount of voltage deviation below a center voltage. In other embodiments, a voltage deviation value (e.g., ΔV₁, ΔV₂) for an amount of voltage deviation above a center voltage may be different from a corresponding voltage deviation value (e.g., ΔV₁, ΔV₂) for an amount of voltage deviation below a center voltage.

It should be appreciated that circuitry may be provided to measure/detect/infer the voltage Von across flying capacitor Cm and the voltage V_{cf2} across flying capacitor C_{f2}. For example, two differential sensors (not shown) (e.g., comparators, differential amplifiers) may be provided, one having its inputs connected across Cm and the other having its inputs connected across C_{f2}. The outputs of both differential sensors may be connected to the controller controlling the switch states.

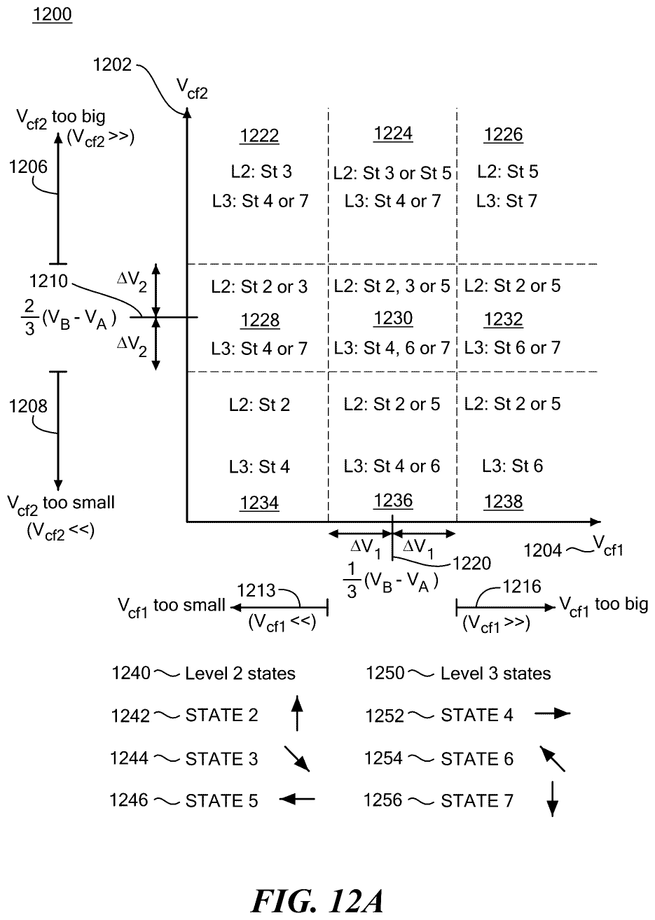

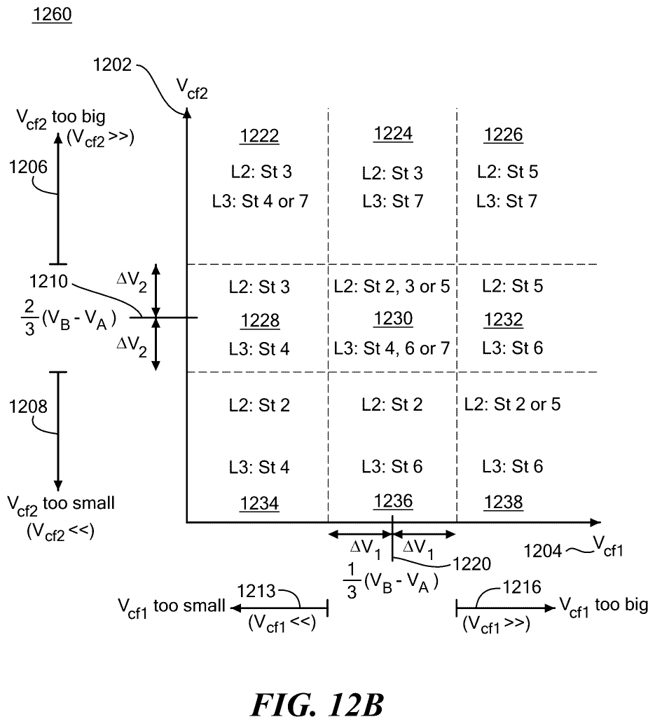

FIG. 12A is a diagram 1200 showing example states that may be selected to properly maintain capacitor voltages (V_{cf1}, V_{cf2}) for different level selections in a four-level multilevel converter (e.g., multilevel converter of FIG. 11), based on different levels of the capacitor voltages (V_{cf1}, V_{cf2}) (or different regions in the (V_{cf1}, V_{cf2}) plane), and showing approximate directions of change in the (V_{cf1}, V_{cf2}) plane for the different state selections. The example states of FIG. 12A may be selected to drive the capacitor voltages towards preferred values for different level selections. The example states (or a subset of the example states) of diagram 1200 may be utilized, for example, to implement a state machine for controlling when to operate switches of a multilevel converter (e.g., multilevel converter of FIG. 11) to switch between levels 2 and 3 when the multilevel converter is configured to supply four output voltage levels. Conditions for states 1 (level 1 (or L1)) and 8 (level 4 (or L4)) are not shown, as the capacitor voltages ideally do not change in these states, and may be regulated through other means, such as low-power startup and/or regulation circuitry.

FIG. 12A includes an X-axis representing voltages of V_{cf1} and a Y-axis representing voltages of V_{cf2}. That is, FIG. 12A illustrates a (V_{cf1}, V_{cf2}) plane. The (V_{cf1}, V_{cf2}) plane of FIG. 12A is shown as being divided into nine regions (regions 1222, 1224, 1226, 1228, 1230, 1232, 1234, 1236, 1238). In general, it may be desirable to maintain a voltage V_{cf1} of capacitor C_{f1} in a range of (V_{B}−V_{A})/3+/−ΔV₁ and a voltage V_{cf2} of capacitor C_{f2} around 2*(V_{B}−V_{A})/3+/−ΔV₂, as previously discussed above. As shown in FIG. 12A, a central point 1220 of the X-axis represents a voltage of (V_{B}−V_{A})/3, and the bidirectional arrows on either side of central point 1220 represent a variation off that voltage of +/−ΔV₁. A central point 1210 of the Y-axis represents a voltage of 2*(V_{B}−V_{A})/3, and the bidirectional arrows on either side of central point 1210 represent a variation off that voltage of +/−ΔV₂. Thus, it may be desirable to maintain the capacitor voltages (voltage V_{cf1} and voltage V_{cf2}) within region 1230. Arrow 1216 represents voltages of V_{cf} that are too big (e.g., condition V_{cf1}>>) and arrow 1213 represents voltages of V_{cf1} that are too small (e.g., condition V_{cf1}<<). Arrow 1206 represents voltages of V_{cf2} that are too big (e.g., condition V_{cf2}>>) and arrow 1208 represents voltages of V_{cf2} that are too small (e.g., condition V_{cf2}<<).

Example states that may be selected to drive the capacitor voltages V_{cf1} and V_{cf2} toward the desired values are shown for each region of the nine regions. The states are shown in terms of the regions of the (V_{cf1}, V_{cf2}) plane, delineated by the aforementioned allowable voltage ranges (i.e., the maximum and minimum desired voltages for V_{cf1} and V_{cf2}). Within a given region of the plane, any of the indicated states may be selected for a given level to provide desirable corrective action for the capacitor voltages V_{cf1} and V_{cf2}.

For example, when the voltages of the capacitors (V_{cf1}, V_{cf2}) are in region 1222, then when in level 2 (L2) state 3 may be selected and when in level 3 (L3) states 4 or 7 may be selected to drive the capacitor voltages toward their desired ranges. When the voltages of the capacitors are in region 1224, then when in level 2 (L2) states 3 or 5 may be selected and when in level 3 (L3) states 4 or 7 may be selected to drive the capacitor voltages toward their desired ranges. When the voltages of the capacitors are in region 1226, then when in level 2 (L2) state 5 may be selected and when in level 3 (L3) state 7 may be selected to drive the capacitor voltages toward their desired ranges.

When the voltages of the capacitors are in region 1228, then when in level 2 (L2) states 2 or 3 may be selected and when in level 3 (L3) states 4 or 7 may be selected to drive the capacitor voltages toward their desired ranges. When the voltages of the capacitors are in region 1230, then when in level 2 (L2) states 2, 3 or 5 may be selected and when in level 3 (L3) states 4, 6, or 7 may be selected to drive the capacitor voltages toward their desired ranges. When the voltages of the capacitors are in region 1232, then when in level 2 (L2) states 2 or 5 may be selected or when in level 3 (L3) states 6 or 7 may be selected to drive the capacitor voltages toward their desired ranges.

When the voltages of the capacitors are in region 1234, then when in level 2 (L2) state 2 may be selected and when in level 3 (L3) state 4 may be selected to drive the capacitor voltages toward their desired ranges. When the voltages of the capacitors are in region 1236, then when in level 2 (L2) states 2 or 5 may be selected and when in level 3 (L3) states 4 or 6 may be selected to drive the capacitor voltages toward their desired ranges. When the voltages of the capacitors are in region 1238, then when in level 2 (L2) states 2 or 5 and when in level 3 (L3) state 6 may be selected to drive the capacitor voltages toward their desired ranges.

FIG. 12A also shows the approximate direction of change in the (V_{cf1}, V_{cf}2) plane for state selections at a given level. For example, for level 2 (1240), FIG. 12A shows that state 2 1242 generally moves the capacitor voltages in the positive direction along the Y-axis in the (V_{cf1}, V_{cf}2) plane (e.g., generally increases V_{cf2} while maintaining V_{cf1}), state 3 1244 generally moves the capacitor voltages in the positive direction along the X-axis and in the negative direction along the Y-axis in the (V_{cf1}, V_{cf2}) plane (e.g., generally increases V_{cf1} while decreasing V_{cf2}), and state 5 1246 generally moves the capacitor voltages in the negative direction along the X-axis in the (V_{cf1}, V_{cf2}) plane (e.g., generally decreases V_{cf1} while maintaining V_{cf2}).

For level 3 (1250), FIG. 12A shows that state 4 1252 generally moves the capacitor voltages in the positive direction along the X-axis in the (V_{cf1}, V_{cf2}) plane (e.g., generally increases V_{cf1} while maintaining V_{cf2}), state 6 1254 generally moves the capacitor voltages in the positive direction along the Y-axis and in the negative direction along the X-axis in the (V_{cf1}, V_{cf}2) plane (e.g., generally increases V_{cf2} while decreasing V_{cf1}), and state 7 1256 generally moves the capacitor voltages in the negative direction along the Y-axis in the (V_{cf1}, V_{cf2}) plane (e.g., generally decreases V_{cf2} while maintaining V_{cf1}).

In a given region of the (V_{cf1}, V_{cf2}) plane shown in FIG. 12A, any of the states shown for that region may be utilized to drive the capacitor voltages toward their desired ranges. Thus, there are many different state machines that could be implemented in one or more controllers (e.g., controller(s) 550) to leverage these state selections and provide acceptable operation of the 4-level hybrid supply generator and supply modulator shown in FIG. 11. Considerations in configuring a particular state machine for a given application may include how tightly voltages should be driven to and maintained near their desired values, how rapidly voltages should be driven to and maintained near their desired values, the number of switching transitions required per unit time in maintaining capacitor voltages near their desired values, and/or, when switching states, how many switch transitions are required to effectuate a change between states.

FIG. 12B is another diagram 1260 showing example states that may be selected to provide a high degree of corrective action in maintaining capacitor voltages (V_{cf1}, V_{cf2}) for different level selections in a four level multilevel converter (e.g., multilevel converter of FIG. 11), based on different levels of the capacitor voltages (V_{cf1}, V_{cf2}) (or different regions in the (V_{cf1}, V_{cf}2) plane). The example states of FIG. 12B may be selected to drive the capacitor voltages towards preferred values for different level selections, but the set of example states of FIG. 12B is more restricted than the set of example states of FIG. 12A. That is, the set of example states of FIG. 12B represents a subset of the states shown in FIG. 12A. The more restricted set of example states of FIG. 12B may provide a higher degree of corrective action on the capacitor voltages (V_{cf1}, V_{cf2}) than the full set of example states shown in FIG. 12A, but may require more switching transitions per time than utilizing other example states shown in FIG. 12A. The example states of diagram 1260 may be utilized, for example, to implement a state machine for controlling when to operate switches of a multilevel converter (e.g., multilevel converter of FIG. 11) to switch between levels 2 (L2) and 3 (L3) when the multilevel converter is configured to supply four output voltage levels. Conditions for state 1 (level 1 (or L1)) and 8 (level 4 (or L4)) are not shown, as the capacitor voltages ideally do not change in these states, and may be regulated through other means, such as low-power startup and/or regulation circuitry.

FIG. 12B represents the same (V_{cf1}, V_{cf}2) plane as in FIG. 12A, but with the subset of states that provide a higher degree of corrective action than the full set of states in FIG. 12A. Within a given region of the plane, any of the indicated states may be selected for a given level to provide the higher degree of corrective action for the capacitor voltages V_{cf1} and V_{cf2}.

For example, when the voltages of the capacitors (V_{cf1}, V_{cf2}) are in region 1222, then when in level 2 (L2) state 3 may be selected and when in level 3 (L3) states 4 or 7 may be selected to drive the capacitor voltages toward their desired ranges. When the voltages of the capacitors are in region 1224, then when in level 2 (L2) state 3 may be selected when in level 3 (L3) state 7 may be selected to drive the capacitor voltages toward their desired ranges. When the voltages of the capacitors are in region 1226, then when in level 2 (L2) state 5 may be selected and when in level 3 (L3) state 7 may be selected to drive the capacitor voltages toward their desired ranges.

When the voltages of the capacitors are in region 1228, then when in level 2 (L2) state 3 may be selected and when in level 3 (L3) state 4 may be selected to drive the capacitor voltages toward their desired ranges. When the voltages of the capacitors are in region 1230, then when in level 2 (L2) states 2, 3, or 5 may be selected and when in level 3 (L3) states 4, 6, or 7 may be selected to drive the capacitor voltages toward their desired ranges. When the voltages of the capacitors are in region 1232, then when in level 2 (L2) state 5 may be selected and when in level 3 (L3) state 6 may be selected to drive the capacitor voltages toward their desired ranges.

When the voltages of the capacitors are in 1234, then when in level 2 (L2) state 2 may be selected and when in level 3 (L3) state 4 may be selected to drive the capacitor voltages toward their desired ranges. When the voltages of the capacitors are in region 1236, then when in level 2 (L2) state 2 may be selected and when in level 3 (L3) state 6 may be selected to drive the capacitor voltages toward their desired ranges. When the voltages of the capacitors are in region 1238, then when in level 2 (L2) states 2 or 5 may be selected and when in level 3 (L3) state 6 may be selected to drive the capacitor voltages toward their desired ranges.

The approximate directions of change in the (V_{cf1}, V_{cf}2) plane for different states at the different levels for FIG. 12B are the same as shown in FIG. 12A.

One or more controllers (e.g., controller(s) 550) may act to transition among states under various conditions, such as due to a change in commanded level or a change in the input (e.g., binary input) regarding capacitor voltage status (e.g., when crossing a boundary in FIG. 12A or FIG. 12B). One consideration when selecting a new state is the number of switch-pair transitions (i.e., complementary switch pairs changing their states) for a given transition. Switching states may, for example, require the switching of at least two complementary switches (e.g., closing one switch and opening another switch). Some state transitions may require the switching of four switches (i.e., two complementary switch pairs) or six switches (i.e., three complementary switch pairs).

When switching among states that change the level output, some state transitions may only require one switch pair transition, while others may require two or three switch pair transitions. It may be preferable (for loss and/or timing reasons) to utilize state transitions that only require a single switch pair transition. It thus may be preferable to utilize a controller (e.g., controller(s) 550) implementing a state machine that requires only state transitions that have single switch pair transitions when changing levels. Table 3 below shows the number of required switch pair transitions for the multilevel converter of FIG. 11 when switching between states for each of the possible state transitions within level 2 (L2). The states switched between in the example state transitions are grouped together in adjacent rows.

TABLE 3

| | | | Switch Pair |
|---|---|---|---|
| Level | State | Switches On | Transitions |
| 2 | 2 | (S₁′, S₂′, S₃) | 2 |
| 2 | 3 | (S₁′, S₂, S₃′) | |
| 2 | 2 | (S₁′, S₂′, S₃) | 2 |
| 2 | 5 | (S₁, S₂′, S₃′) | |
| 2 | 3 | (S₁′, S₂, S₃′) | 2 |
| 2 | 5 | (S₁, S₂′, S₃′) | |

Table 4 below shows the number of required switch pair transitions for the multilevel converter of FIG. 11 when switching between states for each of the possible state transitions within level 3 (L3). The states switched between in the example state transitions are grouped together in adjacent rows.

TABLE 4

| | | | Switch Pair |
|---|---|---|---|
| Level | State | Switches On | Transitions |
| 3 | 4 | (S₁′, S₂, S₃) | 2 |
| 3 | 6 | (S₁, S₂′, S₃) | |
| 3 | 4 | (S₁′, S₂, S₃) | 2 |
| 3 | 7 | (S₁, S₂, S₃′) | |
| 3 | 6 | (S₁, S₂′, S₃) | 2 |
| 3 | 7 | (S₁, S₂, S₃′) | |

As shown above in Tables 3 and 4, all “same level” state transitions (i.e., L2<->L2, L3<->L3) require the same number of switch pair transitions (i.e., 2 switch pair transitions).

Table 5 below shows the number of required switch pair transitions for the multilevel converter of FIG. 11 when switching between states for each of the possible state transitions between levels 2 (L2) and 3 (L3). The states switched between in the example state transitions are grouped together in adjacent rows.

TABLE 5

| | | | Switch Pair |
|---|---|---|---|
| Level | State | Switches On | Transitions |
| 2 | 2 | (S₁′, S₂′, S₃) | 1 |
| 3 | 4 | (S₁′, S₂′, S₃) | |
| 2 | 2 | (S₁′, S₂′, S₃) | 1 |
| 3 | 6 | (S₁, S₂′, S₃) | |
| 2 | 2 | (S₁′, S₂′, S₃) | 3 |
| 3 | 7 | (S₁, S₂, S₃′) | |
| 2 | 3 | (S₁′, S₂, S₃′) | 1 |
| 3 | 4 | (S₁′, S₂, S₃) | |
| 2 | 3 | (S₁′, S₂, S₃′) | 3 |
| 3 | 6 | (S₁, S₂′, S₃) | |
| 2 | 3 | (S₁′, S₂, S₃′) | 1 |
| 3 | 7 | (S₁, S₂, S₃′) | |
| 2 | 5 | (S₁, S₂′, S₃′) | 3 |
| 3 | 4 | (S₁′, S₂, S₃) | |
| 2 | 5 | (S₁, S₂′, S₃′) | 1 |
| 3 | 6 | (S₁, S₂′, S₃) | |
| 2 | 5 | (S₁, S₂′, S₃′) | 1 |
| 3 | 7 | (S₁, S₂, S₃′) | |

As shown above in Table 5, some “interlevel” state transitions (i.e., L2<->L3) require far fewer switch pair transitions than other interlevel state transitions.

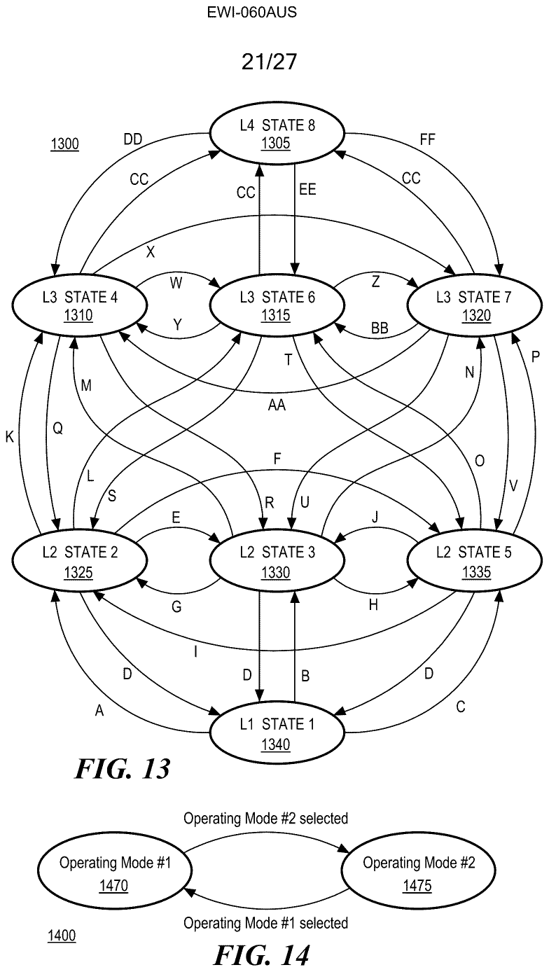

There are many possible control algorithms (or state machines) that one or more controllers (e.g., controller(s) 550) may utilize to leverage the example states of FIG. 12A or 12B and to minimize the number of switch pair transitions required when changing states. One example state machine that may be implemented by one or more controllers (e.g., controller(s) 550) to leverage the example allowed states of FIG. 12B and minimize the number of required switch pair transitions when changing output levels (as per Table 5) is shown in FIG. 13.

FIG. 13 is an example state machine 1300 that may be used for controlling switch states in a four level multilevel converter, such as the multilevel converter of FIG. 11. State machine 1300 illustrates the eight states from Table 2 (e.g., state 1 (L1) 1340, state 2 (L2) 1325, state 3 (L2) 1330, state 5 (L2) 1335, state 4 (L3) 1310, state 6 (L3) 1315, state 7 (L3) 1320, state 8 (L4) 1305) and transitions between the states. Note that, while FIG. 13 only illustrates transitions within a given level (e.g., L2<->L2, L3<->L3) or between adjacent levels (e.g., L1<->L2, L2<->L3, L3<->L4), in some embodiments state machines may be configured that allow for transitioning between non-adjacent levels (e.g., L1<->L3, L1<->L4, L2<->L4). In FIG. 13, the transitions between the states are labeled with letters. An example set of transition conditions for each of the labeled transitions of FIG. 13 is provided below in Table 6. For transitions with two rows of conditions listed, the two rows should be considered to be alternative sets of conditions for effecting that transition. Conditions with an overbar return a true value, for example, if the condition beneath the bar does NOT occur.

TABLE 6

| Transition | Condition(s) |
|---|---|
| A | L2, V_{cf2} « |
| B | L2, V̅_̅{̅c̅f̅1̅}̅ »̅, V̅_̅{̅c̅f̅2̅}̅ «̅ |
| C | L2, V_{cf1} », V̅_̅{̅c̅f̅2̅}̅ «̅ |
| D | L1 |
| E | L2, V_{cf1} «, V̅_̅{̅c̅f̅2̅}̅ «̅ |
| | L2, V̅_̅{̅c̅f̅1̅}̅ »̅, V_{cf2} » |
| F | L2, V_{cf1} », V̅_̅{̅c̅f̅2̅}̅ «̅ |
| G | L2, V̅_̅{̅c̅f̅1̅}̅ »̅, V_{cf2} « |
| H | L2, V_{cf1} » |
| I | L2, V̅_̅{̅c̅f̅1̅}̅ »̅, V_{cf2} « |
| J | L2, V̅_̅{̅c̅f̅1̅}̅ »̅, V_{cf2} » |
| | L2, V_{cf1} «, V̅_̅{̅c̅f̅2̅}̅ «̅ |
| K | L3, V_{cf1} « |
| L | L3, V̅_̅{̅c̅f̅1̅}̅ «̅ |
| M | L3, V_{cf1} « |
| N | L3, V̅_̅{̅c̅f̅1̅}̅ «̅ |
| O | L3, V̅_̅{̅c̅f̅2̅}̅ »̅ |
| P | L3, V_{cf2} » |
| Q | L2, V_{cf2} « |
| R | L2, V̅_̅{̅c̅f̅2̅}̅ «̅ |
| S | L2, V_{cf2} « |
| T | L2, V̅_̅{̅c̅f̅2̅}̅ «̅ |
| U | L2, V̅_̅{̅c̅f̅1̅}̅ »̅ |
| V | L2, V_{cf1} » |
| W | L3, V̅_̅{̅c̅f̅1̅}̅ «̅, V_{cf2} « |
| | L3, V_{cf1} », V̅_̅{̅c̅f̅2̅}̅ »̅ |
| X | L3, V̅_̅{̅c̅f̅1̅}̅ «̅, V_{cf2} » |
| Y | L3, V_{cf1} « |
| Z | L3, V̅_̅{̅c̅f̅1̅}̅ «̅, V_{cf2} » |
| AA | L3, V_{cf1} «, V̅_̅{̅c̅f̅2̅}̅ »̅ |
| BB | L3, V_{cf1} », V̅_̅{̅c̅f̅2̅}̅ »̅ |
| | L3, V̅_̅{̅c̅f̅1̅}̅ »̅, V_{cf2} « |
| CC | L4 |
| DD | L3, V_{cf1} « |
| EE | L3, V̅_̅{̅c̅f̅1̅}̅ «̅, V̅_̅{̅c̅f̅2̅}̅ »̅ |
| FF | L3, V̅_̅{̅c̅f̅1̅}̅ «̅, V_{cf2} » |

A state machine (e.g., state machine of FIG. 13, such as utilizing the example state transition configurations of Table 6) may be implemented by one or more controllers (e.g., controller(s) 550) to act asynchronously (e.g., not with regards to a clock, but instead only with regards to changes in inputs) or synchronously (e.g., responding to changes in the inputs on a clocked basis). Synchronous operation may include synchronization of possible input changes with a clock.

Although FIG. 13 provides an example state machine and Table 6 provides example state transition conditions, the disclosure is not limited to the state machine of FIG. 13 or the example state transition conditions of Table 6. That is, different state transition conditions from those shown in Table 6 may be utilized in implementing a state machine. Moreover, as previously discussed, the example state machine of FIG. 13 only provides for transitions among adjacent output levels. However, the disclosure is not so limited. Alternative state machines, or extensions of the example state machine of FIG. 13, may be implemented that allow for transitions among non-adjacent output levels.

Although certain example states are listed in example regions of the (V_{cf1}, V_{cf2}) plane in FIGS. 12A and 12B, the disclosure is not limited to using these example states in these example regions. For example, in some embodiments it may be desirable to use the states in different regions than the ones for which they are listed in FIGS. 12A and 12B.

FIG. 14 shows an example state machine 1400 that may be used to control a four level multilevel converter (e.g., multilevel converter 1100) to switch between a first operating mode 1470 (e.g., Operating Mode #1) providing 4 available output levels (see, e.g., state machine of FIG. 13 or another state machine implemented based on the allowable levels of FIG. 12A or FIG. 12B) and a second operating mode 1475 (e.g., Operating Mode #2) providing 3 available output levels (see, e.g., state machine of FIGS. 9A-10C). For example, holding switches S₂ and S₂′ on and controlling first flying capacitor C_{f1} and second flying capacitor C_{f2} to each be near (V_{B}−V_{A})/2 enables one to synthesize three effective output levels:

$$L 1 = {V}_{A} ;$$

$$L 2 = ( {V}_{A} + {V}_{B} ) / 2 ; and$$

$$L 3 = {V}_{B} .$$

There is thus also an evenly spaced distribution of effective output levels between V_{A} and V_{B} in second operating mode 1475. Note that although the three output levels in second operating mode 1475 are labeled L1, L2, and L3, these output levels in the second operating mode may not be equivalent in value to the voltage levels labeled L1, L2, and L3 in first operating mode 1470. For example, as previously discussed, levels L1, L2, L3, and L4 in first operating mode 1470 may have approximate values of V_{A}, V_{B}−2*(V_{B}−V_{A})/3, V_{B}−(V_{B}−V_{A})/3, and V_{B}, while levels L1, L2, and L3 in second operating mode 1475 may have approximate values of V_{A}, (V_{A}+V_{B})/2, and V_{B}, respectively.

In some embodiments, switches S₁, S₁′, S₂, S₂′, S₃, S₃′ may be selected to have a voltage rating of more than ½ the maximum difference between V_{B} and V_{A}, but need not be rated for more than the maximum difference between V_{B} and V_{A}. Again, gate drive sources for the switches may be derived from input voltages V_{A}, V_{B}, and/or flying capacitor voltages V_{cf1}, V_{cf2}.

Previously discussed Table 2 shows the behavior of the multilevel converter 1100 of FIG. 11 for first operating mode 1470. Table 7 below shows the behavior of the multilevel converter 1100 of FIG. 11 for second operating mode 1475.

TABLE 7

| State | Switches On | V_{O} | V_{O}≈ | Level | V_{cf1} | V_{cf2} |
|---|---|---|---|---|---|---|
| A | S₁′, S₂, S₂′, | V_{A} | V_{A} | 1 | Unchanging | Unchanging |
| | S₃′ | | | | | |
| B | S₁′, S₂, S₂′, | V_{B} − V_{A} − V_{cf2} | (½)*(V_{A} + V_{B}) | 2 | Increasing | Increasing |
| | S₃ | | | | | |
| C | S₁, S₂, S₂′, | V_{cf2} | (½)*(V_{A} + V_{B}) | 2 | Decreasing | Decreasing |
| | S₃′ | | | | | |
| D | S₁, S₂, S₂′, | V_{B} | V_{B} | 3 | Unchanging | Unchanging |
| | S₃ | | | | | |

A particular operating mode (e.g., first operating mode 1470 or second operating mode 1475) may be most optimal depending on factors such as the input voltage from an energy source (e.g., battery), output power of the PA, and/or other operating characteristics associated with the PA.

In some embodiments, one or more controllers (e.g., controller(s) 550) implementing a digital pre-distortion (DPD) algorithm may send one or more signals to one or more other controllers (e.g., controller(s) 550) commanding an optimal configuration for multilevel converter 1100, and the one or more controllers receiving the signals may control switches of multilevel converter 1100 to implement the optimal configuration. These configuration adjustments may include, for example, adjusting voltage conversion ratios provided by the network of switches and capacitors by switching operating modes and/or adjusting voltages (e.g., voltage V_{B} and/or V_{A}) input to multilevel converter 1100.

After reading the disclosure herein, those of ordinary skill in the art should appreciate that hybrid supply generator and supply modulator designs having more flying capacitors and more effective output levels may be synthesized by direct extension of the 3-level design of FIG. 8 and the 4-level design of FIG. 11, and that these designs may optionally be made to be reconfigurable.

In general, designs providing N effective output levels may utilize N-2 flying capacitors and N-1 complementary switch pairs (yielding up to 2 (N-1) switch states that may be used for level synthesis).

It should be appreciated that additional circuitry may be used to pre-charge the flying capacitors (e.g., C_{f} in FIG. 8 or C_{f1} and C_{f2} in FIG. 11) to desired levels before modulation starts. For a reconfigurable differential multilevel converter, the desired levels may be selected based on the desired configuration.

In some embodiments, additional circuitry may also be provided to maintain the flying capacitor voltages to within a desired range (e.g., close to their respective target voltages) during time periods when the synthesized output levels do not provide charging/discharging control of the capacitor voltage(s), when the system is not operating (e.g., in standby mode or in startup), and/or when the voltage levels V_{A}, V_{B}, or their references are adjusted. Such circuitry might comprise linear circuits (e.g., current sources, linear regulators, etc.) implemented in the integrated circuit.

As previously discussed, in some embodiments, it may be advantageous to provide a low-cost supply generation and supply modulation system that can yield high performance in applications such as mobile WiFi systems in which size and/or cost are heavily constrained. One might just use a linear regulator coupled between a battery and a PA to provide a fixed power supply. However, as discussed above, such a solution may be inefficient as the linear regulator dissipates power to provide the desired output voltage.

Systems, methods, circuits, devices, and techniques disclosed herein provide for power supply designs that provide discrete supply modulation with reduced loss, while still being low in cost and size.

FIG. 15 is a diagram of a system 1500. System 1500 is an example of a reconfigurable hybrid supply generator and supply modulator with a regulation stage. The regulation stage may include one or more linear regulators (e.g., linear regulator 1504). The one or more linear regulators (e.g., linear regulator 1504) and capacitor C₁ may be considered to be a first stage circuit, while the network of switches (e.g., S_{A}, S_{B}, S_{A}′, S_{B}′) and flying capacitor C_{f} may be considered to be a second stage circuit. Any type of linear regulator (e.g., LDO) may be used as linear regulator 1504. Although a linear regulator 1504 is shown in FIG. 15, in some embodiments, different types of voltage regulation circuits may be used in place of, or in addition to, linear regulator 1504. For example, a magnetic converter (e.g., buck, boost, buck-boost, flyback) may be used. As previously discussed, a linear regulator may have more dissipative loss than a magnetic converter (and thus be less efficient), but may be smaller in size (e.g., implemented on a small IC or with small components) and/or less expensive than a magnetic converter. Thus, use of a linear regulator may be advantageous in some applications, such as mobile applications, where size and/or cost may be a constraint. Although a linear regulator 1504 is shown in FIG. 15, in some embodiments, different types of voltage regulation circuits may be used in place of, or in addition to, linear regulator 1504. For example, a combination of a switched-capacitor converter and a linear regulator as shown in FIG. 7G (717) may be used in place of linear regulator 1504. In some such embodiments, the linear regulator (e.g., linear regulator 716) may be omitted, and regulation achieved through control of a switched-capacitor converter (e.g., switched-capacitor converter 733).

System 1500 may be coupled to energy source 1510 (e.g., battery) at a pair of input terminals (e.g., one coupled to the positive terminal and one coupled to the negative terminal of energy source 1510) and may be coupled to a load (e.g., RF amplifier) via a pair of output terminals 1520, 1530. Linear regulator 1504 may draw power at the input terminals to regulate from a voltage of energy source 1510 (e.g., battery), such as a voltage of V_{BAT}, and may output a regulated voltage V_{R}. Energy source 1510 is shown in FIG. 15 in phantom, as it may not properly be considered to be part of system 1500. The voltage level of V_{R} may be set to a fixed value. Alternatively, the voltage level V_{R} may be selected from among multiple discrete values (e.g., based on current input battery voltage of energy source 1510, based on RF PA output power or desired RF PA output power, based on available operating points for a digital predistortion (DPD) system, and/or based on other considerations). That is, the voltage level of V_{R} may be controllable (e.g., able to be programmatically reconfigured) by one or more controllers (not shown), such as controller(s) 550. In some embodiments, the one or more controllers may receive feedback or feedforward signals from elements of a RF PA system (e.g., reflecting battery voltage level of energy source 1510, reflecting RF PA output power), and may control the voltage level V_{R} to be output by linear regulator 1504 based on these signals. In some embodiments, the regulated voltage V_{R} may be adjusted in conjunction with a digital pre-distortion algorithm that provides pre-distortion for a modulated RF waveform. For example, one or more controllers implementing a DPD algorithm may send one or more signals to one or more other controllers, and the one or more controllers receiving the one or more signals may control linear regulator 1504 accordingly. In this way, the regulated voltage V_{R} may be adjusted to achieve a more optimal modulated RF performance, or to minimize loss. In some embodiments, the one or more controllers may control (e.g., programmatically reconfigure) linear regulator 1504 and/or the switches of system 1500 based on one or more signals (e.g., reflecting battery level of energy source 1510, based on RF PA output power or desired RF PA output power, based on available operating points of a DPD system, and/or based on other considerations) received from one or more controllers. In some embodiments, the one or more controllers may control (e.g., programmatically reconfigure) linear regulator 1504 and/or the switches of system 1500 based on one or more signals received from one or more controllers implementing a DPD algorithm.

In the example shown in FIG. 15, a second stage circuit is realized as a network of switches (e.g., switches S_{A}, S_{B}, S_{A}′, S_{B}′) and a capacitor C_{f}. The network of switches and the capacitor in the example of FIG. 15 is designed to generate and supply one of multiple possible regulated voltages related to V_{R} according to a designed ratio to a PA. That is, the network of switches and the capacitor may be configured to output one of a set of voltages V₁, . . . , V_{N} proportional to V_{R} (with an output voltage of V_{R} itself also being proportional by a proportionality constant of 1). The network of switches and the capacitor may be configured to output one of a set of voltages V₁, . . . , V_{N} that is ratiometrically related to voltage V_{R}.

More specifically, as shown in FIG. 15, system 1500 may include a capacitor C₁ coupled between the output of linear regulator 1504 and ground 1515 and configured to hold up the voltage V_{R} output from linear regulator 1504. System 1500 may further include a switch S_{B} coupled between a terminal 1520 and a node 1550, and a switch S_{A} coupled between node 1550 and the output of linear regulator 1504. System 1500 may also include a switch S_{B}′ coupled between terminal 1520 and a node 1540, and a switch S_{A}′ coupled between node 1540 and ground 1515. System 1500 may further include flying capacitor C_{f} coupled between node 1550 and node 1540, configured to hold up a voltage V_{cf}.

The network of switches and the capacitor C_{f} may dynamically provide a modulated output voltage V_{O} to a power amplifier (i.e., discrete supply modulation). The voltage V_{O} may be modulated among multiple (two or more) voltages related to the regulated voltage V_{R}. For example, the network of switches and capacitor C_{f} may be controlled to modulate voltage V_{O} between the voltage V_{R}, a voltage V_{R}/2, and 0V.

Table 8 below illustrates modulation voltage sets that may be obtained with such a system based on two different example regulation set points (i.e., output levels) of V_{R} (4V and 3V, respectively).

TABLE 8

| | V_{R} = 4 V | V_{R} = 3 V |
|---|---|---|
| V_{R} | 4.00 V | 3.00 V |
| V_{R}/2 | 2.00 V | 1.50 V |

In some embodiments, one or more controllers implementing a digital pre-distortion (DPD) algorithm may send one or more signals to one or more other controllers commanding (e.g., programmatically reconfiguring) an optimal configuration for system 1500, and the one or more controllers receiving the signals may control (e.g., programmatically reconfigure) switches of system 1500 to implement the optimal configuration. These configuration adjustments may include, for example, adjusting the regulated output voltage V_{R} of linear regulator 1504.

The switches S_{A}, S_{B}, S_{A}′, S_{B}′ may be implemented in a variety of manners with some or all of the switches having unidirectional blocking capability. For example, one or all of the switches may be configured to block less than or equal to the maximum difference between V_{A} and V_{B}, but more than half the maximum difference therebetween.

In a complementary metal-oxide semiconductor (CMOS) or Bipolar-CMOS-DMOS (BCD) process, one or more of the switches S_{A}, S_{B}, S_{A}′, S_{B}′ may be realized as all NMOS devices or a combination of NMOS and PMOS devices, or all as PMOS devices. In some implementations, one may choose to implement switches S_{A} and S_{A}′ as a CMOS pair and switches S_{B} and S_{B}′ as a CMOS pair. Selection of a particular implementation may be based on size/performance of the switches and/or gate drive convenience of the switches, with gate-drive levels optionally derived from one or more of V_{BAT}, V_{R} and V_{cf}.

In some embodiments, the multilevel converter of FIG. 15 may be operated according to four (4) different switch states, providing the output voltage V_{SM} indicated in Table 9. That is, a controller (e.g., the one or more controllers 550 of FIG. 5) may be connected and configured to turn individual switches S_{A}, S_{B}, S_{A}′, S_{B}′ on or off to achieve a given one of the states set forth in Table 9.

TABLE 9

| State | Switches On | V_{SM} = | Level | V_{cf} |
|---|---|---|---|---|
| 1 | S_{A}, S_{B} | V_{R} | L3 | Unchanging |
| 2 | S_{A}, S_{B}′ | V_{R}/2 | L2 | Increasing (under load) |
| 3 | S_{B}, S_{A}′ | V_{R}/2 | L2 | Decreasing (under load) |
| 4 | S_{B}′, S_{A}′ | 0 | L1 | Unchanging |

Table 9 shows the behavior of the multilevel converter of FIG. 15 for different switch states. In the table, V_{cf} denotes the voltage across flying capacitor C_{f}. State one (1) passes V_{R} to V_{SM}, while state four (4) passes 0V to V_{SM}. State two (2) results in V_{SM}=V_{R}−V_{cf}, while state three (3) results in V_{SM}=V_{cf}. It should be appreciated that, with suitable switching control of the converter (i.e., appropriate selections between states two (2) and three (3)), V_{cf} may be maintained near V_{R}/2, which may result in both states two (2) and three (3) providing an output voltage V_{SM}=V_{R}/2, as indicated in Table 9.

When controlled using the switch states of Table 9, converter 1500 enables three effective levels (i.e., approximate level values) to be synthesized at its output 1520: V_{R}, V_{R}/2, and 0V. Converter 1500 may thus be utilized to provide similar functionality to a 3-level supply modulator producing levels L1=0V, L3=V_{R}, and L2=V_{R}/2, for example.

A benefit of the design of FIG. 15 is that it combines the capacitive energy transfer supply generation function with the supply modulation function, reducing device area and component size as compared to using a separate supply generator and supply modulator. That is, the hybrid supply generator and supply modulator of FIG. 15 is capable of synthesizing selected voltage levels and supplying the selected voltage levels. A switch S_{B} or S_{B}′, for example, may be utilized in both the synthesizing and supplying of a selected voltage level.

In some embodiments, V_{cf} (the voltage across flying capacitor C_{f}) may be maintained near V_{R}/2 by appropriately selecting between states two (2) and three (3) of Table 9 when seeking to synthesize an output voltage level near V_{R}/2. Under a positive load current (e.g., deriving from a PA), V_{cf} may increase over time in state two (2) and may decrease over time in state three (3).

In some embodiments, when selecting which of states two (2) or three (3) to use to supply a voltage close to V_{R}/2 at the modulator output (i.e., synthesizing L2), state two (2) may be selected if V_{cf} falls too far below V_{R}/2, where “too far” may be defined using one or more threshold values as described below.

In some embodiments, switching between states two (2) and three (3) may be controlled on a hysteretic basis and/or with clocked switching transitions. For example, such switching may occur instantaneously when the voltage V_{cf} exceeds an allowed voltage deviation ΔV above or below V_{R}/2, or with transitions clocked, such as at a discrete supply modulation clocking rate. In some embodiments, the allowed voltage deviation ΔV value may be hardcoded in the controller, may be a programmable value of the controller, or may be conveyed via an external signal.

It should be appreciated that circuitry may be provided to measure/detect and/or infer the voltage V_{cf} across the flying capacitor C_{f}. For example, a differential sensor (not shown) (e.g., differential amplifier and/or comparator) may be provided, with each of its two inputs connected to a different terminal of C_{f} and its output connected to the controller controlling the switch states.

The same state machines described with respect to FIGS. 9A and 9B may be used to control the switch state of the multilevel converter 1500 to maintain L2 (i.e., V_{SM}=V_{R}/2) by transitioning back and forth (e.g., alternating) between states two (2) and three (3), except that for multilevel converter 1500, 0V is substituted for V_{A} and V_{R} is substituted for V_{B} for the transition conditions in FIGS. 9A and 9B and in the corresponding discussion. Similarly, the same voltage patterns and state transitions discussed with respect to FIGS. 10A-10C may be associated with multilevel converter 1500, except that 0V is substituted for V_{A} and V_{R} is substituted for V_{B} in the voltage patterns.

FIG. 16 is a diagram of a system 1600. System 1600 is an example of a reconfigurable hybrid supply generator and supply modulator with a regulation stage. The regulation stage may include one or more linear regulators (e.g., linear regulator 1604). The one or more linear regulators (e.g., linear regulator 1604) and capacitor C₁ may be considered to be a first stage circuit, while the network of switches (e.g., S₁, S₂, S₃, S₁′, S₂′, S₃′) and capacitors (e.g., C_{f1}, C_{f2}) may be considered to be a second stage circuit. Any type of linear regulator (e.g., LDO) may be used as linear regulator 1604. Although a linear regulator 1604 is shown in FIG. 16, in some embodiments, different types of voltage regulation circuits may be used in place of, or in addition to, linear regulator 1604. For example, a magnetic converter (e.g., buck, boost, buck-boost, flyback) may be used. As previously discussed, a linear regulator may have more dissipative loss than a magnetic converter (and thus be less efficient), but may be smaller in size (e.g., implemented on a small IC or with small components) and/or less expensive than a magnetic converter. Thus, use of a linear regulator may be advantageous in some applications, such as mobile applications, where size and/or cost may be a constraint. Although a linear regulator 1604 is shown in FIG. 16, in some embodiments, different types of voltage regulation circuits may be used in place of, or in addition to, linear regulator 1604. For example, a combination of a switched-capacitor converter and a linear regulator as shown in FIG. 7G (717) may be used in place of linear regulator 1604. In some such embodiments, the linear regulator (e.g., linear regulator 716) may be omitted, and regulation achieved through control of a switched-capacitor converter (e.g., switched-capacitor converter 733).

System 1600 may be coupled to energy source 1610 (e.g., battery) at a pair of input terminals (e.g., one coupled to the positive terminal and one coupled to the negative terminal of energy source 1610) and may be coupled to a load (e.g., RF amplifier) via a pair of output terminals 1620, 1630. Linear regulator 1604 may draw power at the input terminals to regulate from a voltage of energy source 1610 (e.g., battery), such as a voltage of V_{BAT}, and may output a regulated voltage V_{R}. Energy source 1610 is shown in FIG. 16 in phantom, as it may not properly be considered to be part of system 1600. The voltage level of V_{R} may be set to a fixed value. Alternatively, the voltage level V_{R} may be selected from among multiple discrete values (e.g., based on current input battery voltage of energy source 1610, based on RF PA output power or desired RF PA output power, based on available operating points for a digital predistortion (DPD) system, and/or based on other considerations). That is, the voltage level of V_{R} may be controllable (e.g., able to be programmatically reconfigured) by one or more controllers (not shown), such as controller(s) 550. In some embodiments, the one or more controllers may receive feedback or feedforward signals from elements of a RF PA system (e.g., reflecting battery voltage level of energy source 1610, reflecting RF PA output power), and may control the voltage level V_{R} to be output by linear regulator 1604 based on these signals. In some embodiments, the regulated voltage V_{R} may be adjusted in conjunction with a digital pre-distortion algorithm that provides pre-distortion for a modulated RF waveform. For example, one or more controllers implementing a DPD algorithm may send one or more signals to one or more other controllers, and the one or more controllers receiving the one or more signals may control linear regulator 1604 accordingly. In this way, the regulated voltage V_{R} may be adjusted to achieve a more optimal modulated RF performance, or to minimize loss. In some embodiments, the one or more controllers may control (e.g., programmatically reconfigure) linear regulator 1604 and/or the switches of system 1600 based on one or more signals (e.g., reflecting battery level of energy source 1610, based on RF PA output power or desired RF PA output power, based on available operating points of a DPD system, and/or based on other considerations) received from one or more controllers. In some embodiments, the one or more controllers may control (e.g., programmatically reconfigure) linear regulator 1604 and/or the switches of system 1600 based on one or more signals received from one or more controllers implementing a DPD algorithm.

In the example shown in FIG. 16, a second stage circuit is realized as a network of switches (e.g., switches S₁, S₂, S₃, S₁′, S₂′, S₃′) and capacitors (e.g., capacitors C_{f1}, C_{f2}). The network of switches and capacitors in the example of FIG. 16 is designed to generate and supply one of multiple possible regulated voltages related to V_{R} according to a designed ratio to a PA. That is, the network of switches and capacitors may be configured to output one of a set of voltages V₁, . . . , V_{N} proportional to V_{R}. The network of switches and capacitors may be configured to output one of a set of voltages V₁, . . . , V_{N} that is ratiometrically related to voltage V_{R}.

More specifically, as shown in FIG. 16, system 1600 may include a capacitor C₁ coupled between the output of linear regulator 1604 and ground 1615 and configured to hold up the voltage V_{R} output from linear regulator 1604. System 1600 may further include a switch S₁ coupled between a terminal 1620 and a node 1660, a switch S₂ coupled between node 1660 and a node 1670, and a switch S₃ coupled between node 1670 and the output of linear regulator 1604. System 1600 may also include a switch S₁′ coupled between terminal 1620 and a node 1650, a switch S₂′ coupled between node 1650 and a node 1640, and a switch S₃′ coupled between node 1640 and ground 1615. System 1600 may further include a flying capacitor Cm coupled between node 1660 and node 1650, configured to hold up a voltage V_{cf1}, and a flying capacitor C_{f2} coupled between node 1670 and node 1640, configured to hold up a voltage V_{cf2}.

The network of switches and capacitors may dynamically provide a modulated output voltage V_{O} to a power amplifier (i.e., discrete supply modulation). The voltage V_{O} may be modulated among multiple (two or more) voltages related to the regulated voltage V_{R}. The operation of the network of switches and capacitors may be reconfigurable to provide different discrete voltage outputs depending on a selected regulation voltage V_{R} and/or other consideration. For example, the network of switches and capacitors may be controlled to modulate voltage V_{O} between the voltage V_{R}, a voltage V_{R}/2, and 0V, or may modulate voltage V_{O} among the voltage V_{R}, a voltage (2/3)*V_{R}, a voltage (1/3)*V_{R}, and 0V, depending on a selected configuration, or operating mode.

Table 10 below illustrates modulation voltage sets that may be obtained with such a system based on two different example regulation set points (i.e., output levels) of V_{R} (4V and 3V, respectively). SC Cfg #1 in Table 10 relates to a first operating mode, where system 1600 is capable of supplying voltages at V_{R} (i.e., the voltage output from linear regulator 1604) and ratios of 2/3 and ⅓ of V_{R}. SC Cfg #2 in Table 10 relates to a second operating mode, where system 1600 is capable of supplying voltages at V_{R} and at a ratio of ½ of V_{R}.

TABLE 10

| | SC Cfg #1 | SC Cfg #2 | SC Cfg #1 | SC Cfg #2 |
|---|---|---|---|---|
| | V_{R} = 4 V | V_{R} = 4 V | V_{R} = 3 V | V_{R} = 3 V |
| V_{R} | 4.00 V | 4.00 V | 3.00 V | 3.00 V |
| (2/3)*V_{R} | 2.67 V | | 2.00 V | |
| (1/2)*V_{R} | | 2.00 V | | 1.50 V |
| (1/3)*V_{R} | 1.33 V | | 1.00 V | |

A particular operating mode may be most optimal depending on factors such as the input voltage from energy source 1610 (e.g., battery), output power of the PA (not shown), and/or other operating characteristics associated with the PA.

In some embodiments, one or more controllers implementing a digital pre-distortion (DPD) algorithm may send one or more signals to one or more other controllers commanding (e.g., programmatically reconfiguring) an optimal configuration for system 1600, and the one or more controllers receiving the signals may control (e.g., programmatically reconfigure) switches of system 1600 to implement the optimal configuration. These configuration adjustments may include, for example, adjusting voltage conversion ratios provided by the network of switches and capacitors by switching operating modes and/or adjusting the regulated output voltage V_{R} of linear regulator 1604.

Thus, as discussed, system 1600 may operate in multiple operating modes that provide different available voltage sets at the output V_{O}. The different operating modes leverage different regulation points for flying capacitor voltages V_{cf1} and V_{cf2}. The different operating modes in the example of system 1600 are further described below.

In a first operating mode, output voltage V_{O} may be synthesized at V_{R} and (2/3)*V_{R}. Output voltage V_{O} may also be synthesized at (1/3)*V_{R}, or output at 0V, if desired. In this first operating mode, flying capacitor voltages V_{cf1} and V_{cf2} may be regulated to be near (1/3)*V_{R} and (2/3)*V_{R}, respectively. This first operating mode uses techniques similar to those described with respect to the first operating mode of the multilevel converter of FIG. 11, with V_{A} of the multilevel converter of FIG. 11 now being set to 0V. The switch states that may be utilized in this first operating mode are described below in Table 11.

TABLE 11

| State | Switches On | V_{O} | V_{O}≈ | Level | V_{cf1} | V_{cf2} |
|---|---|---|---|---|---|---|
| 1 | S₁′, S₂′, S₃′ | 0 | 0 | L1 | Unchanging | Unchanging |
| 2 | S₁′, S₂′, S₃ | V_{R} − V_{cf2} | (⅓)*V_{R} | L2 | Unchanging | Increasing |
| 3 | S₁′, S₂, S₃′ | V_{cf2} − V_{cf1} | (⅓)*V_{R} | L2 | Increasing | Decreasing |
| 4 | S₁′, S₂, S₃ | V_{R} − V_{cf1} | (⅔)*V_{R} | L3 | Increasing | Unchanging |
| 5 | S₁, S₂′, S₃′ | V_{cf1} | (⅓)*V_{R} | L2 | Decreasing | Unchanging |
| 6 | S₁, S₂′, S₃ | V_{R} − V_{cf2} + V_{cf1} | (⅔)*V_{R} | L3 | Decreasing | Increasing |
| 7 | S₁, S₂, S₃′ | V_{cf2} | (⅔)*V_{R} | L3 | Unchanging | Decreasing |
| 8 | S₁, S₂, S₃ | V_{R} | V_{R} | L4 | Unchanging | Unchanging |

The states synthesizing each of the two intermediate effective levels each have different effects on the charging and discharging of C_{f1} and C_{f2} (i.e., V_{cf1} or V_{cf2} increasing or decreasing under load (e.g., PA)). By dynamically choosing which state is used to synthesize a desired intermediate output level, one may maintain the capacitor voltages V_{cf1} and V_{cf2} each near their target voltages of (1/3)*V_{R} and (2/3)*V_{R}. These control selections may be done through a variety of means, such as through use of one or more controllers executing one or more state machines. The state machines may be implemented on a clocked or unclocked basis. It should be apparent that there is adequate control authority in system 1600 to select states to both synthesize the desired output levels and maintain the flying capacitor voltages in an acceptable range; many other means may likewise be realized to do so.

As discussed above, if switches S₂ and S₂′ of system 1600 are held on, the circuit of system 1600 may be reconfigured in a second operating mode to provide 3 available levels rather than the 4 available levels of the first operating mode. That is, switch S₃ in system 1600 may act like switch S_{A} in FIG. 8, switch S₁ in system 1600 may act like switch S_{B} in FIG. 8, switch S₁′ in system 1600 may act like switch S_{B}′ in FIG. 8, and switch S₃′ in system 1600 may act like switch S_{A}′ in FIG. 8. System 1600 may thus be a reconfigurable multi-level converter providing two operating configurations (or operating modes) that provide different sets of available voltages V_{SM}. One may then have an extended state machine (or multiple state machines that are selected from depending upon configuration) to control the associated switches.

In the second operating mode, output voltage V_{O} may be synthesized at V_{R} and (1/2)*V_{R}. Output voltage V_{O} may also be output at 0V if desired. In this second operating mode, flying capacitor voltages V_{cf1} and V_{cf2} may be regulated to be near (1/2)*V_{R}, with the two flying capacitors effectively held in parallel (i.e., V_{cf}2=V_{cf1}). This may be accomplished by holding switches S₂ and S₂′ on, while modulating other switches to provide the output and to regulate the flying capacitor voltages near their target values. Techniques similar to those described above with respect to the second operating mode of the multilevel converter of FIG. 11 may be used to accomplish this. The switch states used in this second operating mode are described below in Table 12.

TABLE 12

| State | Switches On | V_{O} | V_{O}≈ | Level | V_{cf1} | V_{cf2} |
|---|---|---|---|---|---|---|
| A | S₁′, S₂, S₂′, S₃′ | 0 | 0 | 1 | Unchanging | Unchanging |
| B | S₁′, S₂, S₂′, S₃ | V_{R} − V_{cf2} | (½)*V_{R} | 2 | Increasing | Increasing |
| C | S₁, S₂, S₂′, S₃′ | V_{cf2} | (½)*V_{R} | 2 | Decreasing | Decreasing |
| D | S₁, S₂, S₂ ′, S₃ | V_{R} | V_{R} | 3 | Unchanging | Unchanging |

In some embodiments, switching between states may be controlled on a hysteretic basis and/or with clocked switching transitions. For example, such switching may occur instantaneously when the voltage V_{cf1} or V_{cf2} exceeds an allowed voltage deviation ΔV above or below V_{R}/2 (in the second operating mode), when V_{cf1} exceeds an allowed voltage deviation ΔV above or below V_{R}/3 (in the first operating mode), or when V_{cf2} exceeds an allowed voltage deviation ΔV above or below 2*V_{R}/3 (in the first operating mode), or with transitions clocked, such as at a discrete supply modulation clocking rate. In some embodiments, the allowed voltage deviation ΔV value may be hardcoded in the controller, may be a programmable value of the controller, or may be conveyed via an external signal.

It should be appreciated that circuitry may be provided to measure/detect and/or infer the voltage V_{cf} across the flying capacitor C_{f1} and the voltage V_{cf2} across the flying capacitor C_{f2}. For example, differential sensors (not shown) (e.g., differential amplifiers and/or comparators) may be provided, each with each of its two inputs connected to a different terminal of its respective capacitor and its output connected to the controller controlling the switch states.

In the second operating mode, the same state machines described with respect to FIGS. 9A and 9B may be used to control the switch state of the multilevel converter 1600 to maintain L2 (i.e., V_{SM}=V_{R}/2) by transitioning back and forth (e.g., alternating) between states two (B) and three (C), except that for multilevel converter 1600, 0V is substituted for V_{A} and V_{R} is substituted for V_{B} for the transition conditions in FIGS. 9A and 9B and in the corresponding discussion. Similarly, the same voltage patterns and state transitions discussed with respect to FIGS. 10A-10C may be associated with the second operating mode of multilevel converter 1600, except that 0V is substituted for V_{A} and V_{R} is substituted for V_{B} in the voltage patterns.

In the first operating mode, the same example states for different regions of the (V_{cf1}, V_{cf2}) plane discussed with respect to FIGS. 12A and 12B may be utilized to drive the capacitor voltages toward their desired values, except that for multilevel converter 1600, 0V is substituted for V_{A} and V_{R} is substituted for V_{B} in the figures and corresponding discussion. Similarly, Tables 3-5 and their corresponding discussion regarding switch pair transitions also applies to multilevel converter 1600, except that again 0V is substituted for V_{A} and V_{R} is substituted for V_{B}. Likewise, the conditions of Table 6 and the state machine of FIG. 13 may also be utilized for multilevel converter 1600, except that for multilevel converter 1600, 0V is substituted for V_{A} and V_{R} is substituted for V_{B} in discussions related to this Table and figure. Furthermore, the state machine of FIG. 14 may also be utilized for switching operating modes of multilevel converter 1600, with operating mode 1 corresponding to the 4-level operation described with respect to Table 11 above and operating mode 2 corresponding to the 3-level operation described with respect to Table 12 above.

In some embodiments, switches S₁, S₁′, S₂, S₂′, S₃, S₃′ may be selected to have a voltage rating of more than ½ of V_{R}, but need not be rated for more than voltage V_{R}. Again, gate drive sources for the switches may be derived from input voltage V_{R} and/or flying capacitor voltages V_{cf1}, V_{cf2}.

In some embodiments, one or more controllers implementing a digital pre-distortion (DPD) algorithm may send one or more signals to one or more other controllers commanding an optimal configuration for system 1600, and the one or more controllers receiving the signals may control switches of system 1600 to implement the optimal configuration. These configuration adjustments may include, for example, adjusting voltage conversion ratios provided by the network of switches and capacitors by switching operating modes and/or adjusting voltages (e.g., controlling linear regulator 1604 to adjust voltage V_{R}).

Those of ordinary skill in the art should appreciate that hybrid supply generator and supply modulator designs including a regulation stage (e.g., system 1600) and having more flying capacitors and more effective output levels may be synthesized by direct extension of the design of system 1600 of FIG. 16, and that these designs may optionally be made to be reconfigurable.

In general, designs providing N effective output levels may utilize N-2 flying capacitors and N-1 complementary switch pairs (yielding up to 2^{(N-1)} switch states that may be used for level synthesis).

It should be appreciated that additional circuitry may be used to pre-charge the flying capacitors (e.g., C_{f1} and C_{f2} in FIG. 16) to desired levels before modulation starts. For a reconfigurable multilevel converter, the desired levels may be selected based on the desired configuration.

In some embodiments, additional circuitry may also be provided to maintain the flying capacitor voltages to within a desired range (e.g., close to their respective target voltages) during time periods when the synthesized output levels do not provide charging/discharging control of the capacitor voltage(s), when the system is not operating (e.g., in standby mode or in startup), and/or when the voltage level V_{R} or its references are adjusted. Such circuitry might comprise linear circuits (e.g., current sources, linear regulators, etc.) implemented in the integrated circuit.

It should be recognized that the multilevel converter of FIG. 8 may include a regulation stage (e.g., linear regulator) as discussed with respect to system 1500 of FIG. 15. For example, if such a regulation stage outputs a voltage V_{R}, the values and/or conditions discussed with respect to FIG. 8 would include V_{R} instead of V_{B}. Similarly, the multilevel converter of FIG. 11 may include a regulation stage (e.g., linear regulator) as discussed with respect to system 1600 of FIG. 16. For example, if such a regulation stage outputs a voltage V_{R}, the values and/or conditions discussed with respect to FIG. 11 would include V_{R} instead of V_{B}.

It should also be recognized that, although system 1500 of FIG. 15 includes a ground input 1515, the disclosure is not so limited. For example, ground input 1515 may be replaced with an input voltage V_{A} (as discussed above with respect to FIG. 8), resulting in a differential multilevel converter. If ground input 1515 were replaced with an input voltage V_{A}, the values and/or conditions discussed with respect to FIG. 8 could be rewritten using V_{A} instead of 0V. Similarly, it should also be recognized that, although system 1600 of FIG. 16 includes a ground input 1615, the disclosure is not so limited. For example, ground input 1615 may be replaced with an input voltage V_{A} (as discussed above with respect to FIG. 11), resulting in a differential multilevel converter. If ground input 1615 were replaced with an input voltage V_{A}, the values and/or conditions discussed with respect to FIG. 16 could be rewritten using V_{A} instead of 0V.

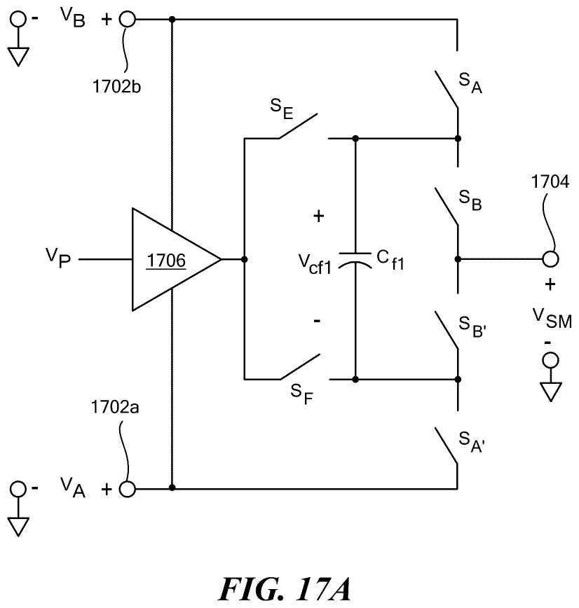

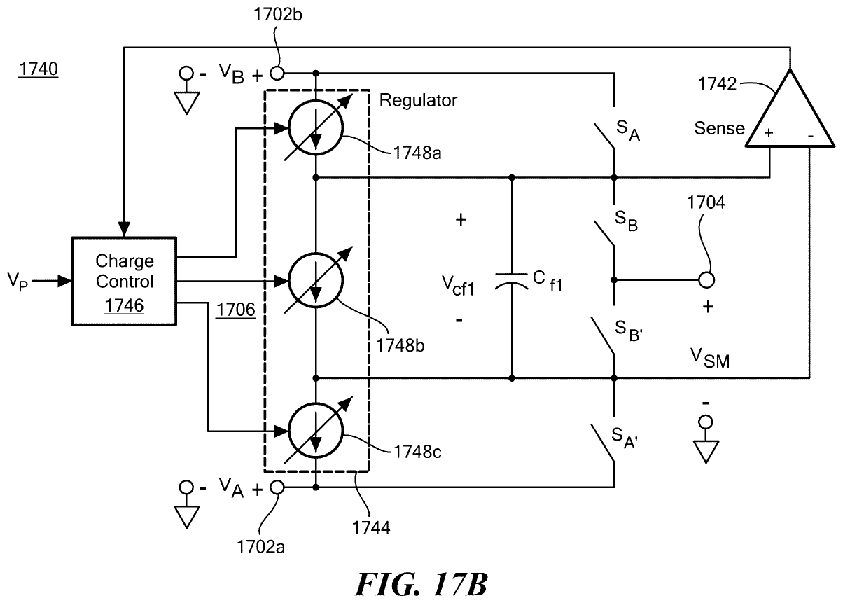

FIG. 17A shows an example of a multilevel converter 1700 with one flying capacitor C_{f} and circuitry for regulating or controlling charge thereon, according to some embodiments.

Converter 1700 may operate from two voltages V_{A} and V_{B} received at inputs 1702a and 1702b, respectively. The two voltages may, for example, be provided as described above in conjunction with FIG. 7A-7E, 7H, 7I, or 7J. Alternatively, voltage V_{A} may be coupled to ground as described above in conjunction with FIG. 7F or 7G. In some embodiments, voltage V_{B} may be controlled to be larger than voltage V_{A}. An output 1704 may provide a modulated output voltage V_{SM}, which may be referenced to ground.

As shown, the multilevel converter circuit includes a set of four switches S_{A}, S_{B}, S_{A}′, and S_{B}′, connected in series between inputs 1702a, 1702b. The multilevel converter circuit further includes a flying capacitor C_{f1} having a first terminal connected between switches S_{A} and S_{B}, and a second terminal connected between switches S_{A}′ and S_{B}′.

To regulate charge on capacitor C_{f1}, converter 1700 further includes charge regulation circuitry (sometimes referred to as “pre-charge” or “charge holding” circuitry). In the example of FIG. 17A, the charge regulation circuitry includes a regulator 1706 (e.g., a linear regulator) receiving a voltage V_{P}, a fifth switch S_{E} connected between an output of regulator 1706 and a first terminal of flying capacitor C_{f1}, and a sixth switch S_{F} connected between the output of regulator 1706 and second terminal of flying capacitor C_{f1}. The linear regulator may be supplied differentially between V_{A} and V_{B} and designed to source and/or sink current to make its output voltage close to the reference voltage V_{P}. The reference voltage V_{P} may be selected based on the levels V_{A} and V_{B}. To regulate charge on the flying capacitor in a three-level system, reference voltage V_{P} may be selected to be half-way in between V_{A} and V_{B} such that the linear regulator seeks to charge V_{cf1} towards half of (V_{B}−V_{A}). Alternatively, it may be dynamically programmable (e.g., from external circuitry). In a four-level system, one may have a charge control circuit for each of the flying capacitors, with reference voltages selected to charge the capacitor voltages towards (V_{B}−V_{A})/3 and 2*(V_{B}−V_{A})/3, respectively.

Converter 1700 may provide a ground referenced output voltage V_{SM} taken between switches S_{B} and S_{B}′, as shown. The output voltage V_{SM} may take on discrete values distributed between voltage values V_{A} and V_{B}, with energy transferred from and between V_{A} and V_{B} and the output.

The switches in FIG. 17A may be implemented in a variety of manners including but not limited to the various switch implementations described above with respect to FIG. 8.

The regulator 1706 and switches S_{E}, S_{F} may be used to regulate the flying capacitor voltage V_{cf1} to within a desired range (e.g., close to reference voltage V_{P}) during time periods when the synthesized output levels do not provide charging/discharging control of the capacitor voltages(s), when the system is not operating (e.g., in standby mode or in startup), and/or when the voltage levels V_{A}, V_{B} or their references are adjusted.

In a state where switch S_{A} is held on, switch S_{F} may be turned on and the regulator 1706 may sink or source current through C_{f1} such that voltage on C_{f1} is maintained close to a desired reference voltage V_{P}. Likewise, in a state where switch S_{A}′ is held on, switch S_{E} may be turned on and regulator 1706 may sink or source current through C_{f1}, such that the voltage on C_{f1} is maintained close to the desired reference voltage V_{P}.

The reference voltage V_{P} may be related to the intermediate voltages V_{A}, V_{B}. For example, V_{P} may be at the midpoint between V_{A} and V_{B}, that is, V_{P}=(V_{B}+V_{A})/2. One may optionally create reference voltage V_{P} through a voltage divider between V_{A} and V_{B}. Alternatively, the reference voltage V_{P} may be provided externally in either analog or digital form.

Regulator 1706 may be configured to drive the voltage across C_{f1} to match reference voltage V_{P} or may be configured to act to drive the voltage across C_{f1} towards V_{P} only when the difference between V_{P} and V_{cf1} exceeds a threshold value ΔV_{P}>0. In some embodiments, the threshold ΔV_{P} may be selected to be greater than the voltage ΔV used for selecting the switch state to synthesize the output voltage level near (V_{B}+V_{A})/2.

In some embodiments, regulator 1706 (e.g., a linear regulator) may be configured to source or sink current if V_{cf1} is greater than a magnitude ΔV_{P} away from V_{P}. This may include a hysteretic comparison. In some examples, one comparator with hysteresis may be used. In other examples, two comparators may be used: a first comparator to detect when V_{cf} is greater than V_{P}+ΔV_{P} and a second comparator to detect when V_{cf} is less than V_{P}−ΔV_{P}. If the first comparator is activated, regulator 1706 may be activated to drive V_{cf} down. If the second comparator is activated, regulator 1706 may be activated to drive V_{cf} up. When the voltage is within V_{P}−ΔV_{P}<V_{cf}<V_{P}+ΔV_{P}, the regulator may not act.

In some embodiments, charge regulation circuitry (e.g., regulator 1706 and switches S_{E}, S_{F}) may be selectively activated and deactivated based on operating mode, modulator state, duration of a particular modulator state, etc. For example, charge regulation circuitry may be selectively activated during modes such as startup and standby, or during particular states of the modulator (such as when switch S_{A} or S_{A}′ is active) or when particular states of the modulator are held for more than a certain duration, or when voltages V_{A} and V_{B} are being adjusted.

FIG. 17B shows another example of a multilevel converter 1740 with one flying capacitor and circuitry for regulating or controlling charge thereon, according to some embodiments. Similar to the converters of FIGS. 8 and 17A, converter 1740 of FIG. 17B includes a set of four switches S_{A}, S_{B}, S_{A}′, S_{B}′ connected in series between inputs 1702a, 1702b. Converter 1740 also includes a flying capacitor Cm having a first terminal connected between switches S_{A} and S_{B}, and a second terminal connected between switches S_{A}′ and S_{B}′.

Additionally, converter 1740 of FIG. 17B includes a differential sensor 1742, a regulator 1744, and a charge control circuit 1746, which may collectively be referred to as the “charge regulation circuitry.” Differential sensor 1742 has inputs connected to opposite terminals of C_{f1} to detect the voltage V_{cf1} across C_{f1}, and an output connected as input to charge control circuit 1746. Regulator 1744 may include controllable source elements 1748a-1748c (e.g., controllable current sources) that may charge and discharge capacitor C_{f1}. Charge control circuit 1746 may receive a reference input V_{P} (e.g., a reference voltage) and the output of differential sensor 1742 and may be configured to control the regulator and, more particularly, to control individual source elements 1748a-1748c of regulator 1744.

In some embodiments, charge control circuit 1746 may be configured to charge or discharge C_{f1} if its voltage V_{cf1} is more than some magnitude ΔV_{P} away from V_{P}. In some examples, this may be done using two comparators: a first comparator to detect when V_{cf1} is more than V_{P}+ΔV_{P} and a second comparator to detect when V_{cf} is less than V_{P}−ΔV_{P}. If the first comparator is activated, then middle current source 1748b may be activated/turned up to drive Voff down. If the second comparator is activated, current sources 1748a and 1748c may be activated to drive V_{cf1} up. When the voltage is within V_{P}−ΔV_{P}<V_{cf}<V_{P}+ΔV_{P}, all current sources 1748a-c may be turned off.

In some embodiments, reference input V_{P} may be related to the intermediate voltages V_{A}, V_{B} such as discussed above for FIG. 17A.

In some embodiments, current sources 1748a-c of FIG. 17B may be controlled to regulate the voltage at each terminal of the capacitor in response to V_{A} target voltage, V_{B} target voltage, system operating mode, and/or other conditions.

Similar to the charge regulation circuitry discussed above with respect to FIG. 17A, the charge regulation circuitry of FIG. 17B may drive the voltage across C_{f1} to match reference input V_{P} or may be configured to act to drive the voltage across C_{f1} towards V_{P} only when the difference between V_{P} and V_{cf1} exceeds a threshold value ΔV_{P}. In some embodiments, the threshold ΔV_{P} may be selected to be greater than the voltage ΔV used for selecting the switch state to synthesize the output voltage level near (V_{B}+V_{A})/2.

Also as discussed above with respect to FIG. 17A, the charge regulation circuitry of FIG. 17B may be selectively activated and deactivated based on operating mode, modulator state, duration of a particular modulator state, etc.

FIGS. 17A and 17B illustrate charge regulation used with a multilevel converter 1740 (e.g., differential multilevel converter) having a single flying capacitor, such as may be used to provide three effective output levels. For converters with greater numbers of flying capacitors (e.g., the converter of FIG. 11 or FIG. 16), the general structures and techniques shown and described with respect to FIGS. 17A and 17B may be extended to control charge on each of the flying capacitors. For example, using the approach of FIG. 17A, a separate linear regulator 1706 and pair of switches S_{E}, S_{F} may be provided for each flying capacitor. As another example, using the approach of FIG. 17B, a separate charge control circuit 1746 and set of controllable source elements 1748a-1748c may be provided for each flying capacitor.

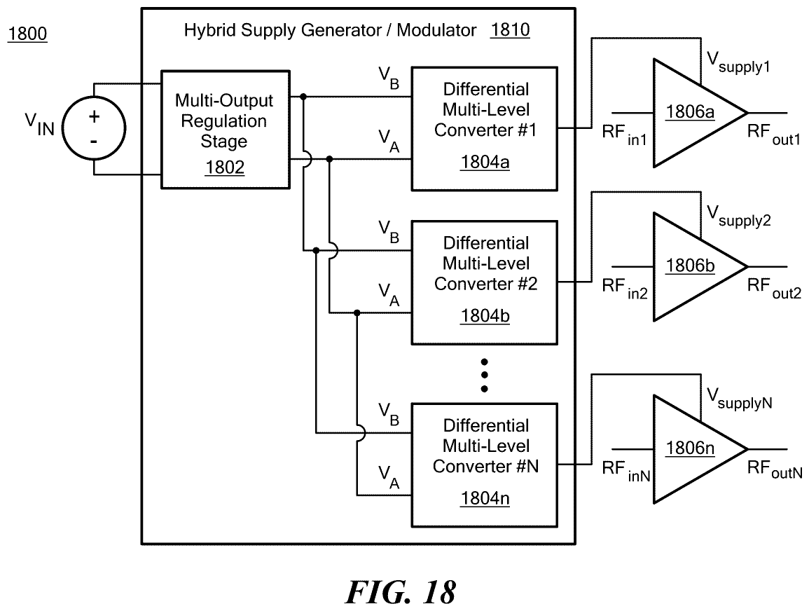

Turning to FIG. 18, according to embodiments of the present disclosure, a hybrid supply generator and supply modulator may have multiple outputs to supply one or more power amplifiers (e.g., with different voltages).

Illustrative hybrid supply generator and supply modulator 1800 includes a single multi-output regulation stage 1802 and a plurality of multilevel converters (e.g., differential multilevel converters) 1804a, 1804b, . . . , 1804n. Multi-output regulation stage 1802 receives input voltage V_{IN} and synthesizes two intermediate voltages V_{A} and V_{B} which may be independently controllable. Each of the differentially-coupled multilevel converters 1804a-n may receive the intermediate voltages V_{A} and V_{B} and be configured to synthesize one of three or more instantaneous output voltage levels, which voltage levels may be used to supply a corresponding one of a plurality of PAs 1806a-n.

In some embodiments, multilevel converters 1804a-n may directly provide supply voltages V_{supply1 . . . N} to PAs 1806a-n, as shown. In other embodiments, the outputs of multilevel converters 1804a-n may be filtered/regulated using additional circuitry to provide the plurality of PA supply voltages V_{supply1 . . . N}. Examples of additional circuitry are described above with respect to FIGS. 5A, 5B, and 5C. In any case, it should be appreciated that different ones of the PA supply voltages V_{supply1 . . . N} may be independently controllable using the system of 1800.

Multi-output regulation stage 1802 may be the same as or similar to any of the multi-output regulation stage embodiments disclosed herein. Alternatively, a single output regulation stage may be used in place of multi-output regulation stage 1802. Such a single output regulation stage may be the same or similar to any of the single output stage embodiments disclosed herein. Likewise, a given one of the multilevel converters 1804a-n may be the same as or similar to that of any of the multilevel converter embodiments disclosed herein.

In some embodiments, regulation stage 1802 may be realized on an IC. In some embodiments, multilevel converters 1804a-n may be realized on one or more ICs. In some embodiments, regulation stage 1802 IC may be different from the multilevel converters 1804a-n IC(s). In some embodiments, regulation stage 1802 and one or more multilevel converters 1804a-n may be realized on the same IC.

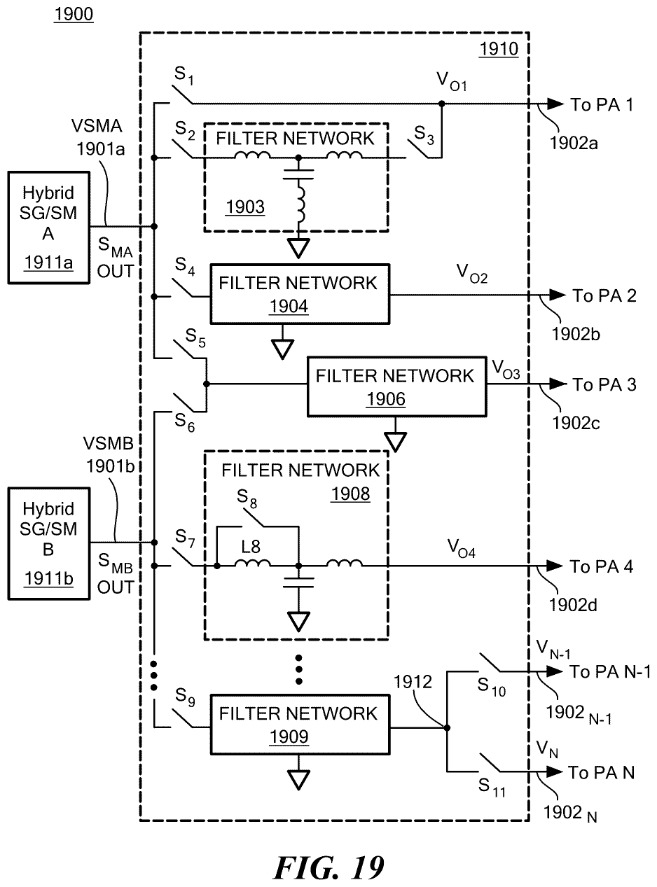

Turning now to FIG. 19, as previously discussed, an RF power amplifier system may include a controller (e.g., one of controllers 550) configured to provide one or more control signals to one or more hybrid supply generator and supply modulators. In some embodiments, the variable supply voltages (or “supply bias voltages”) may be provided in the form of pulses with each pulse having one of a discrete number of voltage levels. That is, the hybrid supply generator and supply modulators may each provide one of a plurality of discrete supply voltages to the supply/bias terminal of a corresponding RF amplifier (or in some cases, to multiple RF amplifiers). Such discrete voltage supply levels may be predetermined or may be adapted over time based upon required average transmit power levels or other factors.

Transitions between pulses of different voltage levels (i.e., transitions from one voltage level to another) may give rise to undesired frequency components in the varying supply voltage signals. In some embodiments, such variable supply voltages may be provided to the supply/bias terminal of the amplifier through one or more pulse shaping networks (PSNs). A PSN functions to filter out or otherwise remove undesirable frequency components in a supply voltage signal (i.e., the PSN filters or shapes the trajectory of the supply voltage signal). Thus, a filtered supply voltage signal may be provided to the supply terminal of the RF amplifier. In the context of FIG. 5A, for example PSNs may correspond to, or form part of, additional circuitry 506, for example. In some case, the hybrid supply generator and supply modulator and PSN may be provided as a power management integrated circuit (PMIC).

FIG. 19 shows an example of a switching network having one or more PSNs and being coupled to one or more hybrid supply generator and supply modulators. Illustrative switching network 1900 has one or more inputs, each of which may be coupled to one or more hybrid supply generator and supply modulators with two hybrid supply generator and supply modulators 1911a, 1911b shown in this example. Alternatively or additionally, rather than outputs from separate hybrid supply generator and supply modulators, signals 1901a and 1901b (and so forth) may represent multiple outputs of a single hybrid supply generator and supply modulator (e.g., the differential multilevel converter outputs 1804a and 1804b of hybrid supply generator and supply modulator 1800 of FIG. 18), or as combinations of outputs of a single multi-output hybrid supply generator and supply modulator and one or more other hybrid supply generator and supply modulator(s).

In some implementations, switching network 1900 may be coupled in a cascaded configuration with hybrid supply generator and supply modulators 1911a, 1911b. In this example embodiment, switching network 1900 comprises two inputs 1901a, 1901b coupled to outputs of respective ones of hybrid supply generators and supply modulators 1911a, 1911b. Hybrid supply generator and supply modulators (A and B) respectively supply modulated voltage signals VSMA and VSMB as inputs to switching network 1900.

Switching network 1900 comprises a first plurality of outputs 1902a-1902N each of which may be coupled to one or more of a second plurality of RF amplifiers (not shown in FIG. 19). In embodiments, the plurality of switching network outputs may be the same as the number of RF amplifiers such that there exists a one-to-one correspondence between the number of switching network outputs and RF amplifiers. In this case, each RF amplifier may be coupled to a respective one of the switching network outputs 1902a-1902N.

In the example embodiment of FIG. 19, switching network 1900 is illustrated as providing N outputs 1902a-1902N (where N is any integer greater than 1) at which respective ones of voltages V_{O1}-V_{ON} may be provided. The switching network outputs may be coupled to one or more bias terminals (e.g., a supply terminal) of one or more RF power amplifiers and thus output voltages V_{O1}-V_{ON} may be coupled to a bias terminal of one or more RF amplifiers. In some embodiments, N may be equal to 2 (thus providing output voltages V_{O1}, V_{O2}). In some embodiments, N may be equal to 4 (thus providing outputs voltages V_{O1}-V_{O4}). In some embodiments, N may be equal to 6 (thus providing output voltages V_{O1}-V_{O6}). In some embodiments, N may be equal to 8 (thus providing output voltages V_{O1}-V_{O8}). In some embodiments, N may be equal to 10 (thus providing output voltages V_{O1}-V_{O10}).

For example, in one embodiment, all N output signals V_{O1}-V_{ON} may be coupled to a bias terminal (e.g., a supply terminal) of a single RF power amplifier. In other embodiments, one or more of each output signal V_{O1}-V_{ON} may be coupled to its own, respective, RF power amplifier (i.e., a bias terminal of respective RF amplifiers). And in still further embodiments, one or more output amplifiers may be coupled to a single output of switching network 1900, while other RF output amplifiers may be coupled to one or more output signals of switching network 1900.

The switches S₁-S₁₁ of switching network 1900 may be coupled to a controller (not shown) that may open and close the switches S₁-S₁₁ to control the output signals V_{O1}-V_{ON}. In this way, switching network 1900 may be coupled across one or more PSN (and in some cases, configured to provide a signal path which bypasses one or more PSN). For example, when switch S₁ is closed, modulated voltage signal VSMA is couped to output 1902a at which voltage V_{O1} is provided. When switch S₁ is open and switches S₂ and S₃ are closed, modulated voltage signal VSMA is coupled through PSN 1903 (also referred to as filter network 1903) to output 1902a. And when switches S₁ and S₃ are open, the output signal V_{O1} at output 1902a is not connected to voltage signal VSMA, and may be floating or tied to some other potential such as ground by circuitry not shown. Thus, switches S₁, S₂, and S₃ may be used to adaptively (or dynamically) in real time enable or disable filtering (performed by filter network 1903) for output signal V_{O1}. It should be appreciated that filtering circuitry may be provided in a variety of different circuit configurations to provide filter characteristics selected to meet the needs of a particular application. Taking filter network (PSN) 1903 illustrative of filter networks 1904-1909, filter network 1903 comprises one or more electronic elements. In the example of FIG. 19, filter network 1903 comprises four electronic elements which are passive circuit elements (also sometimes referred to herein as a “passive component”). Filter networks 1903-1909 may have various passive or active circuit elements selected to suit the needs of a particular application. After reading the disclosure herein, one of ordinary skill in the art would understand how to design one or more filter networks to suit the needs of a particular application.

In some embodiments, a PSN may include one or more passive elements realized as discrete elements. In some embodiments, a PSN may include one or more passive elements realized on an IC or module. In some embodiments, a PSN may include one or more passive elements resulting from parasitic resistance, inductance, or capacitance.

In some embodiments, a PSN may include a resistor having a first terminal connected to the output of the hybrid supply generator and supply modulator, and a capacitor having a first terminal connected to the second terminal of the resistor and second terminal connected to ground. In some embodiments, a PSN may include a capacitor having a first terminal connected to the output of the hybrid supply generator and supply modulator and a second terminal connected to ground, and a resistor having a first terminal connected to the first terminal of the capacitor.

Whether to connect or not a given PSN (e.g., one or more of filter networks 1903, 1904, 1906, 1908, 1909, etc.) between a hybrid supply generator and supply modulator (e.g., one or more of hybrid supply generator and supply modulators 1911a, 1911b) and an output (e.g., one of outputs 1902a-1902N) may depend upon a variety of factors including but not limited to: the RF frequency band in which the RF signal provided to the RF input of the power amplifier resides; the bandwidth of the RF signal provided to the RF input of the power amplifier; peak-to-average ratio of the RF signal provided to the RF input of the power amplifier; power level of the RF signal provided to the RF input of the power amplifier; other aspects or characteristics of the RF signal to be provided to the RF input of the PA; the mode of the supply modulation (e.g., digital envelope tracking (DET) vs. average power tracking vs. fixed supply) being used; and/or by the characteristics of the operating or application scenario (e.g., observed noise or amplifier behavior) among other factors.

Similarly, when switch S₄ is closed, modulated voltage signal VSMA is coupled through filter network 1904 to output 1902b at which voltage V_{O2} is provided. When switch S₅ is closed, modulated voltage VSMA is coupled through filter network 1906 to output 1902c. And when switch S₆ is closed, modulated voltage signal VSMB is coupled through filter network 1906 to output 1902c. Thus, switches S₅ and S₆ may be used to select which modulated voltage signal VSMA or VSMB (or both in parallel) is coupled to provide an output signal at output 1902c.

When switch S is closed, modulated voltage signal VSMB is coupled through filter network 1908 to terminal 1902d. It should be appreciated that one, some or all of filters 1903-1909 may be provided as reconfigurable filters. For example, filter 1908 comprises switch S₈. Switch S₈ is configured to change the filtering parameters (or characteristics) of filter network 1908. In this case, closing switch S₈ creates a short circuit signal path across inductor L8, thereby effectively removing inductor L8 from filter 1908, which will affect the transfer function of filter network 1908. In this way, filter characteristics of filter network 1908 may be changed (e.g., adaptively changed or “on-the-fly” or in real time) to suit the needs of a particular application or operating scenario. For example, it might be desirable to dynamically adjust the characteristics of the filter depending on the RF band in which the signal will be transmitted by the power amplifier, by the bandwidth, peak-to-average ratio, power level, or other aspects of the signal to be transmitted, and by the mode of the supply modulation (e.g., digital envelope tracking (DET) vs. adaptive power tracking vs. fixed supply) being used, or by the characteristics of an operating or application scenario (e.g., observed noise or amplifier behavior) among other factors.

Switch S₉ may be switched between open and closed states to selectively couple modulated voltage signal VSMB through filter 1909 to node 1912. Switches S₁₀, S₁₁ may be switched between open and closed states to couple node 1912 to either or both of outputs 1902N-1, 1902N at which respective ones of voltages VN-1, VN are provided. When switches S₉ and S₁₀ are closed, modulated voltage signal VSMB is coupled through filter network 1909 to output 1902N-1 at which voltage V_{N-1} is provided. Similarly, when switches S₉ and S₁₁ are closed, modulated voltage signal VSMB is coupled through filter network 1909 to node 1912 at which voltage V_{N} may be provided. When all three switches S₉, S₁₀, and S₁₁ are closed, modulated voltage signal VSMB is coupled through filter network 1909 to both output terminals 1902N-1 and 1902N.

The signal paths created by switches S₁-S₁₁ in FIG. 19 are provided as examples. One skilled in the art would recognize that other configurations of signal paths and filtering parameters and characteristics are possible by changing the number, arrangement, and control of the switches in switching network 1900. For example, the switches S₁-S₁₁ may be operated or controlled (i.e., placed in an open or closed state) such that either of modulated voltage signals VSMA, VSMB may be coupled to any of terminals 1902a-1902N. In general, switches within switching network 1900 may be configured to enable one or more on-die supply modulator output(s) to be routed to one or more power amplifier terminals; adjusting filtering of a provided modulator output (e.g., to provide a reconfigurable pulse shaping network); reconfigure how different (possibly spatially separated) filter stages are utilized in connecting one or more modulator outputs via one more filter stages to one or more RF amplifiers; and turn-off switch(es) to enable a supply modulator output to be disconnected from a power amplifier and/or filter, or perform other tasks that modify and/or control the output signals that provide power to RF power amplifiers.

The particular manner in which switching network 1900 is realized may depend upon the power level, voltage level and application space of the system in which the switching network is being used (e.g., an RF amplifier system). For some mobile device applications (e.g., a cellular phone, smart phone, tablet PC with cellular communication capabilities) it may be desirable to monolithically integrate electronic elements (e.g., circuit components) of both the hybrid supply generator and supply modulator and switching elements as well as portions of the ancillary circuits on a single semiconductor die (e.g., in a CMOS or BCD process) or IC. In some cases it may be desirable to integrate electronics such as modulators and switching network 1900 together with power amplifiers on a single die. Moreover, in some cases it may be advantageous to package a hybrid supply generator and supply modulator and one or more linear regulators, switches, and/or some of the filter components within a single module and locate other filter components of the RF amplifier in a physically separate location. In still other applications it may be advantageous to package the modulator and some switches on a first die, and further switches on at least one additional die that is placed a relative distance from the first die. This second die may also contain one or more power amplifiers or be located physically close to power amplifier(s), e.g., in a module or co-located on a circuit board. In these latter cases, the switches on the first die can be used for some of the functions described above and may be placed close to one or more first filter stages, while the second die can also implement some of the functions described above and may be placed closer to one or more second filter stages. Communication lines may also be provided between the first die and the second die (or between a controller and the second die) to allow the configuration to be changed.

Various embodiments of the concepts, systems, circuits, devices, methods, and techniques sought to be protected are described herein with reference to the related drawings. Alternative embodiments may be devised without departing from the scope of the concepts, systems, circuits, devices, methods, and techniques described herein. It is noted that various connections and positional relationships (e.g., over, below, adjacent, etc.) may be set forth between elements in the foregoing description and in the drawings. These connections and/or positional relationships, unless specified otherwise, may be direct or indirect, and the described concepts, systems, circuits, devices, methods, and techniques are not intended to be limited in this respect. Accordingly, a coupling of components or subsystems may refer to either a direct or an indirect coupling, and a positional relationship between components or subsystems may be a direct or indirect positional relationship.

FIGS. 1A-19 illustrate circuits (or corresponding state machines) with certain components directly connected to one another. A person of ordinary skill in the art would understand that each of these components has terminals by which they may be connected with the other components over wires, electrical traces, or other conductive lines as shown in the schematic drawings. While FIGS. 1A-19 may illustrate certain components as being directly connected to one another, the disclosure is not so limited. One or more components may, for example, be connected between the components illustrated as being directly connected in the schematic drawings of FIGS. 1A-19. Both direct connections and indirect connections are intended to be encompassed by the disclosure herein. When direct connections are meant herein and in the claims, the word “direct” will be used in connoting the connection between the components. Thus, the term “connection” (or “coupled” or any other variant thereof), may include an “indirect connection” or a “direct connection.”

As used herein, the terms “comprises,” “comprising,” “includes,” “including,” “has,” “having,” contains,” “containing,” or any other variation thereof, are intended to cover a non-exclusive inclusion. For example, a system, system architecture, subsystem, component, circuit, process, method, article, or apparatus that comprises a list of elements or steps is not necessarily limited to only those elements or steps but may include other elements or steps not expressly listed or inherent to such system, system architecture, subsystem, component, circuit, process, method, article, or apparatus.

Additionally, the term “exemplary,” if used herein, means “serving as an example, instance or illustration.” Any embodiment or example described herein as “exemplary” is not necessarily to be construed as preferred or advantageous over other embodiments or designs. The terms “one or more” is understood to include any integer number greater than or equal to one, i.e., one, two, three, four, etc. The term “plurality” is understood to include any integer number greater than or equal to two, i.e., two, three, four, five, etc.

References in the specification to “one embodiment,” “an embodiment,” “an example embodiment,” etc., indicate that the embodiment may include a particular feature, structure, or characteristic, but every embodiment may include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments, whether or not explicitly described in that manner.

Use of ordinal terms, such as “first, second,” “third,” etc., in the claims to modify a claim element does not by itself connote any priority, preference, or order of one claim element over another, or the temporal order in which acts of a method are performed, but are used merely as labels to distinguish one claim element having a certain name from another element having a same name (but for use of the ordinal term) to distinguish the claim elements.

The terms “approximately,” substantially or “about” may be used to mean±/−30% of a target value in some embodiments, within +/−20% of a target value in some embodiments, within +/−10% of a target value in some embodiments, within +/−5% of a target value in some embodiments, and within +/−2% of a target value in some embodiments. The aforementioned terms may include the target value. The terms “approximately equal to,” substantially equal to” or “about equal to” may be used to refer to values that are within +/−30% of one another in some embodiments, within +/−20% of one another in some embodiments, within +/−10% of one another in some embodiments, within +/−5% of one another in some embodiments, and within +/−2% of one another in some embodiments. For example, a first voltage value that is “approximately,” “substantially,” or about equal to a second voltage value may within +/−30% of the second voltage value in some embodiments, within +/−20% of the second voltage value in some embodiments, within +/−10% of the second voltage value in some embodiments, within +/−5% of the second voltage value in some embodiments, or within +/−2% of the second voltage value in some embodiments. The aforementioned terms may exact matching of values.

It is to be understood that components used in electronic are lossy. Values described herein are described as ideal values and assume lossless components. As a result, descriptions of values, such as voltage values, or use of the phrase “equal to” herein, should be considered to include values within +/−10% of the value indicated.

It is to be understood that the disclosed subject matter is not limited in its application to the details of construction and to the arrangement of the components set forth in the foregoing description or illustrated in the drawings. The disclosed subject matter is capable of other embodiments and of being practiced and carried out in various ways.

Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, systems, system architectures, circuits, methods, and techniques for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing example embodiments, it is to be understood that the present disclosure has been made only by way of example, and that numerous changes in the details of implementation of the disclosed subject matter may be made without departing from the spirit and scope of the disclosed subject matter.

1. A system having a pair of input terminals configured to be connected to terminals of an energy source and having a pair of output terminals configured to be connected to a radio frequency (RF) amplifier, the system comprising:
a hybrid supply generator and supply modulator comprising
a linear regulator configured to draw power at the input terminals, and
a network of switches and at least one capacitor coupled to an output of the linear regulator; and
a controller configured to control the hybrid supply generator and supply modulator to output a selected voltage level.

2. The system of claim 1, wherein the controller is further configured to:
control the linear regulator to output a first voltage level; and
control the network of switches to output a second voltage level as the selected voltage level.

3. The system of claim 1, wherein an output reference of the linear regulator is selected from among multiple discrete regulation points.

4. The system of claim 1, wherein the at least one capacitor comprises a plurality of capacitors, the linear regulator is configured to output a first voltage level, and the network of switches and capacitors is reconfigurable to output one of a plurality of different voltage levels related to the first voltage level as the selected voltage level.

5. The system of claim 4, wherein the plurality of different voltage levels comprises the first voltage level, two thirds of the first voltage level, and one third of the first voltage level.

6. The system of claim 4, wherein the plurality of different voltage levels further comprises a voltage of zero volts.

7. The system of claim 4, wherein the plurality of different voltage levels comprises the first voltage level and one half of the first voltage level.

8. The system of claim 1, wherein the at least one capacitor comprises a plurality of capacitors, the linear regulator is configured to output a first voltage level, and the network of switches and capacitors is reconfigurable to operate in one of at least two different operating modes, a first operating mode configured to output a first set of voltage levels proportional to the first voltage level and a second operating mode configured to output a second set of voltage levels proportional to the first voltage level, the second set being different from the first set.

9. The system of claim 1, wherein the at least one capacitor comprises a plurality of capacitors, the linear regulator is configured to output a first voltage level, and the controller is configured to control the network of switches to reconfigure the hybrid supply generator and supply modulator to operate in one of at least two different operating modes, a first operating mode configured to output at least three different voltage levels proportional to the first voltage level and a second operating mode configured to output at least two different voltage levels proportional to the first voltage level.

10. The system of claim 1, wherein the at least one capacitor comprises a plurality of capacitors, and the controller is further configured to:
detect a voltage level of the energy source;
control the linear regulator to output a first voltage level based on the detected voltage level; and
reconfigure the network of switches and capacitors to output a second voltage level related to the first voltage level based on the detected voltage level.

11. The system of claim 1, wherein the controller is further configured to:
detect a voltage level of the energy source; and
reconfigure the hybrid supply generator and supply modulator to operate in one of at least two different operating modes based on the detected voltage level.

12. The system of claim 1, wherein the hybrid supply generator and supply modulator comprises lumped element capacitors and integrated circuit (IC) transistors.

13. The system of claim 1, wherein the at least one capacitor comprises a plurality of capacitors, and at least one of the linear regulator or the network of switches and capacitors can be programmatically reconfigured.

14. The system of claim 1, further comprising a filtering circuit coupled between the hybrid supply generator and supply modulator and the RF amplifier, the filtering circuit comprising at least one of a resistor, capacitor, or inductor.

15. The system of claim 1, wherein the hybrid supply generator and supply modulator is capable of synthesizing the selected voltage level and supplying the selected voltage level, and wherein at least one of the switches is utilized in both the synthesizing and supplying of the selected voltage level.

16. The system of claim 1, wherein the controller is further configured to operate the switches according to a state of a state machine implemented in the controller.

17. The system of claim 16, wherein the state of the state machine is selected to synthesize the selected voltage level and to maintain one or more voltages in the hybrid supply generator and supply modulator within a range.

18. The system of claim 16, wherein the controller implements the state machine on a clocked basis.

19. The system of claim 16, wherein the controller implements the state machine on an unclocked basis.

20. The system of claim 1, wherein the at least one capacitor comprises a plurality of capacitors, the linear regulator is configured to output a first voltage level, and the controller is further configured to operate the switches to regulate a voltage on one of the capacitors near one third of the first voltage level, and to regulate a voltage on another of the capacitors near two thirds of the first voltage level.

21. The system of claim 1, wherein the at least one capacitor comprises a plurality of capacitors, the linear regulator is configured to output a first voltage level, and the controller is further configured to operate the switches to regulate a voltage on one of the capacitors near one half of the first voltage level, and to regulate a voltage on another of the capacitors near one half of the first voltage level.

22. The system of claim 1, wherein the at least one capacitor comprises a plurality of capacitors, the hybrid supply generator and supply modulator further comprising:
a regulation stage comprising the linear regulator that outputs multiple voltage levels; and
a differential multi-level converter stage comprising the network of switches and capacitors that synthesizes one of two or more voltage levels related to at least one of the multiple voltage levels for output as the selected voltage level.
